(19) United States
(12) Patent Application Publication
(10) Pub. No.: US 2024/0379499 A1
(43) Pub. Date: Nov. 14, 2024

(54) COOLER AND SEMICONDUCTOR DEVICE

(71) Applicant: FUJI ELECTRIC CO., LTD., Kawasaki-shi (JP)

(72) Inventor: Daiki SANO, Matsumoto-city (JP)

(73) Assignee: FUJI ELECTRIC CO., LTD., Kawasaki-shi (JP)

(21) Appl. No.: 18/783,704

(22) Filed: Jul. 25, 2024

Related U.S. Application Data
(63) Continuation of application No. PCT/JP2023/024795, filed on Jul. 4, 2023.

(30) Foreign Application Priority Data
Aug. 8, 2022 (JP) 2022-126059

(51) Int. Cl. H01L 23/473; H01L 23/00; H01L 25/07

(52) U.S. Cl. CPC H01L 23/473; H01L 24/32; H01L 25/072; H01L 2224/32227; H01L 2924/13055

(57) ABSTRACT

A cooler includes first and second flow paths inside a container, respectively communicating with an inlet and an outlet, a third flow path, and first and second flow rate adjusting members respectively disposed between the first and third flow paths, and the second and third flow paths. The first flow rate adjusting member includes one or more openings through which a coolant flows from the first flow path to the third flow path, and has a first region with a first open area ratio and a second region with a second open area ratio less than the first one. The second flow rate adjusting member includes one or more openings through which the coolant flows from the third flow path to the second flow path, and has a third region with a third area ratio and a fourth region with a fourth open area ratio greater than the third one.

### CROSS-REFERENCE TO RELATED APPLICATION

This application is a continuation application of International Application PCT/JP2023/024795 filed on Jul. 4, 2023, which designated the U.S., which claims priority to Japanese Patent Application No. 2022-126059, filed on Aug. 8, 2022, the entire contents of which are incorporated herein by reference.

### BACKGROUND OF THE INVENTION

### 1. Field of the Invention

The embodiments discussed herein relate to a cooler and a semiconductor device.

### 2. Background of the Related Art

A known example of a cooler is integrated into the housing of a power converter and has coolant passages and recessed parts, whose openings are sealed by a heat generating element, connected by connection parts. The opening areas and the shapes of the connection parts vary according to distances from the inlets of the coolant passages (see Japanese Laid-open Patent Publication No. 2012-146759).

Another known cooler is provided with a plurality of plate-like fins, between which flow paths for a coolant are formed, below an upper plate on which a semiconductor chip is disposed. The plurality of plate-like fins are connected by connecting bars equipped with a plurality of comb-like teeth protruding into the flow paths. The plurality of comb-like teeth and the plurality of plate-like fins define a plurality of openings with sizes based on the positions of semiconductor chips and the like (see Japanese Laid-open Patent Publication No. 2019-071330).

Another known semiconductor device is equipped with a fin portion, which includes a plurality of protrusions connected to the lower surface of a thermally conductive base plate, and a cooling element that is connected to an inlet and an outlet of the coolant and covers the fin portion. A header, which serves as a reservoir, and a water flow control plate are provided so that the coolant is able to flow between the inlet and outlet and the fin portion (see International Publication Pamphlet No. WO 2017/090106).

A known semiconductor cooler is equipped with a cooling plate, which has a plurality of semiconductor modules that generate respectively different amounts of heat disposed on one surface and has a plurality of heat dissipating fins erected on the other surface, and a case portion that is disposed facing the cooling plate.

The height of a coolant flow path formed in gaps between adjacent heat dissipating fins, the cooling plate, and the walls of the case portion is varied according to the regions opposite the semiconductor modules that generate different amounts of heat (see Japanese Laid-open Patent Publication No. 2012-069892).

In a known liquid-cooled cooler in which coolant channels are formed, the inside of a cooler container, which has a heat sink with radiator fins as one side wall, is divided into two regions by a first partition wall. A heat dissipation region in which the radiator fins are exposed is formed in one region, and an inlet header region and an outlet header region, which are separated by a second partition wall, are formed in the other region. An inlet-side communication path and an outlet-side communication path are provided in the first partition wall, so that the inlet-side communication path communicates with the heat dissipation region and the inlet header region and the outlet-side communication path communicates with the heat dissipation region and the outlet header region (see Japanese Laid-open Patent Publication No. 2015-153799).

Another known semiconductor device has a plurality of cooling fins and a jacket that surrounds the cooling fins on the bottom surface of the base plate that has a semiconductor element mounted on its upper surface. A partition wall is provided below the plurality of cooling fins inside the jacket and causes coolant from a coolant inlet of the jacket to flow through the plurality of cooling fins and flow out to a coolant outlet of the jacket. An inlet opening portion that causes the coolant to flow from the coolant inlet to the plurality of cooling fins is provided in the partition wall at a position corresponding to the semiconductor element (see International Publication Pamphlet No. WO 2019/211889).

There is a known electrical device that is provided with a plurality of upstream-side communication paths in a connection region between a main flow path, which guides a coolant medium, of a cooling jacket and an inlet path disposed upstream, a plurality of downstream-side communication paths in a connection region between the main flow path and a discharge path disposed downstream, and an electrical element on a ceiling wall of the main flow path of the cooling jacket (see Japanese Laid-open Patent Publication No. 2006-179771).

A known semiconductor module cooler includes: a tray-shaped cooling jacket provided with a coolant introduction channel and a coolant discharge channel, which extend in parallel to each other, and a cooling channel therebetween; a heat sink disposed so that flow paths are orthogonal to the coolant introduction flow path and the coolant discharge flow path and so that a flow rate adjusting plate, which is fixed to one side, extends to a position bordering the coolant discharge channel; and a heat dissipating plate that has a semiconductor element bonded to its outer surface and covers an opening in the cooling jacket (see WO 2015/079643).

A known semiconductor module cooler includes: a first flow path that extends from the coolant inlet; a second flow path that is disposed in parallel with and spaced apart from the first flow path and extends toward a coolant discharge port; a water jacket with a third flow path that communicates with the first flow path and the second flow path; and a heat sink disposed within the third flow path. A flow rate adjustment plate is provided in the second flow path of the water jacket so as to be spaced apart from and parallel to a side surface of the heat sink (see International Publication Pamphlet No. WO 2013/054615).

Technologies that use liquid cooling-based coolers are known as one way of cooling a semiconductor module that generates heat during operation. As one example, a semiconductor module is cooled by distributing a predetermined coolant, such as water, inside the container (also referred to by names such as “water jacket”) of a cooler so that heat exchanging occurs between the semiconductor module, which is mounted on the outer surface of the cooler, and the distributed coolant.

However, an unbalanced flow distribution, where the flow of coolant inside a cooler is uneven, may occur depending on the internal structure of the container, such as the arrangement and shape of flow paths on the coolant inlet and outlet sides and the flow paths that connect the inlet and outlet sides. An unbalanced flow distribution that occurs in a cooler may cause differences in cooling efficiency between different parts of the semiconductor module, resulting in the risk that the semiconductor module may deteriorate in performance or fail due to overheating caused by a decrease in cooling efficiency.

To rectify an unbalanced flow distribution, one known technology provides openings or plates at predetermined positions on the flow paths of the cooler to adjust the flow rate of the coolant. However, when this technology is used, depending on the configuration provided to adjust the flow rate of the coolant, there may be an increase in the pressure loss of the coolant introduced into and discharged from the cooler, resulting in the risk of an increased load on a pump that circulates the coolant within the cooler.

### SUMMARY OF THE INVENTION

According to one aspect, there is provided a cooler, including: a container that includes a first side wall having an inlet for a coolant and a second side wall having an outlet for the coolant; a first flow path that is disposed parallel to the first side wall inside the container, and communicates with the inlet; a second flow path that is disposed parallel to the second side wall inside the container, and communicates with the outlet; a third flow path disposed inside the container and communicating with both the first flow path and the second flow path; a first flow rate adjusting member disposed inside the container between the first flow path and the third flow path; and a second flow rate adjusting member disposed inside the container between the second flow path and the third flow path, wherein the first flow rate adjusting member includes a first region and a second region, and has one or more openings through which the coolant flows from the first flow path to the third flow path, the first region having a first open area ratio that is a ratio of a total size of the one or more openings in the first region to a size of the first region, the second region having a second open area ratio that is a ratio of a total size of the one or more openings in the second region to a size of the second region that is smaller than the first open area ratio at the second region, and the second flow rate adjusting member includes a third region and a fourth region, and has one or more openings through which the coolant flows from the third flow path to the second flow path, the third region having a third open area ratio that is a ratio of a total size of the one or more openings in the third region to a size of the third region, the fourth region having a fourth open area ratio that is a ratio of a total size of the one or more openings in the fourth region to a size of the fourth region that is larger than the third open area ratio.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 depicts one example of a semiconductor device and a cooling system according to a first embodiment;

FIG. 2 depicts one example of the semiconductor device according to the first embodiment;

FIGS. 3A and 3B depict an example configuration of the cooling fins provided on a heat dissipating plate of a cooler according to the first embodiment;

FIGS. 4A and 4B depict an example configuration of the container of a cooler according to the first embodiment;

FIG. 5 depicts an example configuration of a first flow rate adjusting member and a second flow rate adjusting member of a cooler according to the first embodiment;

FIG. 6 is a first diagram useful in explaining one example configuration of a cooler according to the first embodiment;

FIG. 7 is a second diagram useful in explaining one example configuration of a cooler according to the first embodiment;

FIGS. 8A and 8B are third diagrams useful in explaining one example configuration of a cooler according to the first embodiment;

FIG. 9 is a first diagram useful in explaining an example configuration of a cooler according to a comparative example;

FIG. 10 is a second diagram useful in explaining an example configuration of a cooler according to a comparative example;

FIG. 11 is a third diagram useful in explaining an example configuration of a cooler according to a comparative example;

FIG. 12 depicts example evaluation results of the coolant flow rates at semiconductor element positions;

FIG. 13 depicts example evaluation results of pressure loss in each type of cooler;

FIG. 14 depicts example evaluation results of semiconductor element temperature with respect to semiconductor element positions;

FIGS. 15A and 15B depict a first modification of cooling fins provided on a heat dissipating plate of a cooler;

FIGS. 16A and 16B depict a second modification of cooling fins provided on a heat dissipating plate of a cooler;

FIGS. 17A and 17B depict a third modification of cooling fins provided on a heat dissipating plate of a cooler;

FIG. 18 depicts a first modification of a container of a cooler according to a second embodiment;

FIG. 19 depicts a second modification of a container of a cooler according to the second embodiment;

FIG. 20 depicts a third modification of a container of a cooler according to the second embodiment;

FIG. 21 depicts a fourth modification of a container of a cooler according to the second embodiment;

FIG. 22 depicts a first modification of a first flow rate adjusting member and a second flow rate adjusting member of a cooler according to a third embodiment;

FIG. 23 depicts a second modification of a first flow rate adjusting member and a second flow rate adjusting member of a cooler according to the third embodiment;

FIG. 24 depicts a third modification of a first flow rate adjusting member and a second flow rate adjusting member of a cooler according to the third embodiment;

FIGS. 25A to 25F depict a first example of a cooler according to a fourth embodiment;

FIGS. 26A to 26C depict evaluation results produced by thermal fluid simulations of a first example cooler that uses prismatic cooling fins;

FIGS. 27A to 27C depict evaluation results produced by thermal fluid simulations of a first example cooler that uses cylindrical cooling fins;

FIGS. 28A to 28F depict a second example of a cooler according to the fourth embodiment;

FIGS. 29A to 29C depict evaluation results produced by thermal fluid simulations of a second example cooler that uses prismatic cooling fins;

FIGS. 30A to 30C depict evaluation results produced by thermal fluid simulations of a second example cooler that uses cylindrical cooling fins;

FIGS. 31A to 31F depict a third example of a cooler according to the fourth embodiment;

FIGS. 32A to 32C depict evaluation results produced by thermal fluid simulations of a third example cooler that uses prismatic cooling fins;

FIGS. 33A to 33C depict evaluation results produced by thermal fluid simulations of a third example cooler that uses cylindrical cooling fins;

FIGS. 34A to 34F depict a fourth example of a cooler according to the fourth embodiment;

FIGS. 35A to 35C depict evaluation results produced by thermal fluid simulations of a fourth example cooler that uses prismatic cooling fins;

FIGS. 36A to 36C depict evaluation results produced by thermal fluid simulations of a fourth example cooler that uses cylindrical cooling fins;

FIGS. 37A to 37F depict a fifth example of a cooler according to the fourth embodiment;

FIGS. 38A to 38C depict evaluation results produced by thermal fluid simulations of a fifth example cooler that uses prismatic cooling fins; and

FIGS. 39A to 39C depict evaluation results produced by thermal fluid simulations of a fifth example cooler that uses cylindrical cooling fins.

### DETAILED DESCRIPTION OF THE INVENTION

Several embodiments will be described below with reference to the accompanying drawings. Note that in the following description, the expression “upward” refers to a direction toward the top when looking from the plane of the drawing. The expressions “above” and “side surface” are merely convenient expressions for specifying relative positional relationships and do not limit the technical scope of the present embodiments. The expression “main component” in the following description indicates a case where a component composes 80 vol % or higher. The expression “the same” includes values within a range of ±10%. The expression “parallel” too may include directions that are within ±10% of parallel.

### First Embodiment

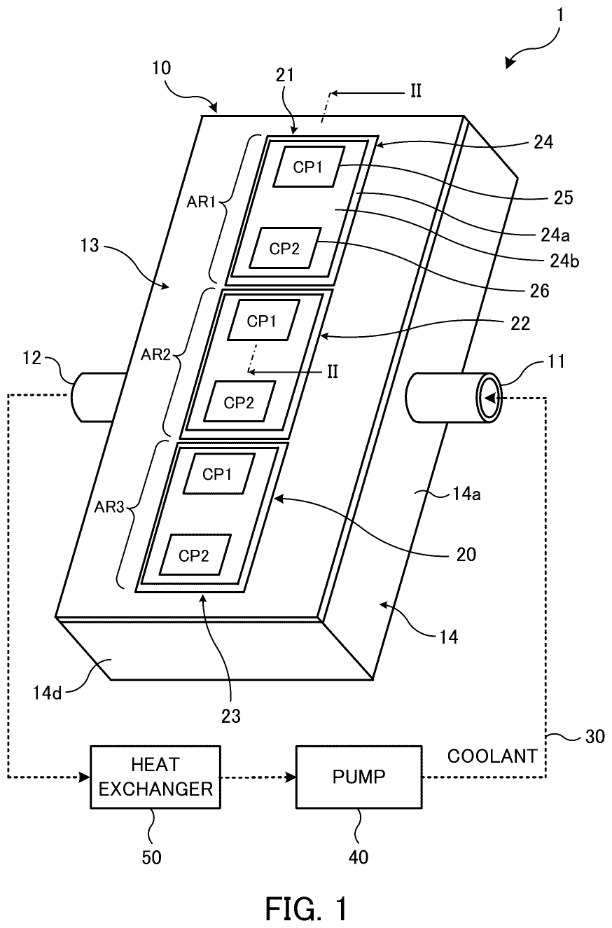

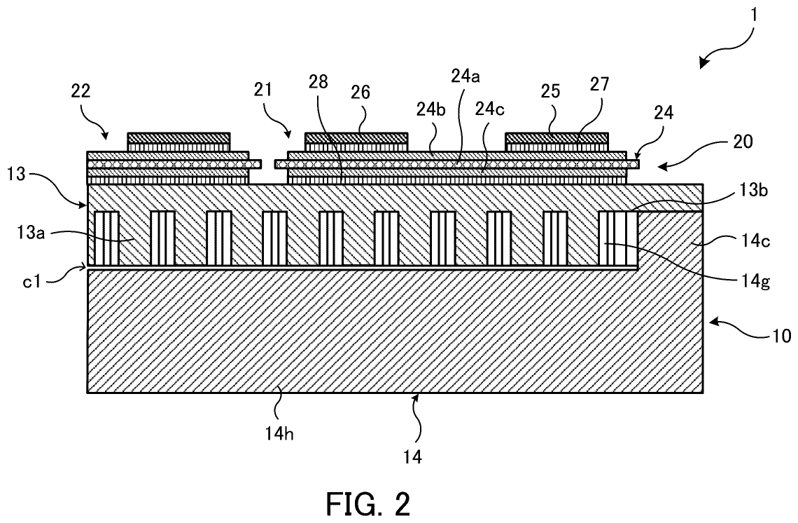

FIG. 1 depicts one example of a semiconductor device and a cooling system according to a first embodiment. FIG. 1 is a perspective view of a principal part of one example of a semiconductor device according to the first embodiment, schematically depicted together with some elements of a cooling system. FIG. 2 depicts one example of the semiconductor device according to the first embodiment.

FIG. 2 is a schematic cross-sectional view of a principal part of one example of a semiconductor device according to the first embodiment. FIG. 2 is a cross-sectional view taken along a line II-II in FIG. 1.

The semiconductor device 1 depicted in FIGS. 1 and 2 includes a cooler 10 and a semiconductor module 20 mounted on the cooler 10.

As depicted in FIG. 1, the semiconductor module 20 includes a circuit element portion 21, a circuit element portion 22, and a circuit element portion 23 mounted in three different mounting areas AR1, AR2, and AR3, respectively, on the cooler 10. The circuit element portion 21, the circuit element portion 22, and the circuit element portion 23 each include an insulated circuit board 24 and a semiconductor element 25 (also referred to as “CP1”) and a semiconductor element 26 (also referred to as “CP2”) that are mounted on the insulated circuit board 24).

As depicted in FIGS. 1 and 2, the insulated circuit board 24 includes an insulating substrate 24a, and a conductive layer 24b and a conductive layer 24c provided on both surfaces of the insulating substrate 24a. As the insulating substrate 24a, a substrate made of alumina, a composite ceramic containing alumina as a main component, aluminum nitride, silicon nitride, or the like is used. A metal material, such as copper or aluminum, is used for the conductive layer 24b and the conductive layer 24c. As one example, a direct copper bonding (DCB) board is used as the insulated circuit board 24. Other substrates, such as an active metal brazed (AMB) substrate, may be used as the insulated circuit board 24.

As one example, power semiconductor elements are used for the semiconductor element 25 and the semiconductor element 26. A switching element, such as an insulated gate bipolar transistor (IGBT) or a metal oxide semiconductor field effect transistor (MOSFET), is used for each of the semiconductor element 25 and the semiconductor element 26. A diode element, such as a freewheeling diode (FWD) or a Schottky barrier diode (SBD) may be connected to or integrated in the respective switch elements used in the semiconductor element 25 and the semiconductor element 26. As one example, reverse conducting insulated gate bipolar transistors (or “RC-IGBT”) are used as the semiconductor element 25 and the semiconductor element 26.

As depicted in FIGS. 1 and 2, the semiconductor element 25 and the semiconductor element 26 are mounted on a conductive layer 24b side provided on one surface of the insulated circuit board 24, and are electrically connected via a bonding layer 27, such as solder, or wires (not illustrated) to the conductive layer 24b. Note that although not illustrated in detail here, the conductive layer 24b of the insulated circuit board 24 is provided on the insulating substrate 24a in a predetermined pattern so as to realize predetermined circuit functions together with the semiconductor element 25, the semiconductor element 26, and the like mounted on the conductive layer 24b.

As one example, the semiconductor element 25 and the semiconductor element 26 are connected in series on the conductive layer 24b side of the insulated circuit board 24, and are mounted on the conductive layer 24b side of the insulated circuit board 24 so as to function as an inverter circuit. As one example, the semiconductor element 25 is mounted so as to construct an upper arm of the inverter circuit, and the semiconductor element 26 is mounted so as to construct the lower arm of the inverter circuit. A junction node between the semiconductor element 25 and the semiconductor element 26 that are connected in series is used as an output.

The three circuit element portions 21, 22, and 23 with the respective configurations described above are connected in parallel on the conductive layer 24b side of the insulated circuit board 24. As one example, the respective outputs of the circuit element portion 21, the circuit element portion 22, and the circuit element portion 23 correspond to U-phase, V-phase, and W-phase outputs, and are connected to a three-phase AC motor. By controlling the switching of the semiconductor elements 25 and 26 of each of the circuit element portion 21, the circuit element portion 22, and the circuit element portion 23, direct current is converted to alternating current to drive the three-phase AC motor.

A conductive layer 24c side, which is the opposite side of each insulated circuit board 24 to the conductive layer 24b side on which the semiconductor element 25 and the semiconductor element 26 are mounted, of each of the circuit element portion 21, the circuit element portion 22, and the circuit element portion 23 of the semiconductor module 20 is thermally connected via a bonding layer 28 to the cooler 10.

The cooler 10 on which the semiconductor module 20 is mounted includes a heat dissipating plate 13 (also referred to simply as a “fin base”) provided with cooling fins 13a (also referred to simply as “fins”), and a container 14 (also referred to as a “water jacket”). The circuit element portion 21, the circuit element portion 22, and the circuit element portion 23 of the semiconductor module 20 are thermally connected via the bonding layer 28 to the heat dissipating plate 13 of the cooler 10.

The heat dissipating plate 13 provided with the cooling fins 13a functions as a heat sink. The container 14 is connected to the heat dissipating plate 13 by bolts for example (not illustrated) so as to cover the cooling fins 13a provided on the heat dissipating plate 13. The container 14 is connected to the heat dissipating plate 13 so that the cooling fins 13a of the heat dissipating plate 13 are housed inside the container 14. The container 14 functions as a fin cover.

Coolant 30 supplied from outside is distributed to an internal space between the heat dissipating plate 13 and the container 14 inside the cooler 10 on which the semiconductor module 20 is mounted, that is, to the gaps between the container 14 and the heat dissipating plate 13 and cooling fins 13a. Water, long life coolant (LLC), or the like is used as the coolant 30. The cooler 10 is provided with an inlet 11 and an outlet 12 for the coolant 30. The coolant 30 introduced from the inlet 11 flows through coolant flow paths (or “third flow paths” 14g), which are defined by the cooling fins 13a and are internal spaces between the heat dissipating plate 13 and the container 14 of the cooler 10, and is discharged from the outlet 12.

When the cooler 10 is used, the inlet 11 is connected via piping to a pump 40 and the outlet 12 is connected via piping to a heat exchanger 50. The coolant 30 is introduced into the container 14 from the inlet 11 by the pump 40, flows through the container 14, and is discharged from the outlet 12. Heat generated at the circuit element portion 21, the circuit element portion 22, and the circuit element portion 23 of the semiconductor module 20 is transferred to the heat dissipating plate 13 of the cooler 10 and its cooling fins 13a, and heat exchanging occurs with the coolant 30 flowing inside the container 14 covering the cooling fins 13a. This results in the circuit element portion 21, the circuit element portion 22, and the circuit element portion 23 being cooled. The coolant 30 whose temperature has risen by cooling the circuit element portion 21, the circuit element portion 22, and the circuit element portion 23 is discharged from the outlet 12. The coolant 30 discharged from the outlet 12 is sent to the heat exchanger 50 and is cooled. The coolant 30 that has been cooled by the heat exchanger 50 is sent back to the inlet 11 by the pump 40 that is connected via piping to the heat exchanger 50, and is introduced into the container 14 from the inlet 11.

In a cooling system including the semiconductor device 1 equipped with the cooler 10, the pump 40, the heat exchanger 50, and the like, a coolant flow path is constructed so that the coolant 30 flows in a closed loop including the cooler 10, the pump 40, and the heat exchanger 50. The coolant 30 is forcibly circulated in this closed loop by the pump 40. The semiconductor module 20 of the semiconductor device 1 is cooled by this forcibly circulated coolant 30.

Note that since the arrangement of the inlet 11 and the outlet 12 of the cooler 10 is restricted by not only the routing of the piping that connects the inlet 11 and the outlet 12 to the pump 40 and the heat exchanger 50 but also by factors such as clearances between the semiconductor device 1 and surrounding parts of the cooling system including the semiconductor device 1, various arrangements may be used. The arrangement of the inlet 11 and the outlet 12 depicted in FIG. 1 is one example of such an arrangement.

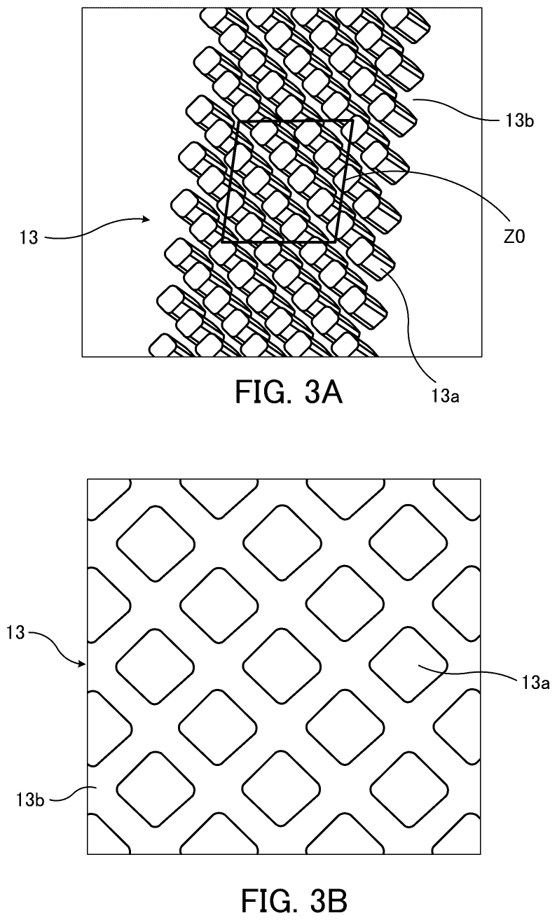

One example configuration of the semiconductor device 1 will now be described further with reference to FIGS. 3A to 8B.

First, the heat dissipating plate 13 of the cooler 10 and the cooling fins 13a provided on the heat dissipating plate 13 will be described with reference to FIGS. 3A and 3B.

FIGS. 3A and 3B depict an example configuration of the cooling fins provided on the heat dissipating plate of a cooler according to the first embodiment.

FIG. 3A is a perspective view that schematically depicts a principal part of example cooling fins provided on a heat dissipating plate of a cooler according to the first embodiment, and FIG. 3B is a plan view that schematically depicts a principal part of example cooling fins provided on a heat dissipating plate of a cooler according to the first embodiment. FIG. 3B is an enlarged plan view of a part marked “Z0” in FIG. 3A.

As depicted in FIGS. 3A and 3B, as one example, the cooling fins 13a are provided on the heat dissipating plate 13 of the cooler 10 as pin fins that are pin-shaped and are arranged in a lattice. As another example, the cooling fins 13a are prismatic or are substantially prismatic with chamfered corners. As one example, end faces (or the cross-sectional shapes) of the cooling fins 13a are rectangular or substantially rectangular with the length of one side in a range of 1 mm to 3 mm, and the height from a mounting surface 13b of the heat dissipating plate 13 is in a range of 2 mm to 10 mm. As one example, on the mounting surface 13b of the heat dissipating plate 13, the plurality of cooling fins 13a have sides that are 3 mm long and are arranged in a lattice so that the gaps between adjacent cooling fins 13a are 1.5 mm. As one example, cooling fins 13a such as those depicted in FIGS. 3A and 3B are provided on the heat dissipating plate 13 of a cooler 10 such as that depicted in FIGS. 1 and 2. Note that the shapes and dimensions of the cooling fins 13a depicted in FIGS. 3A and 3B are mere examples, and the optimal shape and dimensions are selected depending on the desired cooling performance.

The cooling fins 13a are integrated with the heat dissipating plate 13. A metal material, such as aluminum, aluminum alloy, copper, or copper alloy, is used for the heat dissipating plate 13 and the cooling fins 13a. The cooling fins 13a are integrally manufactured with the heat dissipating plate 13 by die-casting, brazing, or various welding techniques. Alternatively, the cooling fins 13a may be integrally formed with the heat dissipating plate 13 using a machining technique for forming projecting cooling fins 13a from the same material as the heat dissipating plate 13 by die casting, forging or pressing, or a machining technique that forms projecting cooling fins 13a from the same material as the heat dissipating plate 13 by cutting or wire cutting.

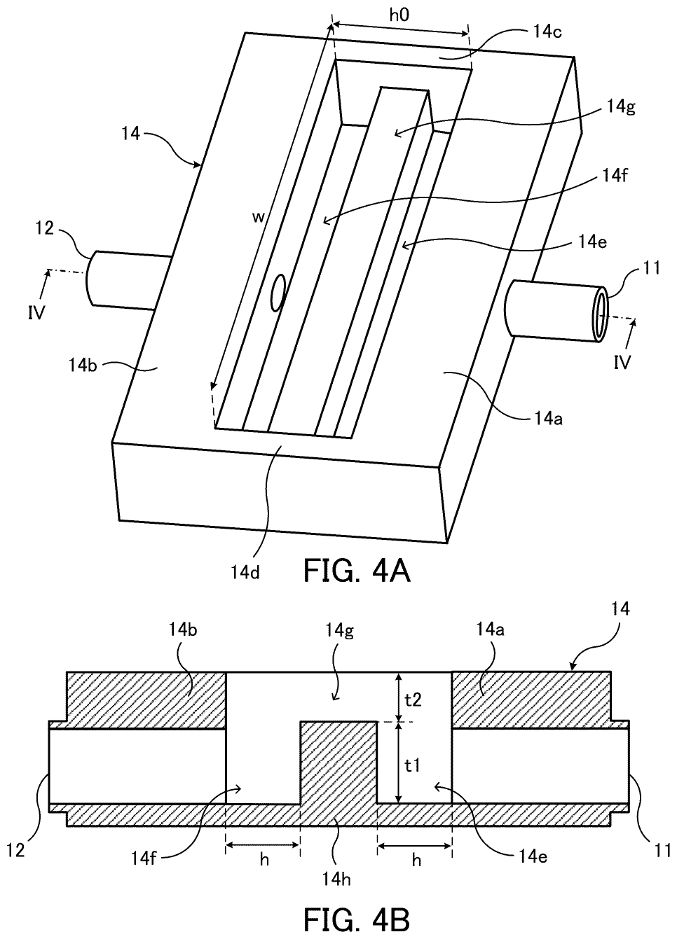

Next, the container 14 of the cooler 10 will be described with reference to FIGS. 4A and 4B.

FIGS. 4A and 4B depict an example configuration of the container of a cooler according to the first embodiment. FIG. 4A is a schematic perspective view of the principal part of an example container of a cooler according to the first embodiment and FIG. 4B is a schematic cross-sectional view of the principal part of an example container of a cooler according to the first embodiment. FIG. 4B is a cross-sectional view taken along a line IV-IV in FIG. 4A.

As one example, the external shape of the container 14 is a rectangular parallelepiped or an approximately rectangular parallelepiped as depicted in FIGS. 4A and 4B. The container 14 includes a first side wall 14a and a second side wall 14b that face each other, and a third side wall 14c and a fourth side wall 14d that face each other. The first side wall 14a, the second side wall 14b, the third side wall 14c, and the fourth side wall 14d are erected on and extend from one surface of the bottom plate 14h. As one example, the inlet 11 is disposed in one side wall out of the first side wall 14a and the second side wall 14b that face each other, in this example, the first side wall 14a, and the outlet 12 is disposed in the other side wall, that is, the second side wall 14b.

Inside the container 14, a first flow path 14e is disposed in parallel with the first side wall 14a so as to communicate with the inlet 11. The first flow path 14e is a first channel (groove) that extends along the first side wall 14a on a bottom portion of the container 14 between the first side wall 14a and the second side wall 14b.

Inside the container 14, a second flow path 14f is disposed in parallel with the second side wall 14b so as to communicate with the outlet 12. The second flow path 14f is a second channel (groove) that extends along the second side wall 14b at a bottom portion of the container 14 between the first side wall 14a and the second side wall 14b. The second flow path 14f extends in parallel with the first flow path 14e. The first flow path 14e is apart from the second flow path 14f by a protrusion protruding upward and extending therebetween along the first and second flow paths 14e, 14f at the bottom plate 14h of the container 14.

A third flow path 14g that communicates with the first flow path 14e and the second flow path 14f is also disposed inside the container 14. The third flow path 14g is an internal space that is above the first flow path 14e (or “first channel”) and the second flow path 14f (or “second channel”) out of the internal space of the container 14. As described later, a first flow rate adjusting member (first flow rate adjusting member) 15 is disposed at the boundary between the third flow path 14g and the first flow path 14e, and a second flow rate adjusting member (second flow rate adjusting member) 16 is disposed at the boundary between the third flow path 14g and the second flow path 14f. The cooling fins 13a of the heat dissipating plate 13 described above that is connected so as to cover the container 14 are disposed and housed in the third flow path 14g, which is an internal space above the first flow path 14e and the second flow path 14f (see FIG. 1 and FIG. 2).

A length w (also referred to as the length w of the first flow path 14e and the second flow path 14f) and width h0 of an internal space surrounded by the first side wall 14a, the second side wall 14b, the third side wall 14c, and the fourth side wall 14d of the container 14, a width h and height t1 of the first flow path 14e and the second flow path 14f, and a height t2 of the third flow path 14g are set as appropriate based on the dimensions of the semiconductor module 20, the dimensions of the semiconductor device 1, the desired cooling performance, and the like.

The container 14 is made of a metal material such as aluminum, aluminum alloy, copper, or copper alloy. When a metal material is used, the first flow path 14e, the second flow path 14f, and the third flow path 14g are formed in the container 14 by die casting, for example. The inlet 11 and the outlet 12 of the container 14 are formed by cutting, for example. The container 14 is not limited to a metal material, and other materials may be used so long as they have sufficient corrosion resistance and heat resistance for the coolant 30 that flows inside the container 14. As one example, the container 14 may be made of a material containing a carbon filler. Depending on the type, temperature, and the like of the coolant 30 flowing through the container 14, a ceramic material, a resin material, or the like may also be used.

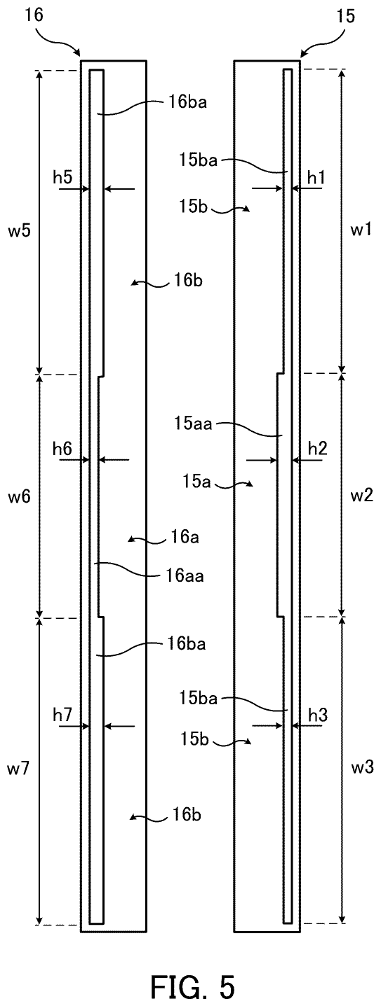

Next, the first flow rate adjusting member 15 and the second flow rate adjusting member 16 disposed in the container 14 will be described with reference to FIG. 5.

FIG. 5 depicts an example configuration of a first flow rate adjusting member and a second flow rate adjusting member of a cooler according to the first embodiment. FIG. 5 is a schematic plan view of a principal part of examples of the first flow rate adjusting member and the second flow rate adjusting member of the cooler according to the first embodiment.

A first flow rate adjusting member 15 and a second flow rate adjusting member 16 like those depicted in FIG. 5 are disposed in the first flow path 14e and the second flow path 14f respectively of the container 14 depicted in FIGS. 4A and 4B described above.

The first flow rate adjusting member 15 is formed of a plate-like member for example, and is arranged in parallel with and separated from the bottom surface of the first flow path 14e (or “first channel”). The first flow rate adjusting member 15 is connected to and fixed to the first side wall 14a so as to cover the first flow path 14e of the container 14, for example. The first flow rate adjusting member 15 is provided with an opening to allow the coolant 30 to flow from the first flow path 14e into the third flow path 14g.

The first flow rate adjusting member 15 includes a first region 15a in which a first slit 15aa with a first width h2 is provided as an opening and second regions 15b in which second slits 15ba with second widths h1 and h3 are provided as openings. As one example, out of a group of regions obtained by dividing the first flow rate adjusting member 15 into three in a length direction thereof (which corresponds to the direction in which the first flow path 14e extends along the first side wall 14a), the center region is set as the first region 15a and the remaining two regions to the outside are set as the second regions 15b. The first flow rate adjusting member 15 depicted in FIG. 5 is configured with a first region 15a in the center sandwiched between the two second regions 15b on the outside. The first region 15a has a first length in the length direction of w2, and the two second regions 15b have second lengths in the length direction of w1 and w3. Note that the total length in the length direction of the first flow rate adjusting member 15 is assumed to be the length w of the internal space of the container 14 depicted in FIG. 4A described above (that is, the length w of the first flow path 14e). The first length w2 of the first region 15a and the second lengths w1 and w3 of the second regions 15b are each set at approximately ⅓ of the length w, which is the entire length of the first flow rate adjusting member 15.

The first width h2 of the first slit 15aa in the first region 15a and the second widths h1 and h3 of the second slits 15ba in the second regions 15b are set in a range of 1 mm to 3 mm. The first width h2 of the first slit 15aa in the first region 15a and the second widths h1 and h3 of the second slits 15ba in the second regions 15b are set at different widths from each other. Note that although the second widths h1 and h3 of the second slits 15ba in the second regions 15b are set at the same width in this example, it is also possible for the slits to have respectively different widths. In the example in FIG. 5, the first width h2 of the first slit 15aa in the first region 15a is set wider than the second widths h1 and h3 of the second slits 15ba in the second regions 15b.

The first region 15a of the first flow rate adjusting member 15 in which the first slit 15aa is provided has a first aperture ratio (first open area ratio) and the second regions 15b where the second slits 15ba are provided have a second aperture ratio (second open area ratio) that is smaller than the first aperture ratio of the first region 15a. Here, the expression “first aperture ratio” for the first region 15a is the ratio of the opening in the first region 15a provided by the first slit 15aa per unit area. Similarly, the expression “second aperture ratio” for the second region 15b is the ratio of the opening in the second region 15b provided by each second slit 15ba per unit area.

The first slit 15aa and the second slits 15ba of the first flow rate adjusting member 15 are disposed at an end portion on one side out of the two end portions that extend along the length direction, that is, the end portion that will be positioned on the first side wall 14a side when the first flow rate adjusting member 15 has been disposed to cover the first flow path 14e of the container 14. Note that although the first slit 15aa and the second slits 15ba are formed continuously, the first slit 15aa and the second slits 15ba may be split at boundary parts between them.

The second flow rate adjusting member 16 is formed of a plate-like member for example, and is arranged in parallel with and separated from the bottom surface of the second flow path 14f (or “second channel”). The second flow rate adjusting member 16 is connected to and fixed to the second side wall 14b so as to cover the second flow path 14f of the container 14, for example. The second flow rate adjusting member 16 is provided with an opening to allow the coolant 30 to flow from the third flow path 14g into the second flow path 14f.

The second flow rate adjusting member 16 includes a third region 16a in which a third slit 16aa with a third width h6 is provided as an opening and fourth regions 16b in which fourth slits 16ba with fourth widths h5 and h7 are provided as openings. As one example, out of a group of regions obtained by dividing the second flow rate adjusting member 16 into three in a length direction thereof (which corresponds to the direction in which the second flow path 14f extends along the second side wall 14b), the center region is set as the third region 16a and the remaining two regions to the outside are set as the fourth regions 16b. The second flow rate adjusting member 16 depicted in FIG. 5 is configured with the third region 16a in the center sandwiched between the two fourth regions 16b on the outside.

The third region 16a has a third length in the length direction of w6, and the two fourth regions 16b have fourth lengths in the length direction of w5 and w7. Note that the total length in the length direction of the second flow rate adjusting member 16 is assumed to be the length w of the internal space of the container 14 depicted in FIG. 4A described above (that is, the length w of the second flow path 14f). The third length w6 of the third region 16a and the fourth lengths w5 and w7 of the fourth regions 16b are each set at approximately ⅓ of the length w, which is the entire length of the second flow rate adjusting member 16.

The third width h6 of the third slit 15aa in the third region 16a and the fourth widths h5 and h7 of the fourth slits 16ba in the fourth regions 16b are set in a range of 1 mm to 3 mm. The third width h6 of the third slit 16aa in the third region 16a and the fourth widths h5 and h7 of the fourth slits 16ba in the fourth regions 16b are set at different widths from each other. Note that although the fourth widths h5 and h7 of the fourth slits 16ba in the fourth regions 16b are set at the same width in this example, it is also possible for the slits to have respectively different widths. In the example in FIG. 5, the third width h6 of the third slit 16aa in the third region 16a is set narrower than the fourth widths h5 and h7 of the fourth slits 16ba in the fourth regions 16b.

The third region 16a of the second flow rate adjusting member 16 in which the third slit 16aa is provided has a third aperture ratio (third open area ratio) and the fourth regions 16b where the fourth slits 16ba are provided have a fourth aperture ratio (fourth open area ratio) that is larger than the third aperture ratio of the third region 16a. Here, the expression “third aperture ratio” for the third region 16a is the ratio of the opening in the third region 16a provided by the third slit 16aa per unit area. Similarly, the expression “fourth aperture ratio” for the fourth regions 16b is the ratio of the opening in the fourth region 16b provided by each fourth slit 16ba per unit area.

The third slit 16aa and the fourth slits 16ba of the second flow rate adjusting member 16 are disposed at an end portion on one side out of the two end portions that extend along the length direction, that is, the end portion that will be positioned on the second side wall 14b side when the second flow rate adjusting member 16 has been disposed to cover the second flow path 14f of the container 14. Note that although the third slit 16aa and the fourth slits 16ba are formed continuously, the third slit 16aa and the fourth slits 16ba may be split at boundary parts between them.

The first flow rate adjusting member 15 and the second flow rate adjusting member 16 are disposed in the container 14 of the cooler 10 so that the first region 15a and the third region 16a, that is, the first region 15a, which is provided with the comparatively wide first slit 15aa and therefore has a comparatively large aperture ratio, and the third region 16a, which is provided with the comparatively narrow third slit 16aa and therefore has a comparatively small aperture ratio, face each other. The first flow rate adjusting member 15 and the second flow rate adjusting member 16 are also disposed in the container 14 of the cooler 10 so that the second regions 15b and the fourth regions 16b, that is, the second regions 15b, which are provided with the comparatively narrow second slits 15ba and therefore have a comparatively small aperture ratio, and the fourth regions 16b, which are provided with the comparatively wide fourth slits 16ba and therefore have a comparatively large aperture ratio, face each other.

For the first flow rate adjusting member 15, the first length w2 of the first region 15a, the first width h2 of the first slit 15aa of the first region 15a, the second lengths w1 and w3 of the second regions 15b, the second widths h1 and h3 of the second slits 15ba of the second region 15b, and for the second flow rate adjusting member 16, the third length w6 of the third region 16a, the third width h6 of the third slit 16aa of the third region 16a, the fourth lengths w5 and w7 of the fourth regions 16b, and the fourth widths h5 and h7 of the fourth slits 16ba of the fourth regions 16b are set as appropriate based on the dimensions of the container 14 of the cooler 10, as examples, the dimensions of the first flow path 14e and the second flow path 14f, and other factors such as the desired cooling performance.

The first flow rate adjusting member 15 and the second flow rate adjusting member 16 are formed by die casting, pressing, or the like. The first flow rate adjusting member 15 is integrated with the container 14 so as to cover the first flow path 14e of the container 14 by being connected to a side wall of the first flow path 14e (that is, at least one out of the first side wall 14a, the third side wall 14c, the fourth side wall 14d, and a side wall on an opposite side of the first flow path 14e to the first side wall 14a) by using brazing or various welding techniques. The second flow rate adjusting member 16 is integrated with the container 14 so as to cover the second flow path 14f of the container 14 by being connected to a side wall of the second flow path 14f (that is, at least one out of the second side wall 14b, the third side wall 14c, the fourth side wall 14d, and a side wall on an opposite side of the second flow path 14f to the second side wall 14b) by using brazing or various welding techniques.

Note that aside from plate-like members, the first flow rate adjusting member 15 and the second flow rate adjusting member 16 may each include a cylindrical member formed to match the channel shapes of the first flow path 14e and the second flow path 14f of the container 14. The first slit 15aa and the second slits 15ba are formed by cutting or the like at predetermined positions on one side surface of a cylindrical member used as the first flow rate adjusting member 15. Likewise, the third slit 16aa and the fourth slits 16ba are formed by cutting or the like at predetermined positions on one side surface of a cylindrical member used as the second flow rate adjusting member 16. A container 14 which has been integrated with the first flow rate adjusting member 15 and the second flow rate adjusting member 16 may be obtained by fitting such cylindrical members used as the first flow rate adjusting member 15 and the second flow rate adjusting member 16 into the first flow path 14e and the second flow path 14f of the container 14.

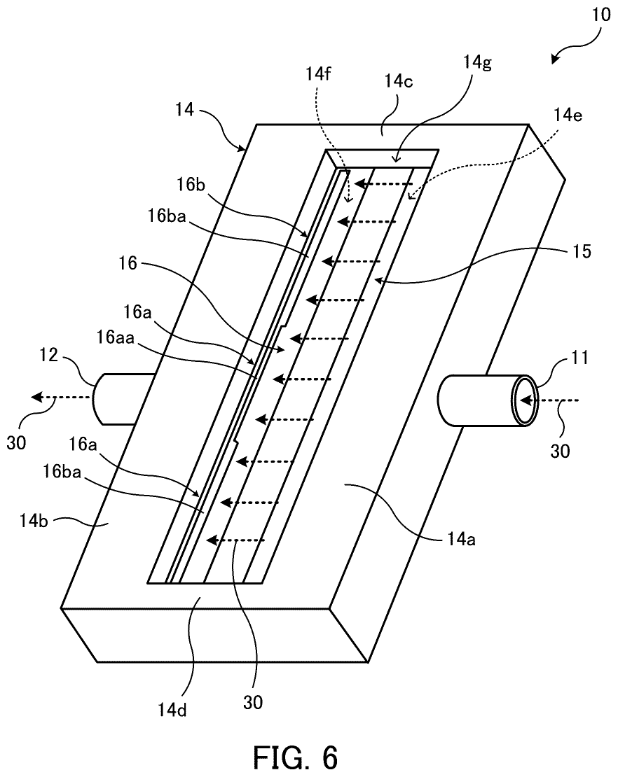

Next, the cooler 10 where the first flow rate adjusting member 15 and the second flow rate adjusting member 16 have been integrated with the container 14 will be described with reference to FIGS. 6 to 8B.

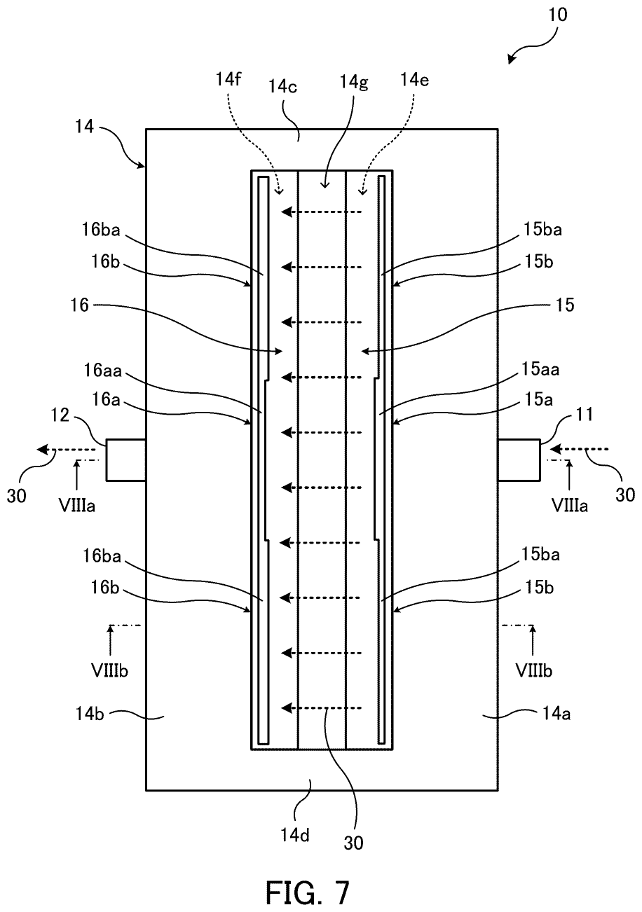

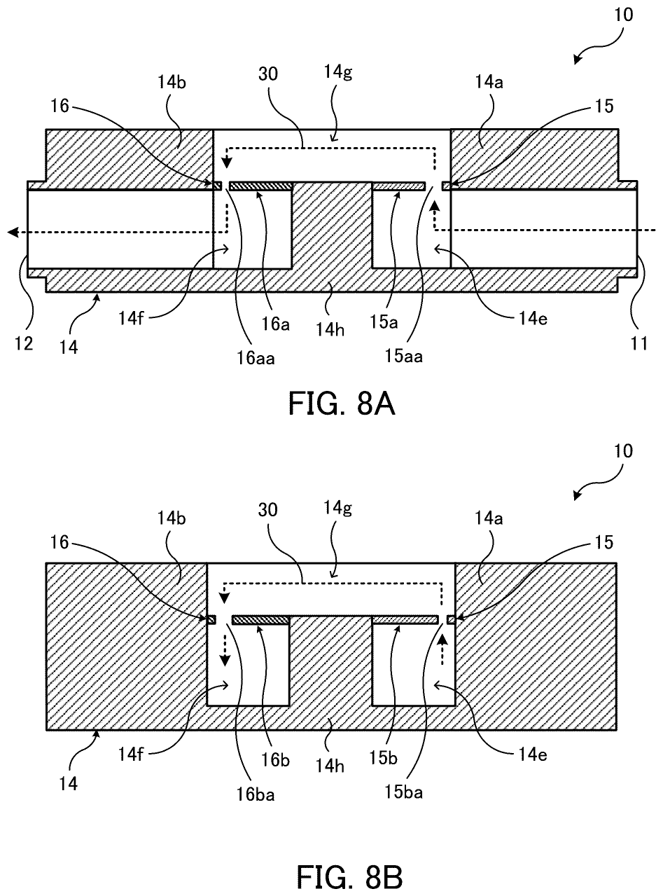

FIGS. 6 to 8B are diagrams useful in explaining example configurations of a cooler according to the first embodiment. FIG. 6 is a schematic perspective view of a principal part of one example of a cooler according to the first embodiment. FIG. 7 is a schematic plan view of a principal part of one example of a cooler according to the first embodiment. FIGS. 8A and 8B are schematic cross-sectional views of a principal part of one example of a cooler according to the first embodiment. FIG. 8A is a cross-sectional view taken along a line VIIIa-VIIIa in FIG. 7, and FIG. 8B is a cross-sectional view taken along a line VIIIb-VIIIb in FIG. 7.

A first flow rate adjusting member 15 and a second flow rate adjusting member 16 like those depicted in FIG. 5 described above are disposed in and connected to the container 14 (or “water jacket”) like that depicted in FIGS. 4A and 4B described above to produce a cooler 10 like that depicted in FIGS. 6, 7, 8A, and 8B. Note that the cooler 10 depicted in FIGS. 6, 7, 8A, and 8B omits the heat dissipating plate 13 (or “fin base”) on which the cooling fins 13a are provided like that depicted in FIGS. 1 and 2 described earlier. In FIGS. 6, 7, 8A, and 8B, the flow of the coolant 30 is schematically indicated using dotted arrows.

The first flow rate adjusting member 15 is disposed so as to cover the first flow path 14e of the container 14, which extends along the first side wall 14a. The first flow rate adjusting member 15 is disposed so that the openings, that is, the first slit 15aa in the first region 15a and the second slits 15ba in the second regions 15b are positioned on the end portion of the first flow rate adjusting member 15 located on the first side wall 14a side of the container 14. It may also be said that the first slit 15aa in the first region 15a and the second slits 15ba in the second regions 15b are positioned at an end portion of the first flow rate adjusting member 15 on the first side wall 14a side of the first flow path 14e. Out of a group of the regions produced by dividing the first flow path 14e into three in a direction that extends along the first side wall 14a, the center region corresponds to the first region 15a of the first flow rate adjusting member 15 and the remaining two regions to the outside correspond to the second regions 15b of the first flow rate adjusting member 15. The first slit 15aa is provided in the first region 15a, and the second slits 15ba that are narrower than the first slit 15aa are provided in the second regions 15b. The first region 15a has the first aperture ratio, and the second regions 15b have the second aperture ratio that is smaller than the first aperture ratio of the first region 15a.

The second flow rate adjusting member 16 is disposed so as to cover the second flow path 14f of the container 14, which extends along the second side wall 14b. The second flow rate adjusting member 16 is disposed so that the openings, that is, the third slit 16aa in the third region 16a and the fourth slits 16ba in the fourth regions 16b are positioned on the end portion of the second flow rate adjusting member 16 located on the second side wall 14b side of the container 14. It may also be said that the third slit 16aa in the third region 16a and the fourth slits 16ba in the fourth regions 16b are positioned at an end portion of the second flow rate adjusting member 16 on the second side wall 14b side of the second flow path 14f. Out of a group of the regions produced by dividing the second flow path 14f into three in a direction that extends along the second side wall 14b, the center region corresponds to the third region 16a of the second flow rate adjusting member 16 and the remaining two regions to the outside correspond to the fourth regions 16b of the second flow rate adjusting member 16. The third slit 16aa is provided in the third region 16a, and the fourth slits 16ba that are wider than the third slit 16aa are provided in the fourth regions 16b. The third region 16a has the third aperture ratio, and the fourth regions 16b have the fourth aperture ratio that is larger than the third aperture ratio of the third region 16a.

The first flow rate adjusting member 15 and the second flow rate adjusting member 16 are disposed in the container 14 so that the first region 15a that is provided with the comparatively wide first slit 15aa and has a comparatively large aperture ratio and the third region 16a that is provided with the comparatively narrow first slit 16aa and has a comparatively small aperture ratio face each other. The first flow rate adjusting member 15 and the second flow rate adjusting member 16 are also disposed in the container 14 so that the second regions 15b that are provided with the comparatively narrow second slits 15ba and have a comparatively small aperture ratio and the fourth regions 16b that are provided with the comparatively large fourth slits 16ba and have a comparatively large aperture ratio face each other.

In the example depicted in FIGS. 6, 7, 8A, and 8B, the first region 15a of the first flow rate adjusting member 15 that is provided with the comparatively wide first slit 15aa and has a comparatively large aperture ratio is disposed at a position that is closer to the inlet 11 of the coolant 30 that communicates with the first flow path 14e of the container 14 than the second regions 15b that are provided with the comparatively narrow second slits 15ba and have a comparatively small aperture ratio. In the example depicted in FIGS. 6, 7, 8A, and 8B, the third region 16a of the second flow rate adjusting member 16 that is provided with the comparatively narrow third slit 16aa and has a comparatively small aperture ratio is disposed at a position that is closer to the outlet 12 of the coolant 30 that communicates with the second flow path 14f of the container 14 than the fourth regions 16b that are provided with the comparatively wide fourth slits 16ba and have a comparatively large aperture ratio.

The third flow path 14g is formed in an internal space located above the first flow path 14e and the second flow path 14f in the container 14, in which the first flow path 14e is covered by the first flow rate adjusting member 15 and the second flow path 14f is covered by the second flow rate adjusting member 16. That is, the first flow rate adjusting member 15 is disposed at the boundary between the first flow path 14e and the third flow path 14g, and the second flow rate adjusting member 16 is disposed at the boundary between the second flow path 14f and the third flow path 14g. The first flow path 14e and the third flow path 14g communicate via the first slit 15aa and the second slits 15ba of the first flow rate adjusting member 15, and the second flow path 14f and the third flow path 14g communicate via the third slit 16aa and the fourth slits 16ba of the second flow rate adjusting member 16.

Although not depicted here, the heat dissipating plate 13 on which the cooling fins 13a are provided or the heat dissipating plate 13 that has a semiconductor module 20 disposed on the opposite side to the cooling fins 13a like those depicted in FIGS. 1, 2, and 3A and 3B is disposed so as to cover the internal space of the container 14. The heat dissipating plate 13 and the container 14 are fastened together and connected using bolts, for example. The cooling fins 13a of the heat dissipating plate 13 that has been connected to the container 14 are disposed so as to be housed inside the third flow path 14g of the container 14 as depicted in FIG. 2 described above. Note that the cooling fins 13a are provided so that when the heat dissipating plate 13 has been connected to the container 14, a certain amount of clearance cl (see FIG. 2) is provided between the front ends of the cooling fins 13a and the bottom surface of the third flow path 14g.

When the cooler 10 is used, the coolant 30 flows through the cooler 10 as indicated by the dotted arrows in FIGS. 6, 7, 8A, and 8B. When this happens, the coolant 30 supplied to the cooler 10 by the pump 40 (see FIG. 1) is introduced into the cooler 10 from the inlet 11. The coolant 30 introduced from the inlet 11 flows into the first flow path 14e of the container 14 that communicates with the inlet 11, and flows from the first flow path 14e through the comparatively wide first slit 15aa (see FIG. 8A) and the comparatively narrow second slits 15ba (see FIG. 8B) of the first flow rate adjusting member 15 into the third flow path 14g. The coolant 30 that has flowed into the third flow path 14g is transferred from the third flow path 14g through the comparatively narrow third slit 16aa (see FIG. 8A) and the comparatively wide fourth slits 16ba (see FIG. 8B) of the second flow rate adjusting member 16 and flows into the second flow path 14f of the container 14 that communicates with the outlet 12. The coolant 30 that has flowed into the second flow path 14f is discharged to the outside of the cooler 10 from the outlet 12.

The coolant 30 that has flowed from the first flow path 14e into the third flow path 14g flows on coolant flow paths defined by the cooling fins 13a housed inside the third flow path 14g, that is, in the gaps between adjacent cooling fins 13a. While the coolant 30 is flowing through the third flow path 14g, heat exchanging occurs so that heat that has been transferred from the semiconductor module 20 to the heat dissipating plate 13 and the cooling fins 13a is transferred to the coolant 30 flowing through the third flow path 14g, thereby cooling the semiconductor module 20. The coolant 30, whose temperature has increased due to heat exchanging with the heat dissipating plate 13 and the cooling fins 13a, flows into the second flow path 14f and is discharged to the outside of the cooler 10 from the outlet 12. After this, the coolant 30 that has been sent to the heat exchanger 50 (see FIG. 1) and whose temperature has fallen is introduced back into the cooler 10 from the inlet 11 by the pump 40.

According to the cooler 10 with the configuration described above, it is possible to suppress the occurrence of an unbalanced flow distribution and an increase in pressure loss for the coolant 30 flowing through the cooler 10. It is also possible to realize a semiconductor device 1 equipped with a cooler 10 that is capable of suppressing the occurrence of unbalanced flow distribution and an increase in pressure loss. This is explained in more detail below.

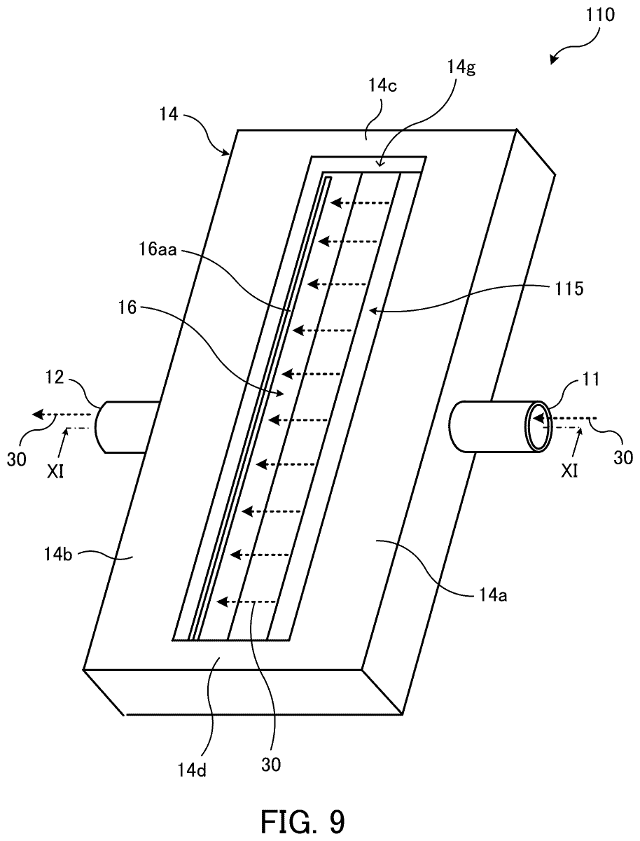

Here, a cooler like that depicted in FIGS. 9 to 11 and a semiconductor device equipped with this cooler will be used as a comparative example.

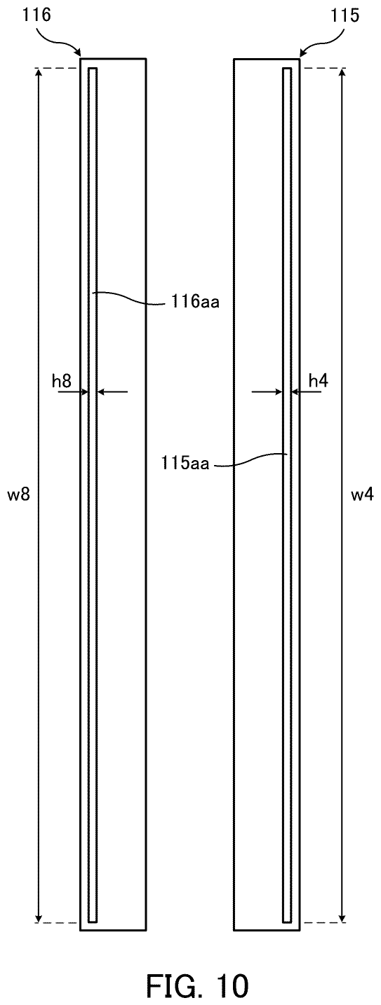

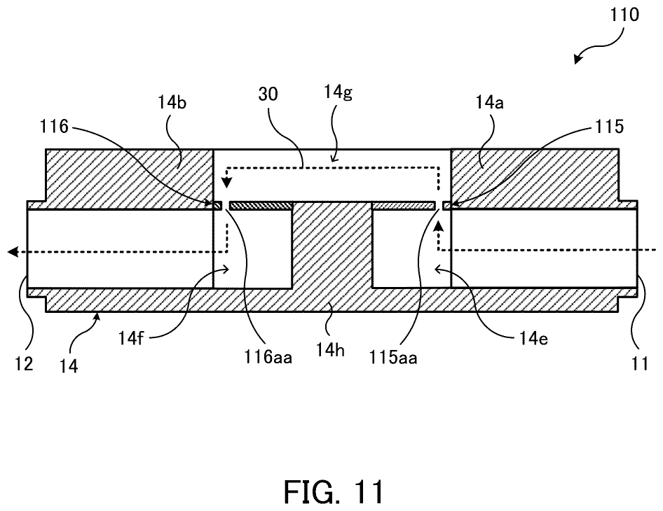

FIGS. 9 to 11 are diagrams useful in explaining an example configuration of a cooler according to a comparative example. FIG. 9 is a schematic perspective view of a principal part of one example of a cooler according to this comparative example. FIG. 10 is a schematic plan view of a principal part of a first flow rate adjusting member and a second flow rate adjusting member of a cooler according to a comparative example. FIG. 11 is a schematic cross-sectional view of a principal part of one example of a cooler according to a comparative example. FIG. 11 is a cross-sectional view taken along a line XI-XI in FIG. 9. In FIGS. 9 and 11, the flow of the coolant 30 is schematically indicated using dotted arrows.

The cooler 110 depicted in FIG. 9 differs from the cooler 10 according to the first embodiment described above by having a configuration in which a first flow rate adjusting member 115 and a second flow rate adjusting member 116 like those depicted in FIGS. 9 to 11 are disposed. The same configurations as the first embodiment are used as the container 14 of the cooler 110, and although not illustrated here, as the heat dissipating plate 13 that covers the container 14, the cooling fins 13a of the heat dissipating plate 13, and the semiconductor module 20 mounted on the heat dissipating plate 13.

As depicted in FIG. 10, the first flow rate adjusting member 115 of the cooler 110 of the comparative example is provided, as an opening, with a seventh slit 115aa with a length in the length direction of w4 and a constant width h4. As depicted in FIG. 10, the second flow rate adjusting member 116 of the cooler 110 of the comparative example is provided, as an opening, with an eighth slit 116aa with a length in the length direction of w8 and a constant width h8. The first flow rate adjusting member 115 and the second flow rate adjusting member 116 are disposed to cover the first flow path 14e and the second flow path 14f of the container 14, respectively. The seventh slit 115aa of the first flow rate adjusting member 115 is disposed at an end portion on a first side wall 14a side of the first flow rate adjusting member 115, that is, so as to be positioned at the first side wall 14a side-end of the first flow path 14e. The eighth slit 116aa of the second flow rate adjusting member 116 is disposed at an end portion on a second side wall 14b side of the second flow rate adjusting member 116, that is, so as to be positioned at the second side wall 14b side-end of the second flow path 14f.

Although not depicted here, the heat dissipating plate 13 on which the cooling fins 13a are provided or the heat dissipating plate 13 on which the semiconductor module 20 has been mounted on the opposite side to the cooling fins 13a is disposed in keeping with the examples depicted in FIGS. 1, 2, 3A, and 3B so as to cover the internal space of the container 14. The heat dissipating plate 13 and the container 14 are fastened together and connected using bolts, for example. The cooling fins 13a of the heat dissipating plate 13 that has been connected to the container 14 are disposed so as to be housed inside the third flow path 14g of the container 14.

When the cooler 110 is used, in the same way as depicted in FIG. 1 described above, the inlet 11 of the cooler 110 is connected via piping to the pump 40, and the outlet 12 of the cooler 110 is connected via piping to the heat exchanger 50. The pump 40 and the heat exchanger 50 are connected by piping. The coolant 30 is distributed within the cooler 110 as indicated by the dotted arrows in FIGS. 9 and 11. That is, the coolant 30 supplied to the cooler 110 by the pump 40 is introduced into the cooler 110 from the inlet 11. The coolant 30 introduced from the inlet 11 flows into the first flow path 14e of the container 14 that communicates with the inlet 11, and flows from the first flow path 14e through the seventh slit 115aa, which has a constant width, of the first flow rate adjusting member 115 into the third flow path 14g. The coolant 30 that has flowed into the third flow path 14g flows from the third flow path 14g through the eighth slit 116aa, which has a constant width, of the second flow rate adjusting member 116 into the second flow path 14f of the container 14 that communicates with the outlet 12. The coolant 30 that has flowed into the second flow path 14f is discharged to the outside of the cooler 110 from the outlet 12.

The coolant 30 that has flowed from the first flow path 14e into the third flow path 14g flows on coolant flow paths defined by the cooling fins 13a housed inside the third flow path 14g, that is, in the gaps between adjacent cooling fins 13a. While the coolant 30 is flowing through the third flow path 14g, heat exchanging occurs so that heat that has been transferred from the semiconductor module 20 to the heat dissipating plate 13 and the cooling fins 13a is transferred to the coolant 30 flowing through the third flow path 14g, thereby cooling the semiconductor module 20. The coolant 30, whose temperature has increased due to heat exchanging with the heat dissipating plate 13 and the cooling fins 13a, flows into the second flow path 14f and is discharged to the outside of the cooler 110 from the outlet 12. After this, the coolant 30 that has been sent to the heat exchanger 50 and whose temperature has been fallen is introduced back into the cooler 110 from the inlet 11 by the pump 40.

Here, the cooler 10 according to the first embodiment described above will be referred to as “type A”, and the cooler 110 according to this comparative example will be referred to as “type B”. A cooler that uses a container 14 that is not provided with the first flow rate adjusting members 15 and 115 and the second flow rate adjusting members 16 and 116 described above is referred to as “type C”.

The length w, the width h0, the width h, the height t1, and the height t2 of the container 14 of the type A cooler 10, the type B cooler 110, and the type C cooler are the dimensions of the parts indicated in FIGS. 4A and 4B described above. The lengths w of the container 14 of the type A cooler 10, the type B cooler 110, and the type C cooler are set at the same length. The widths h0 of the container 14 of the type A cooler 10, the type B cooler 110, and the type C cooler are set at the same width. The widths h of the container 14 of the type A cooler 10, the type B cooler 110, and the type C cooler are set at the same width. The heights t1 of the container 14 of the type A cooler 10, the type B cooler 110, and the type C cooler are set at the same height. The heights t2 of the container 14 of the type A cooler 10, the type B cooler 110, and the type C cooler are also set at the same height.

The first length w2, the second lengths w1 and w3, the first width h2, and the second widths h1 and h3 of the first flow rate adjusting member 15 of the type A cooler 10 are the dimensions of the parts indicated in FIG. 5 described above. The third length w6, the fourth lengths w5 and w7, the third width h6, and the fourth widths h5 and h7 of the second flow rate adjusting member 16 of the type A cooler 10 are the dimensions of the parts indicated in FIG. 5 described above. The first length w2 and the second lengths w1 and w3 of the first flow rate adjusting member 15 are set at lengths obtained by dividing the length w of the container 14 into three approximately equal parts. The first width h2 of the first flow rate adjusting member 15 is set at 2 mm for example, and the second widths h1 and h3 are set at 1 mm for example. The third length w6, and the fourth lengths w5 and w7 of the second flow rate adjusting member 16 are set at lengths obtained by dividing the length w of the container 14 into three approximately equal parts. The third width h6 of the second flow rate adjusting member 16 is set at 1 mm for example, and the fourth widths h5 and h7 are set at 2 mm, for example.

The length w4 and width h4 of the first flow rate adjusting member 115 of the type B cooler 110 are the dimensions of the parts indicated in FIG. 10 described above. The length w8 and width h8 of the second flow rate adjusting member 116 of the type B cooler 110 are the dimensions of the parts indicated in FIG. 10 described above. The length w4 of the first flow rate adjusting member 115 is set equal to the total length of the first length w2 and the second lengths w1 and w3 of the first flow rate adjusting member 15 of the type A cooler 10. The width h4 of the first flow rate adjusting member 115 is set at the same width as the second widths h1 and h3 of the first flow rate adjusting member 15 of the type A cooler 10, as one example, at 1 mm. The length w8 of the second flow rate adjusting member 116 is set at the same length as the total length of the third length w6 and the fourth lengths w5 and w7 of the second flow rate adjusting member 16 of the type A cooler 10. The width h8 of the second flow rate adjusting member 116 is set at the same width as the third width h6 of the second flow rate adjusting member 16 of the type A cooler 10, as one example, at 1 mm.

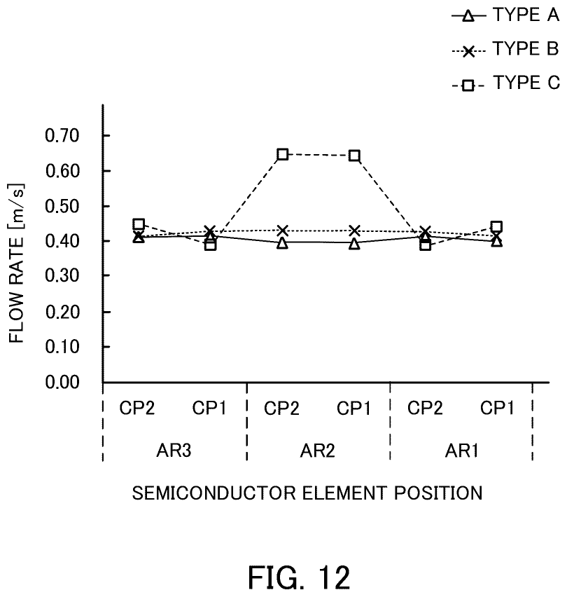

FIGS. 12 to 14 depict the results of thermo-fluid simulations and evaluation of the Type A cooler 10, the Type B cooler 110, and the Type C cooler with the dimensions described above.

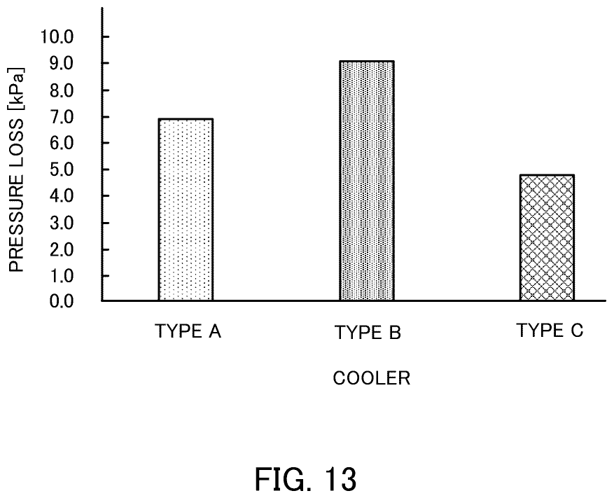

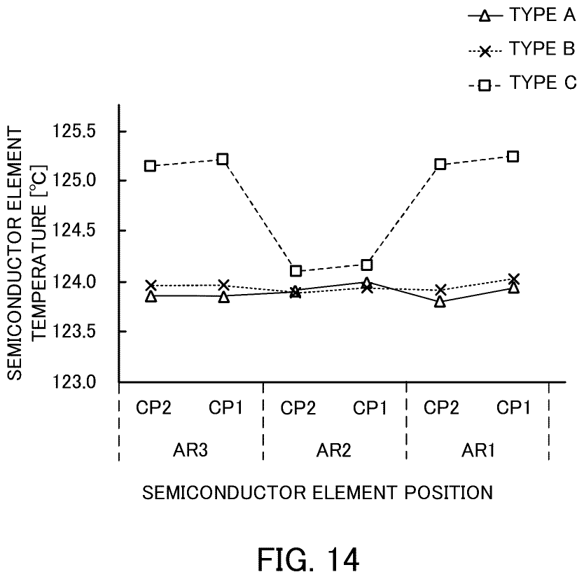

FIG. 12 depicts example evaluation results of the coolant flow rates at semiconductor element positions. FIG. 13 depicts example evaluation results of pressure loss in each type of cooler. FIG. 14 depicts example evaluation results of semiconductor element temperature with respect to semiconductor element positions.

In the thermal fluid simulation, the flow rate of the coolant 30 introduced from the inlet 11 of the container 14 is set at 10 L/min. In the thermal fluid simulation, the generation of heat is reproduced by assigning a certain amount of loss to a semiconductor module 20 like that depicted in FIG. 1 described above. That is, the generation of heat is reproduced by assigning a constant loss to each of a semiconductor element CP1 (the semiconductor element 25) and a semiconductor element CP2 (the semiconductor element 26) in each of the three mounting areas, that is, mounting area AR1 (the circuit element portion 21), the mounting area AR2 (the circuit element portion 22), and the mounting area AR3 (the circuit element portion 23), of the semiconductor module 20 that is mounted on the heat dissipating plate 13 that covers the container 14.

In FIG. 12, the flow rate of the coolant 30 at the positions of the semiconductor elements CP1 and CP2 in the mounting area AR1, the flow rate of the coolant 30 at the positions of the semiconductor elements CP1 and CP2 in the mounting area AR2, and the flow rate of the coolant 30 at the positions of the semiconductor elements CP1 and CP2 in the mounting area AR3 are indicated.

From FIG. 12, it may be understood that in the type C cooler, which uses a container 14 without the first flow rate adjusting members 15 and 115 and the second flow rate adjusting members 16 and 116 like those described above, an unbalanced flow distribution occurs where the flow rate of the coolant 30 at the positions of the semiconductor elements CP1 and CP2 in the center mounting area AR2 is around 0.65 m/s but the flow rate of the coolant 30 at the positions of the semiconductor elements CP1 and CP2 in each of the mounting areas AR1 and AR3 at both ends is around 0.40 m/s to 0.45 m/s. On the other hand, it may also be understood from FIG. 12 that with the type A cooler 10 that uses the container 14 provided with the first flow rate adjusting member 15 and the second flow rate adjusting member 16 and the type B cooler 110 that uses the container 14 provided with the first flow rate adjusting member 115 and the second flow rate adjusting member 116, the flow rate of the coolant 30 at the positions of the semiconductor elements CP1 and CP2 is around 0.40 m/s in each of the mounting area AR1, the mounting area AR2, and the mounting area AR3, so that compared to the type C cooler, a more uniform flow of coolant is produced.

FIG. 13 depicts the pressure loss between the inlet 11 and the outlet 12 of the container 14, that is, the decrease in coolant pressure at the outlet 12 with respect to the pressure of the coolant 30 at the inlet 11.

From FIG. 13, it may be understood that although the pressure loss is about 5.0 kPa in the type C cooler that uses a container 14 without the first flow rate adjusting members 15 and 115 and the second flow rate adjusting members 16 and 116 like those described above, the pressure loss increases by 80% to 9.0 kPa in the type B cooler 110 that uses the container 14 provided with the first flow rate adjusting member 115 and the second flow rate adjusting member 116. On the other hand, from FIG. 13, the pressure loss is around 7.0 kPa for the type A cooler 10 that uses the container 14 provided with the first flow rate adjusting member 15 and the second flow rate adjusting member 16, which suppresses the increase in pressure loss from the type C cooler to 40%.

FIG. 14 depicts the temperatures of the semiconductor elements CP1 and CP2 in the mounting area AR1, the temperatures of the semiconductor elements CP1 and CP2 in the mounting area AR2, and the temperatures of the semiconductor elements CP1 and CP2 in the mounting area AR3.

From FIG. 14, in the type C cooler that uses the container 14 without the first flow rate adjusting members 15 and 115 and the second flow rate adjusting members 16 and 116 like those described above, the semiconductor elements CP1 and CP2 in the center mounting area AR2, where the flow rate of the coolant 30 is comparatively fast (see FIG. 12), are favorably cooled and the temperature is comparatively low at around 124° C., but the temperatures of the semiconductor elements CP1 and CP2 in the mounting areas AR1 and AR3 at both ends where the flow rate of the coolant 30 is comparatively slow (see FIG. 12) are comparatively high at 125° C. or higher. On the other hand, it may be understood from FIG. 14 that in the type A cooler 10, which uses the container 14 provided with the first flow rate adjusting member 15 and the second flow rate adjusting member 16, and in the type B cooler 110, which uses the container 14 provided with the first flow rate adjusting member 115 and the second flow rate adjusting member 116, the temperatures of the semiconductor elements CP1 and CP2 in all of the mounting area AR1, the mounting area AR2, and the mounting area AR3 (see FIG. 2) where the flow rate of the coolant 30 is comparatively uniform is around 124° C., so that compared to the type C cooler, the cooling is more uniform.

From the results depicted in FIGS. 12 to 14, the type A cooler 10 suppresses pressure loss more than the type B cooler 110 while obtaining the same or nearly the same effects of suppressing an unbalanced flow distribution and cooling the semiconductor elements as the type B cooler 110.

According to the type A cooler 10, that is, the cooler 10 according to the first embodiment, it is possible to suppress an unbalanced flow distribution and an increase in pressure loss for the coolant 30 flowing in the cooler 10. It is also possible to realize a semiconductor device 1 equipped with a cooler 10 that is capable of suppressing the occurrence of an unbalanced flow distribution and an increase in pressure loss.

In general, the semiconductor module 20 like that described above is widely used in power converter apparatuses used in control apparatuses for hybrid vehicles, electric vehicles, and the like. In the semiconductor module 20 that constructs a control apparatus for reducing power consumption like this, power semiconductor elements that control large currents are used as the semiconductor element 25 (CP1) and the semiconductor element 26 (CP2). Atypical power semiconductor element is a heat generating element that generates heat when controlling a large current, and due to a trend for power converter apparatuses to be miniaturized and have an increasingly large output, the generated amount of heat is increasing. For this reason, cooling of the semiconductor module 20 that is equipped with a plurality of heat generating elements is an important issue.

As one example, liquid cooling-based coolers have been used in the past to cool the semiconductor module 20. In a liquid cooling-based cooler, to improve the cooling efficiency, measures have been used such as increasing the flow rate of the coolant and changing the shape or material of cooling fins to achieve a high heat transfer coefficient. However, as a result of such measures, the load on the pump for circulating the coolant may increase, for reasons such as an increase in the pressure loss of the coolant inside the cooler. To reduce this pressure loss, it would be ideal to raise the cooling efficiency while using a low coolant flow rate, and while it would be favorable to reduce the flow rate of coolant and change the shape and material of the cooling fins to produce a higher heat transfer coefficient, using cooling fins like that would risk an increase in the cost of a cooler and of the semiconductor device that uses such cooler. In addition, in existing liquid-cooled coolers, an unbalanced flow distribution where the flow of coolant inside the cooler is unbalanced occurs due to the shape of the heat sink and/or the coolant flow paths, the arrangement of heat generating elements, the shapes of the coolant inlet and outlet, and the like. Since this unbalanced flow distribution biases the cooling performance, it has been difficult to obtain uniform and stable cooling performance with an existing cooler. As a result, the temperature of some of the heat generating elements may rise, which risks a reduction in performance and lifespan, failure, and the like.

In the past, to improve an unbalanced flow distribution in a cooler, there is a known technology (see for example, Japanese Laid-open Patent Publication No. 2012-146759 and Japanese Laid-open Patent Publication No. 2019-071330 cited earlier) that changes the sizes of the openings through which the coolant flows depending on the positions and the like of the coolant inlet and/or the heat-generating elements, for example. With this technology however, the structure of the cooler becomes complex, which risks an increase in cost. A technology that causes the coolant to flow through a single slit of a certain width to the heat sink (see for example, International Publication Pamphlet No. WO 2017/090106, Japanese Laid-open Patent Publication No. 2012-069892, and Japanese Laid-open Patent Publication No. 2015-153799 cited earlier or the type B cooler 110 described above) and a technology that causes coolant to flow through a plurality of holes or slits of the same size (see for example, International Publication Pamphlet No. WO 2019/211889 and Japanese Laid-open Patent Publication No. 2006-179771 cited earlier) are known. However, with this type of technology, when the shape of the heat sink, and/or the coolant inlet and outlet have a large influence, the width of the slit and/or the diameter of the hole(s) needs to be made small in order to produce a uniform flow rate distribution, and this tends to cause an increase in pressure loss. A technology for suppressing an increase in pressure loss by providing coolant flow paths on side surfaces of a heat sink is also known (see for example, International Publication Pamphlet No. WO 2015/079643 and International Publication Pamphlet No. WO 2013/054615 cited earlier). However, with such a technique, the dimensions of the flow path as a whole of a cooler become large, and the size of a semiconductor device including this cooler becomes excessively large. In addition, it is difficult to use this technique when bolt holes or seal grooves for connecting the heat sink to the cooler container are provided near side surfaces of the heat sink.

On the other hand, in the cooler 10 (type A) according to the first embodiment described above, the first flow rate adjusting member 15 and the second flow rate adjusting member 16 are disposed between the parallel first flow path 14e and second flow path 14f inside the container 14 and the third flow path 14g that communicates with these flow paths. The first flow rate adjusting member 15 includes the first region 15a with a first aperture ratio due to the comparatively wide first slit 15aa and the second region 15b with a second aperture ratio that is smaller than the first aperture ratio due to the comparatively narrow second slits 15ba. The second flow rate adjusting member 16 includes the third region 16a with a third aperture ratio due to the comparatively narrow third slit 16aa, and a fourth regions 16b with a fourth aperture ratio that is larger than the third aperture ratio due to the comparatively wide fourth slits 16ba. In this cooler 10, by forming a plurality of types of gaps with appropriate shapes and dimensions in the first flow rate adjusting member 15 and the second flow rate adjusting member 16, it is possible to cause the coolant 30 to flow smoothly without applying excessive pressure inside the first flow path 14e and the second flow path. As a result, it is possible to suppress an increase in pressure loss while suppressing the size of the cooler 10 and of the semiconductor device 1 including the cooler and maintaining a more uniform flow rate distribution for the coolant 30.

According to the cooler 10 according to the first embodiment, it is possible to suppress the occurrence of an unbalanced flow distribution and an increase in pressure loss for the coolant 30 inside the cooler 10, while suppressing an increase of the complexity and size of the structure and restrictions on the connecting of the container 14 and the heat dissipating plate 13. It is also possible to realize a semiconductor device 1 including this cooler 10.

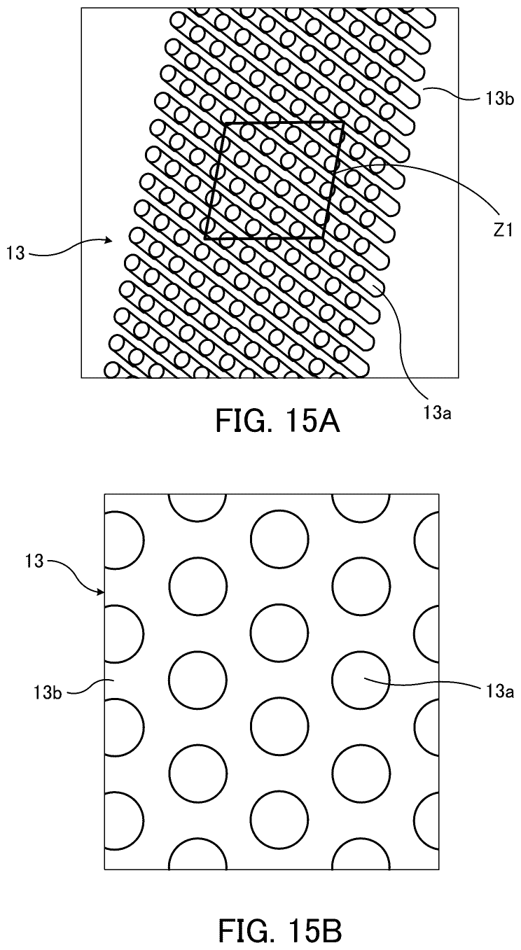

FIGS. 15A and 15B depict a first modification of the cooling fins provided on the heat dissipating plate of the cooler. FIG. 15A is a perspective view that schematically depicts a principal part of a first modification of the cooling fins provided on a heat dissipating plate, and FIG. 15B is a plan view that schematically depicts a principal part of a first modification of the cooling fins provided on a heat dissipating plate. FIG. 15B is an enlarged plan view of a part marked “Z1” in FIG. 15A.

The cooling fins 13a provided on the mounting surface 13b of the heat dissipating plate 13 that covers the container 14 of the cooler 10 and is connected to the container 14 are not limited to prismatic or substantially prismatic cooling fins 13a as described above, and cylindrical cooling fins 13a like those depicted in FIGS. 15A and 15B may be provided. The dimensions of the cylindrical cooling fins 13a are selected as appropriate depending on the desired cooling performance. As one example, a plurality of cylindrical cooling fins 13a are arranged on the heat dissipating plate 13 in a densely packed arrangement like that depicted in FIGS. 15A and 15B.

The cylindrical cooling fins 13a are integrated with the heat dissipating plate 13. A metal material is used for the heat dissipating plate 13 and the cylindrical cooling fins 13a. As examples, the cylindrical cooling fins 13a are integrated with the heat dissipating plate 13 by die casting, brazing, or various welding techniques. Alternatively, it is also possible to form cylindrical cooling fins 13a that are integrated with the heat dissipating plate 13 using a machining technique for forming projecting cooling fins 13a from the material of the heat dissipating plate 13 by die casting, forging or pressing, or a machining technique that forms projecting cooling fins 13a from the material of the heat dissipating plate 13 by cutting or wire cutting.

A heat dissipating plate 13 provided with cylindrical cooling fins 13a as depicted in FIGS. 15A and 15B is disposed on the container 14 so that the cooling fins 13a are housed in the third flow path 14g and is connected to and fixed to the container 14. Due to these cylindrical cooling fins 13a also, heat, which is generated at the semiconductor module 20 mounted on the heat dissipating plate 13, is transferred to the cooling fins 13a, and heat exchanging with the coolant 30 flowing through the third flow paths 14g is performed, thereby cooling the semiconductor module 20.

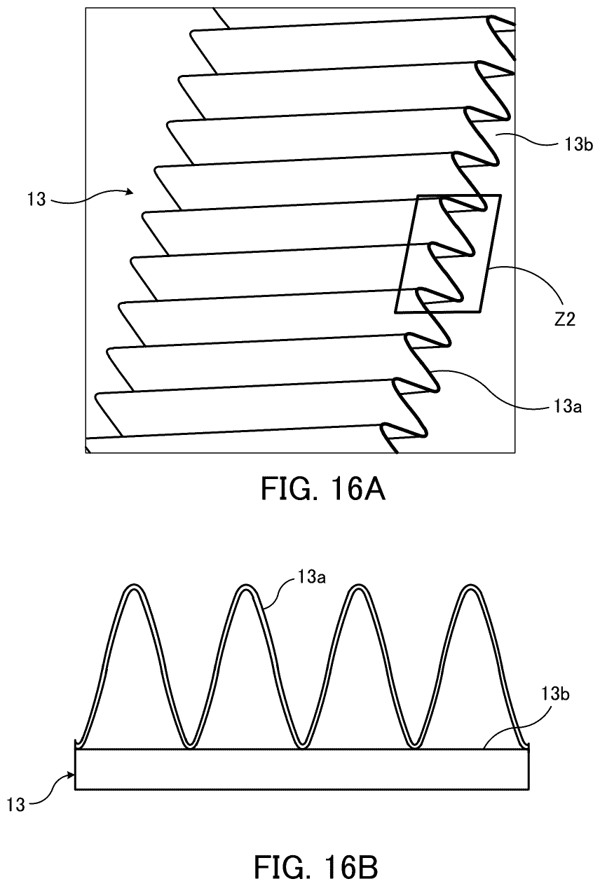

FIGS. 16A and 16B depict a second modification of the cooling fins provided on the heat dissipating plate of the cooler. FIG. 16A is a perspective view that schematically depicts a principal part of a second modification of the cooling fins provided on a heat dissipating plate, and FIG. 16B is a plan view that schematically depicts a principal part of a second modification of the cooling fins provided on a heat dissipating plate. FIG. 16B is an enlarged plan view of a part marked “Z2” in FIG. 16A.

Wavy cooling fins 13a, that is, corrugated fins, like those depicted in FIGS. 16A and 16B may be provided on the heat dissipating plate 13 that covers the container 14 of the cooler 10 and is connected to the container 14. The dimensions of the corrugated fins provided as the cooling fins 13a are selected as appropriate depending on the desired cooling performance. As one example, corrugated fins like those depicted in FIGS. 16A and 16B are disposed on the heat dissipating plate 13 as the cooling fins 13a.

The corrugated fins provided as the cooling fins 13a are integrated with the heat dissipating plate 13. A metal material is used for the heat dissipating plate 13 and the cooling fins 13a. As examples, the corrugated fins provided as the cooling fins 13a are integrated with the heat dissipating plate 13 using die casting, brazing, or various welding techniques.

A heat dissipating plate 13 provided with corrugated fins like those depicted in FIGS. 16A and 16B as the cooling fins 13a is disposed on the container 14 so that the corrugated fins are housed in the third flow path 14g and is connected and fixed to the container 14. Note that when doing so, the corrugated fins are housed in the third flow path 14g so that the coolant 30 flowing in the third flow path 14g from the first flow path 14e toward the second flow path 14f flows in a direction that is parallel to the mounting surface 13b of the heat dissipating plate 13, where the corrugated fins are mounted, along a direction in which the peaks or valleys of the corrugated fins extend. Even when such corrugated fins are provided as the cooling fins 13a, the heat generated by the semiconductor module 20 mounted on the heat dissipating plate 13 is transferred to the corrugated fins, and heat exchanging is performed with the coolant 30 flowing through the third flow path 14g, thereby cooling the semiconductor module 20.

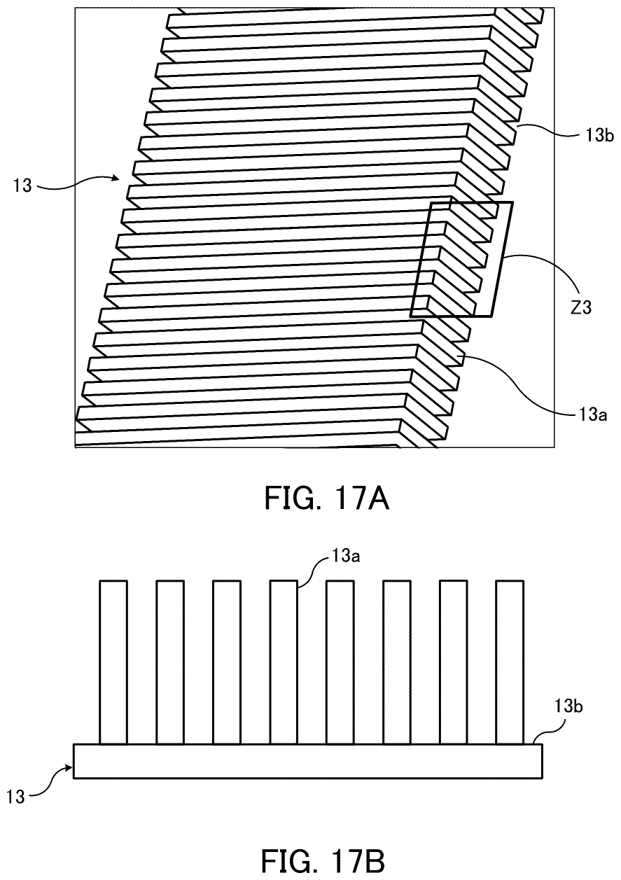

FIGS. 17A and 17B depict a third modification of the cooling fins provided on the heat dissipating plate of the cooler. FIG. 17A is a perspective view that schematically depicts a principal part of a third modification of the cooling fins provided on a heat dissipating plate, and FIG. 17B is a plan view that schematically depicts a principal part of a third modification of the cooling fins provided on a heat dissipating plate. FIG. 17B is an enlarged plan view of a part marked “Z3” in FIG. 17A.

The heat dissipating plate 13 that covers the container 14 of the cooler 10 and is connected to the container 14 may be provided with cooling fins 13a in the form of flat plates as depicted in FIGS. 17A and 17B, that is, straight fins (or blade fins). The dimensions of the straight fins provided as the cooling fins 13a are selected as appropriate depending on the desired cooling performance. As one example, straight fins like those depicted in FIGS. 17A and 17B are disposed on the heat dissipating plate 13 as the cooling fins 13a.

The straight fins provided as the cooling fins 13a are integrated with the heat dissipating plate 13. A metal material is used for the heat dissipating plate 13 and the cooling fins 13a. As examples, the straight fins provided as the cooling fins 13a are integrated with the heat dissipating plate 13 using die casting, brazing, or various welding techniques. Alternatively, it is also possible to form straight fins as the cooling fins 13a that are integrated with the heat dissipating plate 13 using a machining technique for forming projecting straight fins from the material of the heat dissipating plate 13 by die casting, forging or pressing, or a machining technique that forms projecting straight fins from the material of the heat dissipating plate 13 by cutting or wire cutting.

The heat dissipating plate 13 provided with straight fins like those depicted in FIGS. 17A and 17B as the cooling fins 13a is disposed on the container 14 so that the straight fins are housed in the third flow path 14g and is connected and fixed to the container 14. Note that when doing so, the straight fins are housed in the third flow path 14g so that the coolant 30 flowing in the third flow path 14g from the first flow path 14e toward the second flow path 14f flows in a direction that is parallel to the mounting surface 13b of the heat dissipating plate 13, where the straight fins are mounted, along a direction in which the side walls of the straight fins extend. Even when such straight fins are provided as the cooling fins 13a, the heat generated by the semiconductor module 20 mounted on the heat dissipating plate 13 is transferred to the straight fins and heat exchanging is performed with the coolant 30 flowing through the third flow path 14g, thereby enabling the semiconductor module 20 to be cooled.

### Second Embodiment

A modification of the container 14 of the cooler 10 will now be described as a second embodiment.

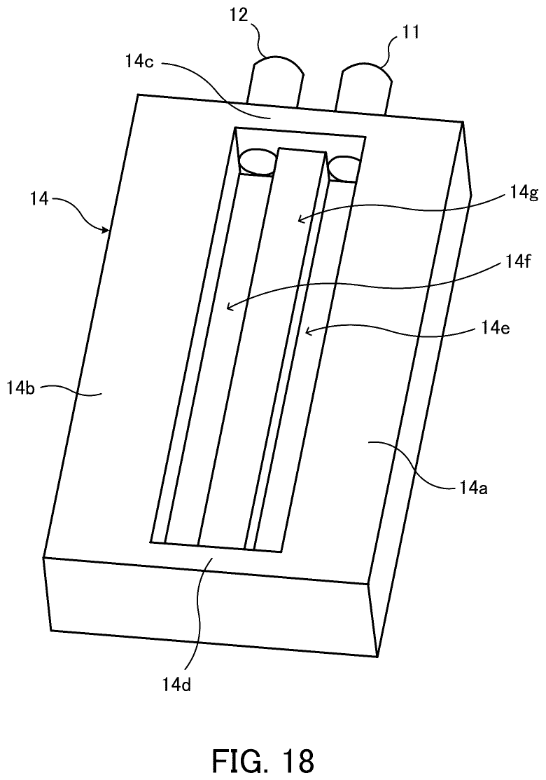

FIG. 18 depicts a first modification of the container of a cooler according to the second embodiment. FIG. 18 is a perspective view schematically depicting the principal part of a first modification of the container of a cooler.

The container 14 depicted in FIG. 18 is provided with the inlet 11, which communicates with the first flow path 14e that extends along the first side wall 14a, and the outlet 12, which communicates with the second flow path 14f that extends along the second side wall 14b, in the third side wall 14c between the first side wall 14a and the second side wall 14b. In the container 14 depicted in FIG. 18, a first flow rate adjusting member 15 like that depicted in FIG. 5 described above for example is disposed so as to cover the first flow path 14e that communicates with the inlet 11 provided in the third side wall 14c. A second flow rate adjusting member 16 like that depicted in FIG. 5 described above for example is disposed so as to cover the second flow path 14f that communicates with the outlet 12 provided in the third side wall 14c.

In a cooler 10 that uses a container 14 like that depicted in FIG. 18, by disposing the first flow rate adjusting member 15 between the first flow path 14e and the third flow path 14g and disposing the second flow rate adjusting member 16 between the second flow path 14f and the third flow path 14g, it is possible to suppress the occurrence of an unbalanced flow distribution and an increase in pressure loss for the coolant 30 flowing through the cooler 10.

Note that it is also possible to change the layout of the openings in the first flow rate adjusting member 15 and the second flow rate adjusting member 16 in keeping with a change in the positions of the inlet 11 and the outlet 12 like that depicted in FIG. 18.

As one example, the slit width of the first flow rate adjusting member 15 is adjusted so that the aperture ratio of a region closest to the inlet 11, out of a group of regions produced by dividing the first flow path 14e into three in a direction that extends along the first side wall 14a, is larger than the aperture ratios of the other two regions. In addition, the slit width of the second flow rate adjusting member 16 is adjusted so that the aperture ratio of a region closest to the outlet 12, out of a group of regions produced by dividing the second flow path 14f into three in a direction that extends along the second side wall 14b, is smaller than the aperture ratios of the other two regions. By doing so, a region of the first flow rate adjusting member 15, which is closest to the inlet 11 and has a comparatively large aperture ratio, and a region of the second flow rate adjusting member 16, which is closest to the outlet 12 and has a comparatively small aperture ratio, face each other. In addition, regions of the first flow rate adjusting member 15, which are comparatively far from the inlet 11 and have a comparatively small aperture ratio, and regions of the second flow rate adjusting member 16, which are comparatively far from the outlet 12 and have a comparatively large aperture ratio, face each other. The first flow rate adjusting member 15 and the second flow rate adjusting member 16 which have openings in a changed layout like this may be disposed on a container 14 as depicted in FIG. 18.

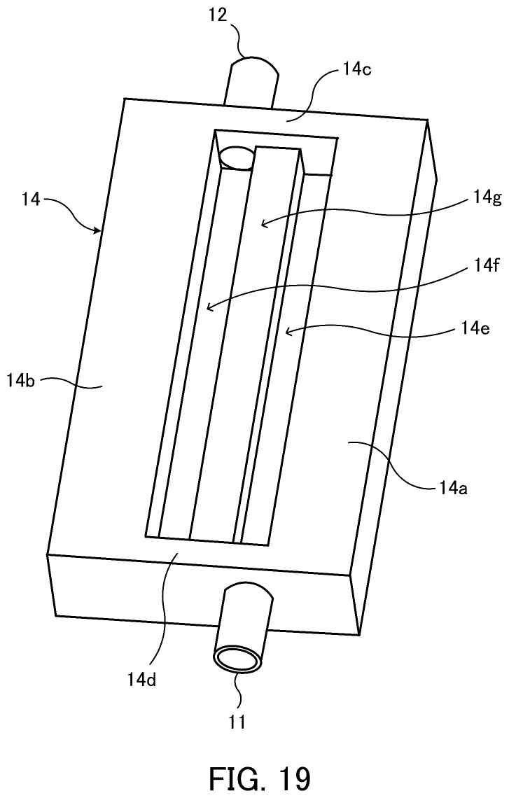

FIG. 19 depicts a second modification of the container of a cooler according to the second embodiment. FIG. 19 is a perspective view schematically depicting a principal part of a second modification of the container of the cooler.

The container 14 depicted in FIG. 19 is provided with the inlet 11, which communicates with a first flow path 14e that extends along the first side wall 14a, in the fourth side wall 14d that is connected between the first side wall 14a and the second side wall 14b. In addition, the container 14 depicted in FIG. 19 is provided with the outlet 12, which communicates with a second flow path 14f that extends along the second side wall 14b, in the third side wall 14c that connects the first side wall 14a and the second side wall 14b. In the container 14 depicted in FIG. 19, as one example, a first flow rate adjusting member 15 like that depicted in FIG. 5 described above is disposed so as to cover the first flow path 14e that communicates with the inlet 11 provided in the fourth side wall 14d. A second flow rate adjusting member 16 like that depicted in FIG. 5 described above is disposed so as to cover the second flow path 14f that communicates with the outlet 12 provided in the third side wall 14c.

In a cooler 10 that uses a container 14 like that depicted in FIG. 19, by disposing the first flow rate adjusting member 15 between the first flow path 14e and the third flow path 14g and disposing the second flow rate adjusting member 16 between the second flow path 14f and the third flow path 14g, it is possible to suppress the occurrence of an unbalanced flow distribution and an increase in pressure loss for the coolant 30 flowing in the cooler 10.

Note that a first flow rate adjusting member 15 and a second flow rate adjusting member 16 with openings in a layout that has changed in keeping with the change in the positions of the inlet 11 and the outlet 12 may be disposed.

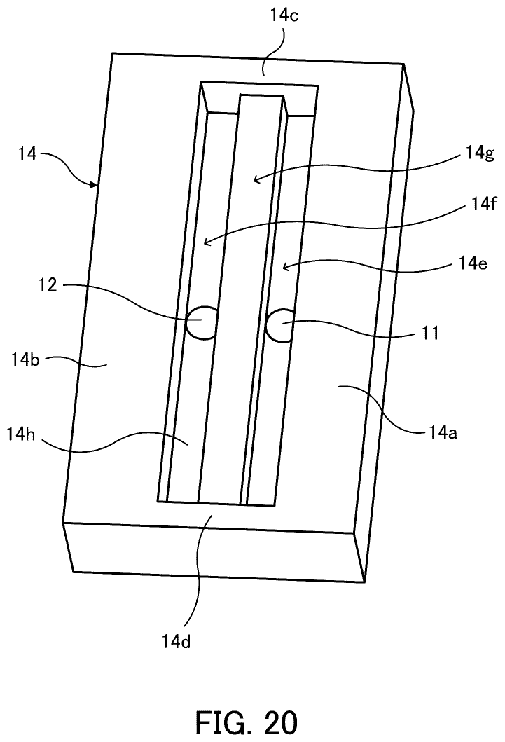

FIG. 20 depicts a third modification of a container of a cooler according to the second embodiment. FIG. 20 is a perspective view schematically depicting a principal part of a third modification of the container of the cooler.

The container 14 depicted in FIG. 20 is provided with the inlet 11, which communicates with the first flow path 14e that extends along the first side wall 14a, and the outlet 12, which communicates with the second flow path 14f that extends along the second side wall 14b, in the bottom plate 14h. In the container 14 depicted in FIG. 20, a first flow rate adjusting member 15 like that depicted in FIG. 5 described above for example is disposed so as to cover the first flow path 14e that communicates with the inlet 11 provided in the bottom plate 14h. As one example, the second flow rate adjusting member 16 like that depicted in FIG. 5 is disposed so as to cover the second flow path 14f that communicates with the outlet 12 provided in the bottom plate 14h.

In a cooler 10 that uses a container 14 like that depicted in FIG. 20, by disposing the first flow rate adjusting member 15 between the first flow path 14e and the third flow path 14g and disposing the second flow rate adjusting member 16 between the second flow path 14f and the third flow path 14g, it is possible to suppress the occurrence of an unbalanced flow distribution and an increase in pressure loss for the coolant 30 flowing through the cooler 10.

Note that a first flow rate adjusting member 15 and a second flow rate adjusting member 16 with openings in a layout that has changed in keeping with the change in the positions of the inlet 11 and the outlet 12 as depicted in FIG. 20 may be disposed.

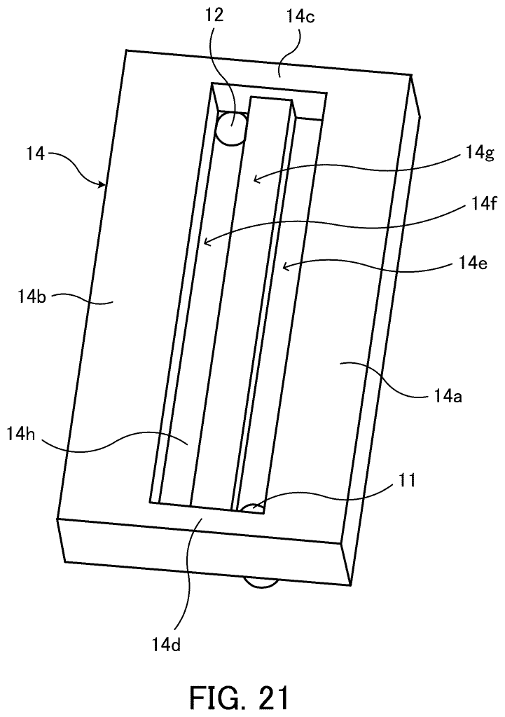

FIG. 21 depicts a fourth modification of the container of a cooler according to the second embodiment. FIG. 21 is a perspective view schematically depicting a principal part of a fourth modification of the container of the cooler.

The container 14 depicted in FIG. 21 is provided with an inlet 11, which communicates with a first flow path 14e, in the bottom plate 14h at a fourth side wall 14d side-end of the first flow path 14e that extends along the first side wall 14a. In addition, the container 14 depicted in FIG. 21 is provided with an outlet 12, which communicates with a second flow path 14f, in the bottom plate 14h at a third side wall 14c-side end of the second flow path 14f that extends along the second side wall 14b. In the container 14 depicted in FIG. 21, a first flow rate adjusting member 15 like that depicted in FIG. 5 described above for example is disposed so as to cover the first flow path 14e that communicates with the inlet 11 provided in the bottom plate 14h. A second flow rate adjusting member 16 like that depicted in FIG. 5 described above for example is disposed so as to cover the second flow path 14f that communicates with the outlet 12 provided in the bottom plate 14h.

In a cooler 10 that uses a container 14 like that depicted in FIG. 21, by disposing the first flow rate adjusting member 15 between the first flow path 14e and the third flow path 14g and disposing the second flow rate adjusting member 16 between the second flow path 14f and the third flow path 14g, it is possible to suppress the occurrence of an unbalanced flow distribution and an increase in pressure loss for the coolant 30 flowing in the cooler 10.

Note that a first flow rate adjusting member 15 and a second flow rate adjusting member 16 with openings in a layout that has changed in keeping with a change in the positions of the inlet 11 and the outlet 12 like that depicted in FIG. 21 may be disposed.

### Third Embodiment

A modification of the first flow rate adjusting member 15 and the second flow rate adjusting member 16 of the cooler 10 will now be described as a third embodiment.

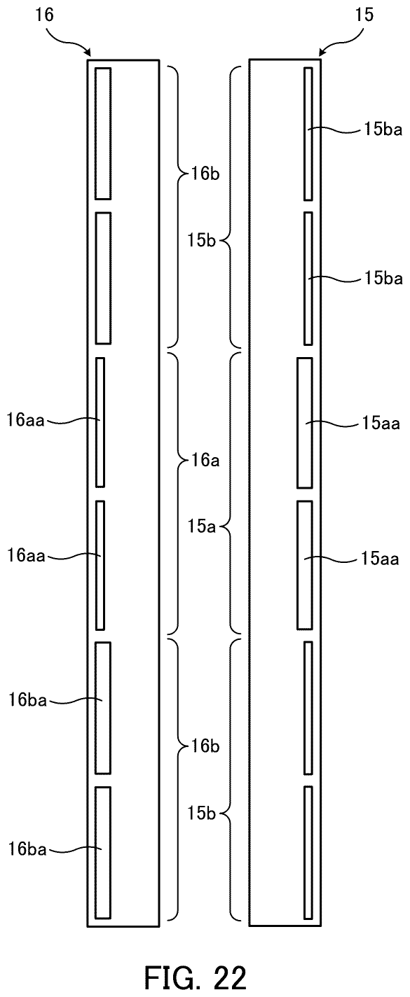

FIG. 22 depicts a first modification of the first flow rate adjusting member and the second flow rate adjusting member of a cooler according to the third embodiment. FIG. 22 is a plan view schematically depicting a principal part of a first modification of the first flow rate adjusting member and the second flow rate adjusting member of a cooler.

In the first flow rate adjusting member 15 depicted in FIG. 22, out of a group of regions produced by dividing the first flow rate adjusting member 15 into three in the length direction, the first slit 15aa of the first region 15a in the center is divided into a plurality of parts, as one example, two parts, and each of the second slits 15ba of the two second regions 15b on the outside is divided into a plurality of parts, as one example, two parts. In the second flow rate adjusting member 16 depicted in FIG. 22, out of a group of regions produced by dividing the second flow rate adjusting member 16 into three in the length direction, the third slit 16aa of the third region 16a in the center is divided into a plurality of parts, as one example, two parts, and each of the fourth slits 16ba of the two fourth regions 16b on the outside is divided into a plurality of parts, as one example, two parts. A first flow rate adjusting member 15 and a second flow rate adjusting member 16 like those depicted in FIG. 22 are disposed so as to cover the first flow path 14e and the second flow path 14f respectively of the container 14. The first region 15a of the first flow rate adjusting member 15 whose aperture ratio is comparatively high and the third region 16a of the second flow rate adjusting member 16 whose aperture ratio is comparatively low face each other, and the second regions 15b of the first flow rate adjusting member 15 whose aperture ratio is comparatively low and the fourth regions 16b of the second flow rate adjusting member 16 whose aperture ratio is comparatively high face each other.

In a cooler 10 that uses the first flow rate adjusting member 15 and the second flow rate adjusting member 16 like those depicted in FIG. 22, that is, even with the cooler 10 in which a first flow rate adjusting member 15 and a second flow rate adjusting member 16 like those depicted in FIG. 22 have been disposed on the first flow path 14e and the second flow path 14f of the container 14, it is possible to suppress the occurrence of an unbalanced flow distribution and the increase in pressure loss for the coolant 30 flowing in the cooler 10.

Note that in the first flow rate adjusting member 15, the first slit 15aa in the first region 15a may be divided into three or more parts, and the second slits 15ba in the second regions 15b may be divided into three or more parts. So long as the aperture ratio of the first region 15a is larger than the aperture ratio of the second regions 15b, the respective widths of the plurality of parts produced by dividing the first slit 15aa may be the same or respectively different, and the widths of the plurality of parts produced by dividing the second slits 15ba may be the same or respectively different.

Likewise, in the second flow rate adjusting member 16, the third slit 16aa in the third region 16a may be divided into three or more parts, and the fourth slits 16ba in the fourth regions 16b may be divided into three or more parts. So long as the aperture ratio of the third region 16a is smaller than the aperture ratio of the fourth regions 16b, the respective widths of the plurality of parts produced by dividing the third slit 16aa may be the same or respectively different, and the widths of the plurality of parts produced by dividing the fourth slits 16ba may be the same or respectively different.

The width of the first slit 15aa of the first flow rate adjusting member 15 and the width of the fourth slit 16ba of the second flow rate adjusting member 16 may be the same or may be different, and the width of the second slits 15ba of the first flow rate adjusting member 15 and the width of the third slit 16aa of the second flow rate adjusting member 16 may be the same or may be different.

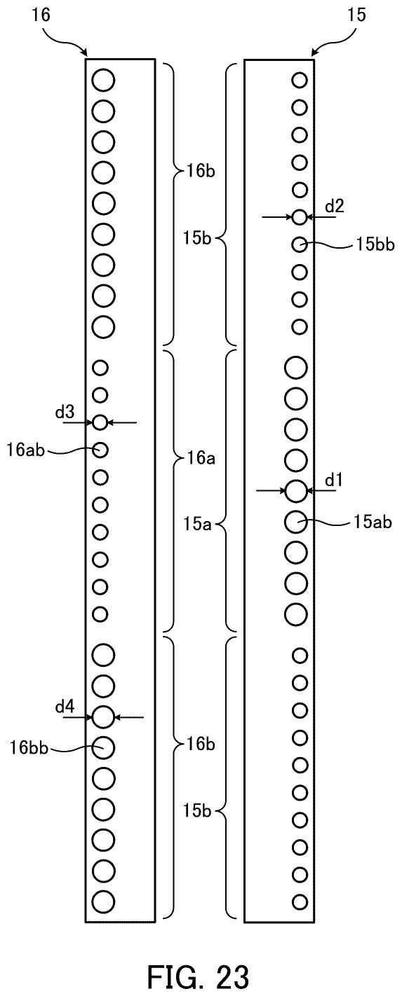

FIG. 23 depicts a second modification of the first flow rate adjusting member and the second flow rate adjusting member of a cooler according to the third embodiment. FIG. 23 is a plan view schematically depicting a principal part of a second modification of the first flow rate adjusting member and the second flow rate adjusting member of a cooler.

The first flow rate adjusting member 15 and the second flow rate adjusting member 16 depicted in FIG. 23 are provided with holes in place of slits as openings. In the first flow rate adjusting member 15 depicted in FIG. 23, out of a group of regions produced by dividing the first flow rate adjusting member 15 into three in the length direction, a plurality of first holes 15ab with a first diameter d1 are provided in a first region 15a in the center, and a plurality of second holes 15bb with a second diameter d2 that is smaller than the first diameter d1 are provided in each of the two second regions 15b on the outside. In the second flow rate adjusting member 16 depicted in FIG. 23, out of a group of regions produced by dividing the second flow rate adjusting member 16 into three in the length direction, a plurality of third holes 16ab with a third diameter d3 are provided in a third region 16a in the center, and a plurality of fourth holes 16bb with a fourth diameter d4 that is larger than the third diameter d3 are provided in each of the two fourth regions 16b on the outside. A first flow rate adjusting member 15 and a second flow rate adjusting member 16 like those depicted in FIG. 23 are disposed so as to cover the first flow path 14e and the second flow path 14f, respectively, of the container 14. The first region 15a of the first flow rate adjusting member 15 that has a comparatively large aperture ratio and a third region 16a of the second flow rate adjusting member 16 that has a comparatively small aperture ratio face each other, and the second regions 15b of the first flow rate adjusting member 15 that have a comparatively small aperture ratio and the fourth regions 16b of the second flow rate adjusting member 16 that have a comparatively large aperture ratio face each other.

With a cooler 10 that uses the first flow rate adjusting member 15 and the second flow rate adjusting member 16 like those depicted in FIG. 23, that is, even with a cooler 10 in which a first flow rate adjusting member 15 and a second flow rate adjusting member 16 like those depicted in FIG. 23 are disposed on the first flow path 14e and the second flow path 14f respectively of the container 14, it is possible to suppress the occurrence of an unbalanced flow distribution and an increase in pressure loss for the coolant 30 flowing in the cooler 10.

Note that in the first flow rate adjusting member 15, so long as the aperture ratio of the first region 15a is larger than the aperture ratio of the second regions 15b, the number of first holes 15ab in the first region 15a and the number of second holes 15bb in the second regions 15b are not limited to the illustrated example. So long as the aperture ratio of the first region 15a is larger than the aperture ratio of the second regions 15b, the first diameter d1 of each of the plurality of first holes 15ab may be the same or may be different, and the second diameter d2 of each of the plurality of second holes 15bb may be the same or may be different. The plurality of first holes 15ab are not limited to a single row and may also be disposed in a plurality of rows, and the plurality of second holes 15bb are not limited to a single row and may also be disposed in a plurality of rows.

Likewise in the second flow rate adjusting member 16, so long as the aperture ratio of the third region 16a is smaller than the aperture ratio of the fourth regions 16b, the number of third holes 16ab in the third region 16a and the number of fourth holes 16bb in the fourth regions 16b are not limited to the illustrated example. So long as the aperture ratio of the third region 16a is smaller than the aperture ratio of the fourth regions 16b, the third diameter d3 of each of the plurality of third holes 16ab may be the same or may be different, and the fourth diameter d4 of each of the plurality of fourth holes 16bb may be the same or may be different. The plurality of third holes 16ab are not limited to a single row and may also be disposed in a plurality of rows, and the plurality of fourth holes 16bb are not limited to a single row and may also be disposed in a plurality of rows.

The first diameter d1 of the first holes 15ab in the first flow rate adjusting member 15 and the fourth diameter d4 of the fourth holes 16bb in the second flow rate adjusting member 16 may be the same or may differ from each other, and the second diameter d2 of the second holes 15bb in the first flow rate adjusting member 15 and the third diameter d3 of the third holes 16ab in the second flow rate adjusting member 16 may be the same or may differ from each other.

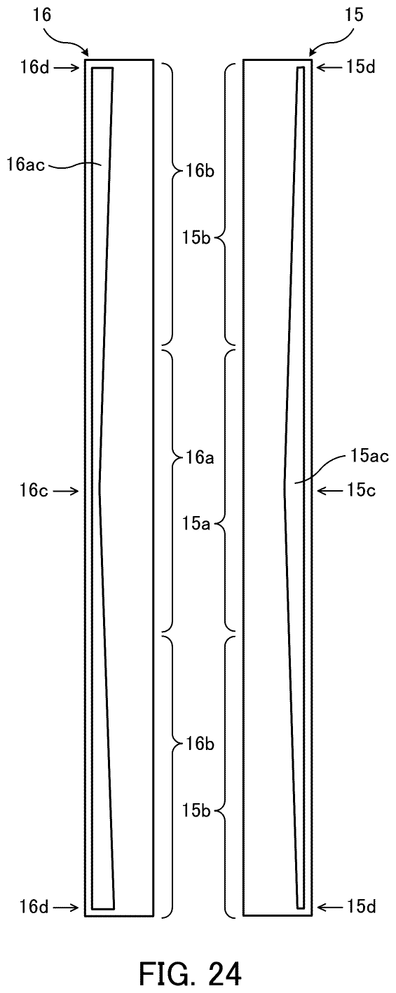

FIG. 24 depicts a third modification of the first flow rate adjusting member and the second flow rate adjusting member of a cooler according to the third embodiment. FIG. 24 is a plan view schematically depicting a principal part of a third modification of the first flow rate adjusting member and the second flow rate adjusting member of a cooler.

The first flow rate adjusting member 15 depicted in FIG. 24 is provided with a fifth slit 15ac whose width becomes narrower from a center portion 15c in the length direction toward both end portions 15d. Here, it may be said that the first flow rate adjusting member 15 depicted in FIG. 24 is provided with a fifth slit 15ac whose width becomes narrower from a first region 15a in the center, out of a group of regions produced by dividing the first flow rate adjusting member 15 into three in the length direction, toward the two outer second regions 15b. The second flow rate adjusting member 16 depicted in FIG. 24 is provided with a sixth slit 16ac whose width becomes wider from a center portion 16c in the length direction toward both end portions 16d. Here, it may be said that the second flow rate adjusting member 16 depicted in FIG. 24 is provided with a sixth slit 16ac whose width becomes wider from a third region 16a in the center, out of a group of regions produced by dividing the second flow rate adjusting member 16 into three in the length direction, toward the two outer fourth regions 16b. A first flow rate adjusting member 15 and a second flow rate adjusting member 16 like those depicted in FIG. 24 are disposed so as to cover the first flow path 14e and the second flow path 14f respectively of the container 14. The first region 15a of the first flow rate adjusting member 15 whose aperture ratio is comparatively high and the third region 16a of the second flow rate adjusting member 16 whose aperture ratio is comparatively low face each other, and the second regions 15b of the first flow rate adjusting member 15 whose aperture ratio is comparatively low and the fourth regions 16b of the second flow rate adjusting member 16 whose aperture ratio is comparatively high face each other.

With a cooler 10 that uses a first flow rate adjusting member 15 and a second flow rate adjusting member 16 like those depicted in FIG. 24, that is, even with a cooler 10 in which a first flow rate adjusting member 15 and a second flow rate adjusting member 16 like those depicted in FIG. 24 are disposed on the first flow path 14e and the second flow path 14f of the container 14, it is possible to suppress the occurrence of an unbalanced flow distribution and an increase in pressure loss for the coolant 30 flowing in the cooler 10.

Note that the fifth slit 15ac of the first flow rate adjusting member 15 may be divided at boundary positions between the first region 15a and the second regions 15b into a plurality of slits, and may be divided in the center in each of the first region 15a and the second regions 15b into a plurality of parts as in the example in FIG. 22 described above.

Likewise, the sixth slit 16ac of the second flow rate adjusting member 16 may be divided at boundary positions between the third region 16a and the fourth regions 16b into a plurality of slits, and may be divided in the center in each of the third region 16a and the fourth regions 16b into a plurality of parts as in the example in FIG. 22 described above.

The width in the center portion 15c of the fifth slit 15ac of the first flow rate adjusting member 15 and the width at the end portions 16d of the sixth slit 16ac of the second flow rate adjusting member 16 may be the same or may be different, and the width at the end portions 15d of the fifth slit 15ac of the first flow rate adjusting member 15 and the width in the center portion 16c of the sixth slit 16ac of the second flow rate adjusting member 16 may be the same or may be different.

### Fourth Embodiment

Evaluation results produced by thermal fluid simulations when coolers of various configurations are used will now be described as a fourth embodiment.

### First Example

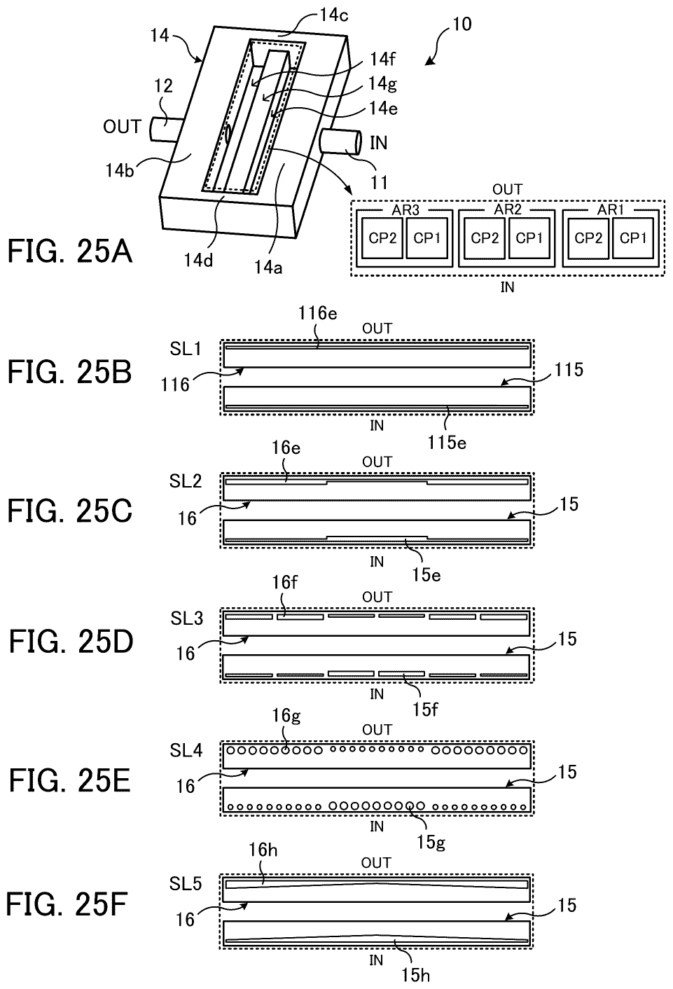

FIGS. 25A to 25F depict a first example of a cooler according to the fourth embodiment. FIG. 25A is a perspective view of a principal part of a first example of a cooler and schematically depicts the layout of semiconductor element mounting areas. FIGS. 25B to 25F are plan views schematically depicting principal parts of flow rate adjusting members used in this first example of a cooler.

In the first example, a container 14 like that depicted in FIG. 25A is used in the cooler 10. The container 14 depicted in FIG. 25A corresponds to a container 14 like that depicted in FIGS. 4A and 4B described above. In the container 14 depicted in FIG. 25A, the inlet 11 (IN) that communicates with the first flow path 14e is disposed in the center of the first side wall 14a and the outlet 12 (OUT) that communicates with the second flow path 14f is disposed in the center of the second side wall 14b. The cooling fins 13a of the heat dissipating plate 13 described above that covers the container 14 are housed in the third flow path 14g, which is an internal space above the first flow path 14e and the second flow path 14f. In the thermal fluid simulations, the cooling fins 13a that are prismatic like those depicted in FIGS. 3A and 3B described above, or are cylindrical like those depicted in FIGS. 15A and 15B are used. In a region corresponding to the third flow path 14g on the heat dissipating plate 13 (that is, the region indicated by the dotted frame in FIG. 25A), in keeping with the example in FIG. 1 and the like described above, a semiconductor element CP1 and a semiconductor element CP2 are disposed in each of the three mounting areas AR1, AR2, and AR3 as depicted in FIG. 25A.

Note that in FIG. 25A (and in FIG. 25B to FIG. 25F described later), the inlet 11 side of the container 14 is indicated as “IN” and the outlet 12 side is indicated as “OUT”. The three mounting areas AR1 to AR3 and the semiconductor elements CP1 and CP2 provided in each of these areas have a positional relationship with respect to the IN and OUT of the container 14 like that depicted in FIG. 25A.

In the thermal fluid simulations, in a cooler 10 like that depicted in FIG. 25A, a first flow rate adjusting member 115 and a second flow rate adjusting member 116 like those depicted in FIG. 25B, and first flow rate adjusting members 15 and second flow rate adjusting members 16 like those depicted in FIGS. 25C to 25F are used.

Here, the first flow rate adjusting member 115 and the second flow rate adjusting member 116 depicted in FIG. 25B are indicated as “SL1”. This configuration SL1 corresponds to the first flow rate adjusting member 115 and the second flow rate adjusting member 116 depicted in FIG. 10 described above. The first flow rate adjusting member 115 and the second flow rate adjusting member 116 depicted in FIG. 25B respectively have a slit 115e (or “seventh slit”) and a slit 116e (or “eighth slit”) with a constant width extending in the length direction. The width of the slits 115e and 116e is set at 1 mm.

The first flow rate adjusting member 15 and the second flow rate adjusting member 16 depicted in FIG. 25C are indicated as “SL2”. This configuration SL2 corresponds to the first flow rate adjusting member 15 and the second flow rate adjusting member 16 depicted in FIG. 5 described above. In the first flow rate adjusting member 15 depicted in FIG. 25C, the width of a slit 15e is adjusted so that out of a group of regions produced by dividing the first flow rate adjusting member 15 into three in the length direction, the aperture ratio of the center region (or “first region”) closest to the inlet 11 (IN) is larger than the aperture ratio of the regions on both sides (or “second regions”). The width of the slit 15e (or “first slit”) in the center region closest to the inlet 11 is set at 2 mm, and the width of the slit 15e (or “second slit”) in the regions on both sides is set at 1 mm. In the second flow rate adjusting member 16 depicted in FIG. 25C, the width of a slit 16e is adjusted so that out of a group of regions produced by dividing the second flow rate adjusting member 16 into three in the length direction, the aperture ratio of the center region (or “third region”) closest to the outlet 12 (OUT) is smaller than the aperture ratio of the regions on both sides (or “fourth regions”). The width of the slit 16e (or “third slit”) in the center region closest to the outlet 12 is set at 1 mm, and the width of the slit 16e (or “fourth slit”) in the regions on both sides is set at 2 mm.

The first flow rate adjusting member 15 and the second flow rate adjusting member 16 depicted in FIG. 25D are indicated as “SL3”. This configuration SL3 corresponds to the first flow rate adjusting member 15 and the second flow rate adjusting member 16 depicted in FIG. 22 described above. As the slits 15f, the first flow rate adjusting member 15 depicted in FIG. 25D has slits produced by dividing the slit 15e depicted in FIG. 25C described above into two in each of the regions obtained by dividing the first flow rate adjusting member 15 into three in the length direction. As the slits 16f, the second flow rate adjusting member 16 depicted in FIG. 25D has slits produced by dividing the slit 16e depicted in FIG. 25C described above into two in each of the regions obtained by dividing the second flow rate adjusting member 16 into three in the length direction.

The first flow rate adjusting member 15 and the second flow rate adjusting member 16 depicted in FIG. 25E are indicated as “SL4”. This configuration SL4 corresponds to the first flow rate adjusting member 15 and the second flow rate adjusting member 16 depicted in FIG. 23 described above. In the first flow rate adjusting member 15 depicted in FIG. 25E, out of a group of regions produced by dividing the first flow rate adjusting member 15 into three in the length direction, the diameters of the holes 15g are adjusted so that the aperture ratio of the center region (or “first region”) that is closest to the inlet 11 (IN) is larger than the aperture ratio in the regions on both sides (or “second regions”). The diameter of the holes 15g (or “first holes”) of the center region that is closest to the inlet 11 is set at 2 mm and the diameter of the holes 15g (or “second holes”) of the region on both sides is set at 1 mm. In addition, in the second flow rate adjusting member 16 depicted in FIG. 25E, out of a group of regions produced by dividing the second flow rate adjusting member 16 into three in the length direction, the diameters of the holes 16g are adjusted so that the aperture ratio in the center region (or “third region”) that is closest to the outlet 12 (OUT) is smaller than the aperture ratio in the regions on both sides (or “fourth regions”). The diameter of the holes 16g (or “third holes”) of the center region that is closest to the outlet 12 is set at 1 mm and the diameter of the holes 16g (or “fourth holes”) in the regions on both sides is set at 2 mm.

The first flow rate adjusting member 15 and the second flow rate adjusting member 16 depicted in FIG. 25F are indicated as “SL5”. This configuration SL5 corresponds to the first flow rate adjusting member 15 and the second flow rate adjusting member 16 depicted in FIG. 24 described above. In the first flow rate adjusting member 15 depicted in FIG. 25F, out of a group of regions produced by dividing the first flow rate adjusting member 15 into three in the length direction, the width of a slit 15h (or “fifth slit”) narrows from the center toward both sides so that the aperture ratio of the center region (or “first region”) closest to the inlet 11 (IN) is larger than the aperture ratio of the regions on both sides (or “second regions”). The width of the slit 15h at the center is set at 2 mm and the width at both ends is set at 1 mm. In the second flow rate adjusting member 16 depicted in FIG. 25F, out of a group of regions produced by dividing the second flow rate adjusting member 16 into three in the length direction, the width of a slit 16h (or “sixth slit”) widens from the center toward both sides so that the aperture ratio of the center region (or “third region”) closest to the outlet 12 (OUT) is smaller than the aperture ratio of the regions on both sides (or “fourth regions”). The width of the slit 16h at the center is set at 1 mm and the width at both ends is set at 2 mm.

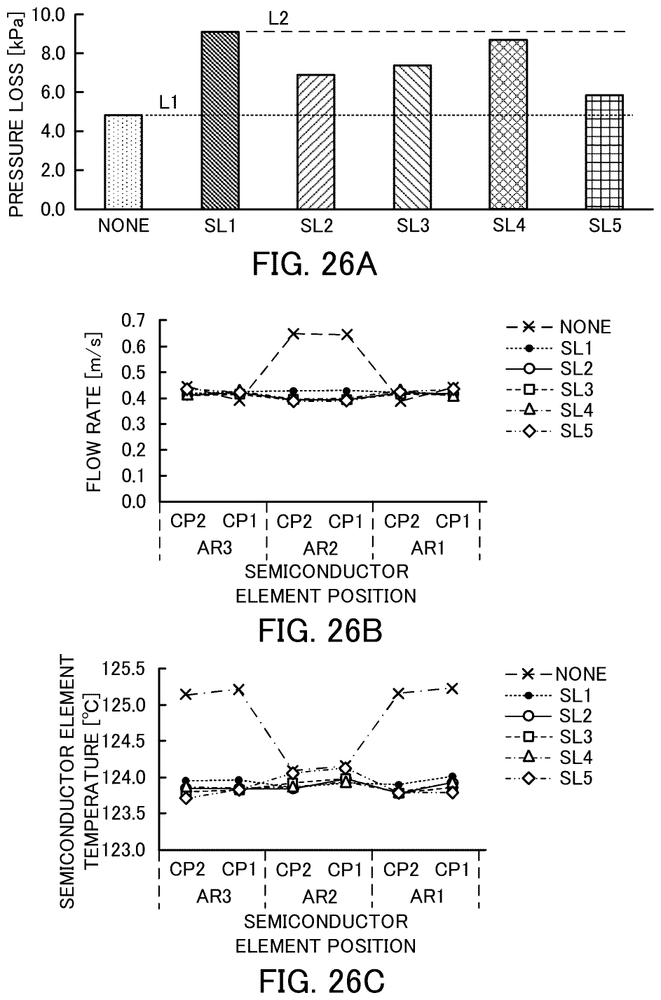

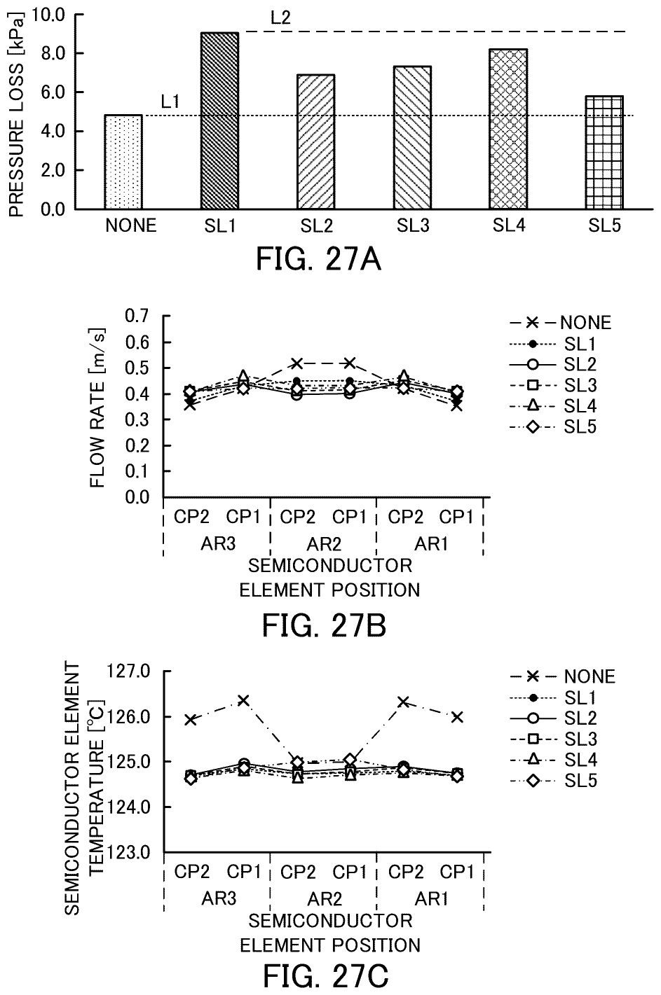

In the thermal fluid simulations, SL1 to SL5 depicted in FIGS. 25B to 25F are each used in a container 14 of a cooler 10 like that depicted in FIG. 25A. With respect to each of these cases, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the case where prismatic or cylindrical fins are used as the cooling fins 13a of the heat dissipating plate 13 described above. For comparison purposes, with respect to a configuration where the flow rate adjusting members (SL1 to SL5) are not used in the container 14 of the cooler 10 like that depicted in FIG. 25A, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the same way in the case where prismatic or cylindrical cooling fins 13a are used in the same way. Note that in the thermal fluid simulations, heat generation is reproduced by assigning a certain amount of loss to the semiconductor elements CP1 and CP2 in the mounting areas AR1 to AR3. The evaluation results produced by these thermal fluid simulations are depicted in FIGS. 26A to 26C and FIGS. 27A to 27C.

FIGS. 26A to 26C depict evaluation results produced by thermal fluid simulations of a first example cooler that uses prismatic cooling fins. FIG. 26A depicts example evaluation results of pressure loss in a cooler. FIG. 26B depicts example evaluation results of coolant flow rates relative to semiconductor element positions. FIG. 26C depicts example evaluation results of semiconductor element temperatures relative to semiconductor element positions. In FIGS. 26A to 26C, the flow rate adjusting members (that is, the first and second flow rate adjusting members) used in the container of a cooler are indicated as “SL1” to “SL5” (see FIG. 25B to FIG. 25F), with “NONE” indicating a “no flow rate adjusting member” configuration where no flow rate adjusting members are used.

From FIG. 26A, it may be understood that compared to the configuration with no flow rate adjusting members (the pressure loss indicated by the dotted line L1 in FIG. 26A), there is an increase of 90.1% in the pressure loss of the cooler 10 when SL1 is used, an increase of 44.3% when SL2 is used, an increase of 54.2% when SL3 is used, an increase of 81.6% when SL4 is used, and an increase of 22.9% when SL5 is used. On the other hand, compared to SL1 where the slit width is constant (the pressure loss indicated by the broken line L2 in FIG. 26A), the pressure loss of the cooler 10 decreases by 24.1% when SL2 is used, decreases by 18.9% when SL3 is used, decreases by 4.5% when SL4 is used, and decreases by 35.4% when SL5 is used. Accordingly, the increase in pressure loss relative to when no flow rate adjusting members are used is smaller when the configurations SL2 to SL5 are used than when the configuration SL1 is used.

From FIG. 26B, it may be understood that when there are no flow rate adjusting members, the coolant flow rates at the positions of the semiconductor elements CP1 and CP2 in the center mounting area AR2 are higher than the coolant flow rates at the positions of the semiconductor elements CP1 and CP2 in the mounting areas AR1 and AR3 at both ends, which means that an unbalanced flow distribution occurs. On the other hand, when SL1 to SL5 are used, the coolant flow rates at the positions of the semiconductor elements CP1 and CP2 in the mounting areas AR1 to AR3 are kept comparatively constant compared to the configuration with no flow rate adjusting members, which results in a more uniform flow.

From FIG. 26C, it may be understood that if there are no flow rate adjusting members, the temperatures of the semiconductor elements CP1 and CP2 in the center mounting area AR2 where the coolant flow rates are comparatively high are lower and the temperatures of the semiconductor elements CP1 and CP2 in the mounting areas AR1 and AR3 at both ends where the coolant flow rates are comparatively slow are higher. On the other hand, when SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 26A to 26C, it may be said that with the cooler 10 in FIG. 25A that uses prismatic cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 25 A that uses prismatic cooling fins, it may be said that when the configurations SL2 to SL5 are used, it is possible to suppress the increase in pressure loss compared to when the configuration SL1 is used but still achieve equal or nearly equal effects of suppressing an unbalanced flow distribution and cooling the semiconductor elements as when the configuration SL1 is used.

FIGS. 27A to 27C depict evaluation results produced by thermal fluid simulations of a first example cooler that uses cylindrical cooling fins. FIG. 27A depicts example evaluation results of pressure loss in a cooler. FIG. 27B depicts example evaluation results of coolant flow rates relative to semiconductor element positions. FIG. 27C depicts example evaluation results of semiconductor element temperatures relative to semiconductor element positions. In FIG. 27A to FIG. 27C, the flow rate adjusting members (that is, the first and second flow rate adjusting members) used in the container of a cooler are indicated as “SL1” to “SL5” (see FIG. 25B to FIG. 25F), with “NONE” indicating a configuration where no flow rate adjusting members are used.

From FIG. 27A, it may be understood that compared to the configuration with no flow rate adjusting members (the pressure loss indicated by the dotted line L1 in FIG. 27A), there is an increase of 86.4% in the pressure loss of the cooler 10 when SL1 is used, an increase of 42.4% when SL2 is used, an increase of 52.0% when SL3 is used, an increase of 69.6% when SL4 is used, and an increase of 20.4% when SL5 is used. On the other hand, compared to SL1 where the slit width is constant (the pressure loss indicated by the broken line L2 in FIG. 27A), the pressure loss of the cooler 10 decreases by 23.6% when SL2 is used, decreases by 18.5% when SL3 is used, decreases by 9.0% when SL4 is used, and decreases by 35.4% when SL5 is used. Accordingly, the increase in pressure loss relative to when no flow rate adjusting members are used is smaller when the configurations SL2 to SL5 are used than when the configuration SL1 is used.

From FIG. 27B, it may be understood that when there are no flow rate adjusting members, the coolant flow rates at the positions of the semiconductor elements CP1 and CP2 in the center mounting area AR2 are higher than the coolant flow rates at the positions of the semiconductor elements CP1 and CP2 in the mounting areas AR1 and AR3 at both ends, which means that an unbalanced flow distribution occurs. On the other hand, when the configurations SL1 to SL5 are used, the coolant flow rates at the positions of the semiconductor elements CP1 and CP2 in the mounting areas AR1 to AR3 are kept comparatively constant compared to the configuration with no flow rate adjusting members, which results in a more uniform flow.

From FIG. 27C, it may be understood that if there are no flow rate adjusting members, the temperatures of the semiconductor elements CP1 and CP2 in the center mounting area AR2 where the coolant flow rates are comparatively high are lower and the temperatures of the semiconductor elements CP1 and CP2 in the mounting areas AR1 and AR3 at both ends where the coolant flow rates are comparatively low are higher. On the other hand, when SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 27A to 27C, it may be said that with the cooler 10 in FIG. 25A that uses cylindrical cooling fins, when the configurations SL1 to SL5 are used, compared to the configuration with no flow rate adjusting member, a superior effect of suppressing an uneven flow distribution and a superior effect of cooling the semiconductor elements may be obtained. In the cooler 10 in FIG. 25A that uses cylindrical cooling fins, it may be said that when the configurations SL2 to SL5 are used, it is possible to suppress the increase in pressure loss compared to when the configuration SL1 is used but still achieve equal or nearly equal effects of suppressing the unbalanced flow distribution and cooling the semiconductor elements as when the configuration SL1 is used.

### Second Example

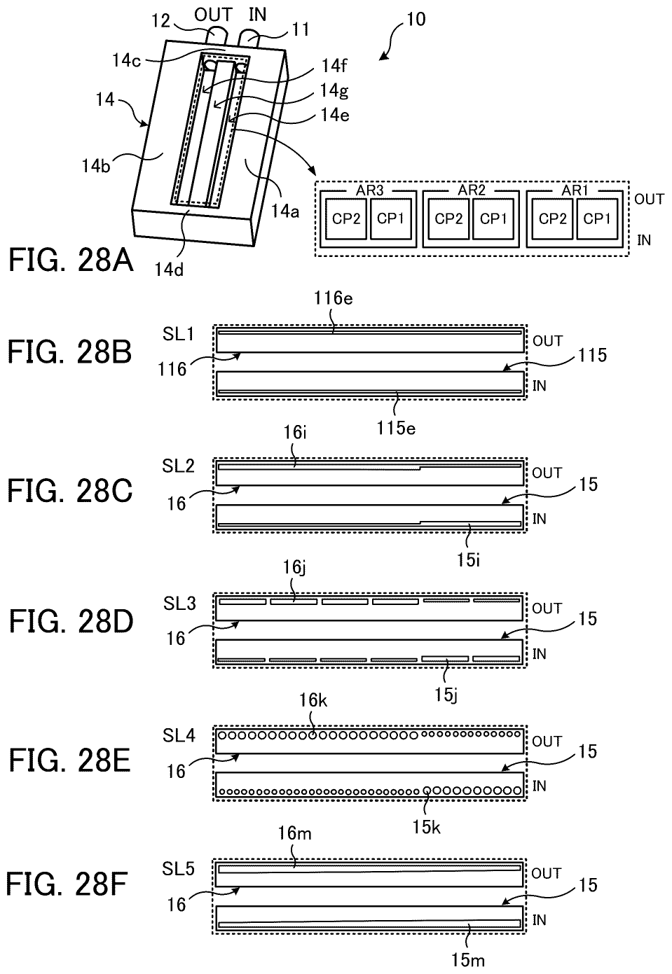

FIGS. 28A to 28F depict a second example of a cooler according to the fourth embodiment. FIG. 28A is a perspective view of a principal part of a second example of a cooler and schematically depicts the layout of semiconductor element mounting areas. FIGS. 28B to 28F are plan views schematically depicting principal parts of flow rate adjusting members used in this second example of a cooler.

In the second example, a container 14 like that depicted in FIG. 28A is used as the cooler 10. The container 14 depicted in FIG. 28A corresponds to a container 14 like that depicted in FIG. 18 described above. In the container 14 depicted in FIG. 28A, the inlet 11 (IN) that communicates with the first flow path 14e and the outlet 12 (OUT) that communicates with the second flow path 14f are disposed in the third side wall 14c. The cooling fins 13a of the heat dissipating plate 13 that covers the container 14 are housed in the third flow path 14g, which is an internal space above the first flow path 14e and the second flow path 14f. In the thermal fluid simulations, the cooling fins 13a that are prismatic like those depicted in FIGS. 3A and 3B described above, or are cylindrical like those depicted in FIGS. 15A and 15B are used. In a region corresponding to the third flow path 14g on the heat dissipating plate 13 (that is, the region indicated by the dotted frame in FIG. 28A), in keeping with the example in FIG. 1 and the like described above, a semiconductor element CP1 and a semiconductor element CP2 are disposed in each of the three mounting areas AR1, AR2, and AR3 as depicted in FIG. 28A.

Note that in FIG. 28A (and FIG. 28B to FIG. 28F described later), the inlet 11 side of the container 14 is indicated as “IN” and the outlet 12 side is indicated as “OUT”. The three mounting areas AR1 to AR3 and the semiconductor elements CP1 and CP2 provided in each of these areas have a positional relationship with respect to the IN and OUT of the container 14 like that depicted in FIG. 28A.

In the thermal fluid simulations, in a cooler 10 like that depicted in FIG. 28A, a first flow rate adjusting member 115 and a second flow rate adjusting member 116 like those depicted in FIG. 28B, and first flow rate adjusting members 15 and second flow rate adjusting members 16 like those depicted in FIGS. 28C to 28F are used.

Here, the first flow rate adjusting member 115 and the second flow rate adjusting member 116 depicted in FIG. 28B are indicated as “SL1”. This configuration SL1 corresponds to the first flow rate adjusting member 115 and the second flow rate adjusting member 116 depicted in FIG. 10 described above. The first flow rate adjusting member 115 and the second flow rate adjusting member 116 depicted in FIG. 28B respectively have a slit 115e (or “seventh slit”) and a slit 116e (or “eighth slit”) with a constant width extending in the length direction. The width of the slits 115e and 116e is set at 1 mm.

The first flow rate adjusting member 15 and the second flow rate adjusting member 16 depicted in FIG. 28C are indicated as “SL2”. This configuration SL2 corresponds to the first flow rate adjusting member 15 and the second flow rate adjusting member 16 depicted in FIG. 5 described above but with openings in a changed layout. In the first flow rate adjusting member 15 depicted in FIG. 28C, the width of the slit 15i is adjusted so that out of a group of regions produced by dividing the first flow rate adjusting member 15 into three in the length direction, the aperture ratio of the region (or “first region”) closest to the inlet 11 (IN) is larger than the aperture ratio of the remaining two regions (or “second regions”). The width of the slit 15i (or “first slit”) in the region closest to the inlet 11 is set at 2 mm, and the width of the slit 15i (or “second slit”) in the remaining two regions is set at 1 mm. In the second flow rate adjusting member 16 depicted in FIG. 28C, the width of the slit 16i is adjusted so that out of a group of regions produced by dividing the second flow rate adjusting member 16 into three in the length direction, the aperture ratio of the region (or “third region”) closest to the outlet 12 (OUT) is smaller than the aperture ratio of the remaining two regions (or “fourth regions”). The width of the slit 16i (or “third slit”) in the region closest to the outlet 12 is set at 1 mm, and the width of the slit 16i (or “fourth slit”) in the remaining regions is set at 2 mm.

The first flow rate adjusting member 15 and the second flow rate adjusting member 16 depicted in FIG. 28D are indicated as “SL3”. This configuration SL3 corresponds to the first flow rate adjusting member 15 and the second flow rate adjusting member 16 depicted in FIG. 22 described above but with openings in a changed layout. As slits 15j, the first flow rate adjusting member 15 depicted in FIG. 28D has slits produced by dividing the slit 15i depicted in FIG. 28C described above in two in each of the three regions obtained by dividing the first flow rate adjusting member 15 into three in the length direction. As slits 16j, the second flow rate adjusting member 16 depicted in FIG. 28D has slits produced by dividing the slit 16i depicted in FIG. 28C described above in two in each of the three regions obtained by dividing the second flow rate adjusting member 16 into three in the length direction.

The first flow rate adjusting member 15 and the second flow rate adjusting member 16 depicted in FIG. 28E are indicated as “SL4”. This configuration SL4 corresponds to the first flow rate adjusting member 15 and the second flow rate adjusting member 16 depicted in FIG. 23 described above but with openings in a changed layout. In the first flow rate adjusting member 15 depicted in FIG. 28E, out of a group of regions produced by dividing the first flow rate adjusting member 15 into three in the length direction, the diameters of holes 15k are adjusted so that the aperture ratio of the region (first region) that is closest to the inlet 11 (IN) is larger than the aperture ratio in the remaining two regions (or “second regions”). The diameter of the holes 15k (or “first holes”) of the region that is closest to the inlet 11 is set at 2 mm and the diameter of the holes 15k (or “second holes”) of the remaining regions is set at 1 mm. In addition, in the second flow rate adjusting member 16 depicted in FIG. 28E, out of a group of regions produced by dividing the second flow rate adjusting member 16 into three in the length direction, the diameters of holes 16k are adjusted so that the aperture ratio of the region (or “third region”) closest to the outlet 12 (OUT) is smaller than the aperture ratio of the remaining two regions (or “fourth regions”). The diameter of the holes 16k (or “third holes”) of the region that is closest to the outlet 12 is set at 1 mm and the diameter of the holes 16k (or “fourth holes”) in the remaining regions is set at 2 mm.

The first flow rate adjusting member 15 and the second flow rate adjusting member 16 depicted in FIG. 28F are indicated as “SL5”. This configuration SL5 corresponds to the first flow rate adjusting member 15 and the second flow rate adjusting member 16 depicted in FIG. 24 described above but with openings in a changed layout. In the first flow rate adjusting member 15 depicted in FIG. 28F, the width of a slit 15m (or “fifth slit”) is adjusted so that the aperture ratio of a region close to the inlet 11 (IN) (or “first region”) is (increasingly) larger than the aperture ratios of regions (or “second regions”) that are further from the inlet 11, or in other words, so that the slit 15m narrows as the distance from the inlet 11 increases. The width of the inlet 11-side end of the slit 15m is set at 2 mm and the width at the other end is set at 1 mm. In the second flow rate adjusting member 16 depicted in FIG. 28F, the width of a slit 16m (or “sixth slit”) is adjusted so that the aperture ratio of a region close to the outlet 12 (OUT) (or “third region”) is (increasingly) smaller than the aperture ratio of regions (or “fourth regions”) that are further from the outlet 12, or in other words, so that the slit 16m widens as the distance from the outlet 12 increases. The width of the outlet 12-side end of the slit 16m is set at 1 mm and the width at the other end is set at 2 mm.

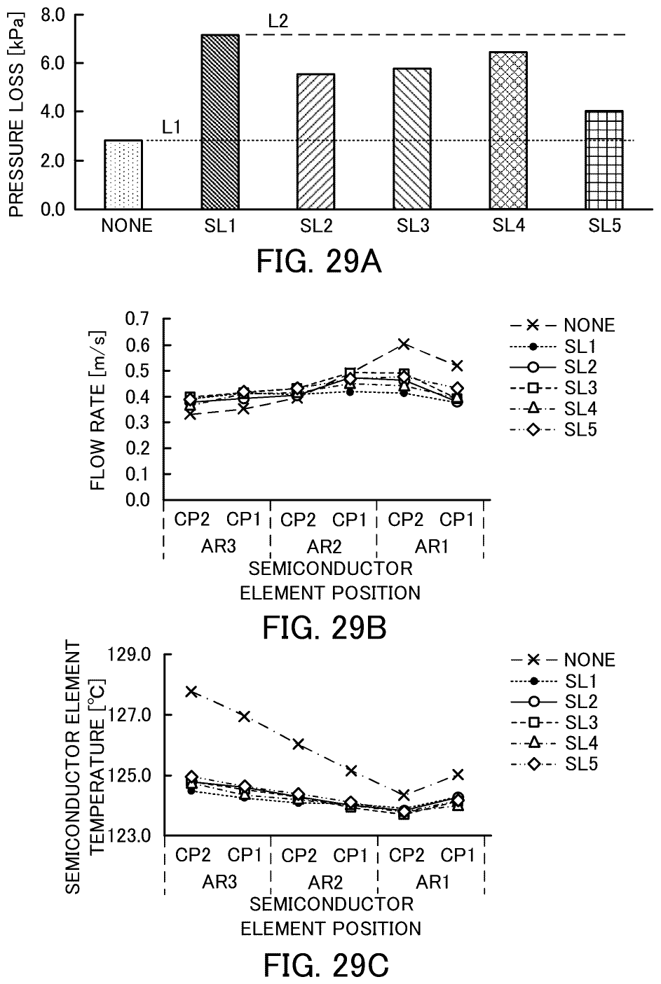

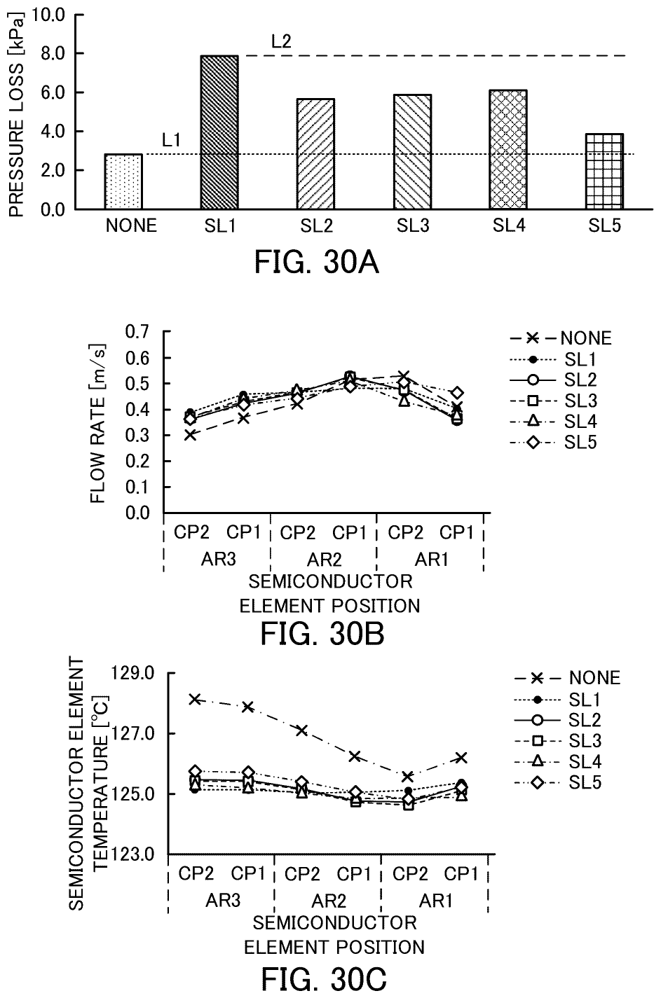

In the thermal fluid simulations, the configurations SL1 to SL5 depicted in FIGS. 28B to 28F are each used in a container 14 of a cooler 10 like that depicted in FIG. 28A. With respect to each of these cases, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the case where prismatic or cylindrical fins are used as the cooling fins 13a of the heat dissipating plate 13 described above. For comparison purposes, with respect to a configuration where the flow rate adjusting members (SL1 to SL5) are not used in the container 14 of a cooler 10 like that depicted in FIG. 28A, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the same way in the case where prismatic or cylindrical cooling fins 13a are used. Note that in the thermal fluid simulations, heat generation is reproduced by assigning a certain amount of loss to the semiconductor elements CP1 and CP2 in the mounting areas AR1 to AR3. The evaluation results produced by these thermal fluid simulations are depicted in FIGS. 29A to 29C and FIGS. 30A to 30C.

FIGS. 29A to 29C depict evaluation results produced by thermal fluid simulations of a second example cooler that uses prismatic cooling fins. FIG. 29A depicts example evaluation results of pressure loss in a cooler. FIG. 29B depicts example evaluation results of coolant flow rates relative to semiconductor element positions. FIG. 29C depicts example evaluation results of semiconductor element temperatures relative to semiconductor element positions. In FIG. 29A to FIG. 29C, the flow rate adjusting members (that is, the first and second flow rate adjusting members) used in the container of a cooler are indicated as “SL1” to “SL5” (see FIG. 28B to FIG. 28F), with “NONE” indicating a configuration where no flow rate adjusting members are used.

From FIG. 29A, it may be understood that compared to the configuration with no flow rate adjusting members (the pressure loss indicated by the dotted line L1 in FIG. 29A), there is an increase of 153.2% in the pressure loss of the cooler 10 when SL1 is used, an increase of 96.7% when SL2 is used, an increase of 104.2% when SL3 is used, an increase of 128.2% when SL4 is used, and an increase of 42.5% when SL5 is used. On the other hand, compared to SL1 where the slit width is constant (the pressure loss indicated by the broken line L2 in FIG. 29A), the pressure loss of the cooler 10 decreases by 22.3% when SL2 is used, decreases by 19.4% when SL3 is used, decreases by 9.9% when SL4 is used, and decreases by 43.7% when SL5 is used. Accordingly, the increase in pressure loss relative to when no flow rate adjusting members are used is smaller when the configurations SL2 to SL5 are used than when the configuration SL1 is used.

From FIG. 29B, it may be understood that when there are no flow rate adjusting members, the coolant flow rates at the positions of the semiconductor elements CP1 and CP2 in the mounting area AR2 are higher than the coolant flow rates at positions of the semiconductor elements CP1 and CP2 in the mounting areas AR1 and AR3, which means that an unbalanced flow distribution occurs. On the other hand, when the configurations SL1 to SL5 are used, an unbalanced flow distribution of the coolant at the positions of the semiconductor elements CP1 and CP2 in the mounting areas AR1 to AR3 is suppressed compared to the configuration with no flow rate adjusting members, which means that a more uniform flow is produced.

From FIG. 29C, it may be understood that if there are no flow rate adjusting members, the temperatures of the semiconductor elements CP1 and CP2 in the mounting area AR1 where the coolant flow rate is comparatively high are lower and the temperatures of the semiconductor elements CP1 and CP2 in the mounting areas AR2 and AR3 where the coolant flow rate is comparatively low are higher. On the other hand, when SL1 to SL5 are used, compared to the configuration with no flow rate adjusting member, the temperatures of the semiconductor elements CP1 and CP2 in the mounting areas AR1 to AR3 are kept comparatively constant and are cooled more uniformly.

From the results depicted in FIGS. 29A to 29C, it may be said that with the cooler 10 in FIG. 28A that uses prismatic cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 28 A that uses prismatic cooling fins, it may be said that when the configurations SL2 to SL5 are used, it is possible to suppress the increase in pressure loss compared to when the configuration SL1 is used but still achieve equal or nearly equal effects of suppressing an unbalanced flow distribution and cooling the semiconductor elements as when the configuration SL1 is used.

FIGS. 30A to 30C depict evaluation results produced by thermal fluid simulations of a second example cooler that uses cylindrical cooling fins. FIG. 30A depicts example evaluation results of pressure loss in a cooler. FIG. 30B depicts example evaluation results of coolant flow rates relative to semiconductor element positions. FIG. 30C depicts example evaluation results of semiconductor element temperatures relative to semiconductor element positions. In FIG. 30A to FIG. 30C, the flow rate adjusting members (that is, the first and second flow rate adjusting members) used in the container of a cooler are indicated as “SL1” to “SL5” (see FIG. 28B to FIG. 28F), with “NONE” indicating a configuration where no flow rate adjusting members are used.

From FIG. 30A, it may be understood that compared to the configuration with no flow rate adjusting members (the pressure loss indicated by the dotted line L1 in FIG. 30A), there is an increase of 176.5% in the pressure loss of the cooler 10 when SL1 is used, an increase of 98.5% when SL2 is used, an increase of 105.4% when SL3 is used, an increase of 114.1% when SL4 is used, and an increase of 35.1% when SL5 is used. On the other hand, compared to SL1 where the slit width is constant (the pressure loss indicated by the broken line L2 in FIG. 30A), the pressure loss of the cooler 10 decreases by 28.2% when SL2 is used, decreases by 25.7% when SL3 is used, decreases by 22.6% when SL4 is used, and decreases by 51.1% when SL5 is used. Accordingly, the increase in pressure loss relative to when no flow rate adjusting members are used is smaller when the configurations SL2 to SL5 are used than when the configuration SL1 is used.

From FIG. 30B, it may be understood that when there are no flow rate adjusting members, the coolant flow rates at the positions of the semiconductor elements CP1 and CP2 in the mounting area AR3 are lower than the coolant flow rates at positions of the semiconductor elements CP1 and CP2 in the mounting areas AR1 and AR2, which means that an unbalanced flow distribution occurs. On the other hand, when the configurations SL1 to SL5 are used, an unbalanced flow distribution of the coolant at the positions of the semiconductor elements CP1 and CP2 in the mounting areas AR1 to AR3 is suppressed compared to the configuration with no flow rate adjusting members, which results in a more uniform flow.

From FIG. 30C, it may be understood that if there are no flow rate adjusting members, the temperatures of the semiconductor elements CP1 and CP2 in the mounting areas AR1 to AR3 are comparatively high. On the other hand, when the configurations SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 30A to 30C, it may be said that with the cooler 10 in FIG. 28A that uses cylindrical cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 28A that uses cylindrical cooling fins, it may be said that when the configurations SL2 to SL5 are used, it is possible to suppress the increase in pressure loss compared to when the configuration SL1 is used but still achieve equal or nearly equal effects of suppressing an unbalanced flow distribution and cooling the semiconductor elements as when the configuration SL1 is used.

### Third Example

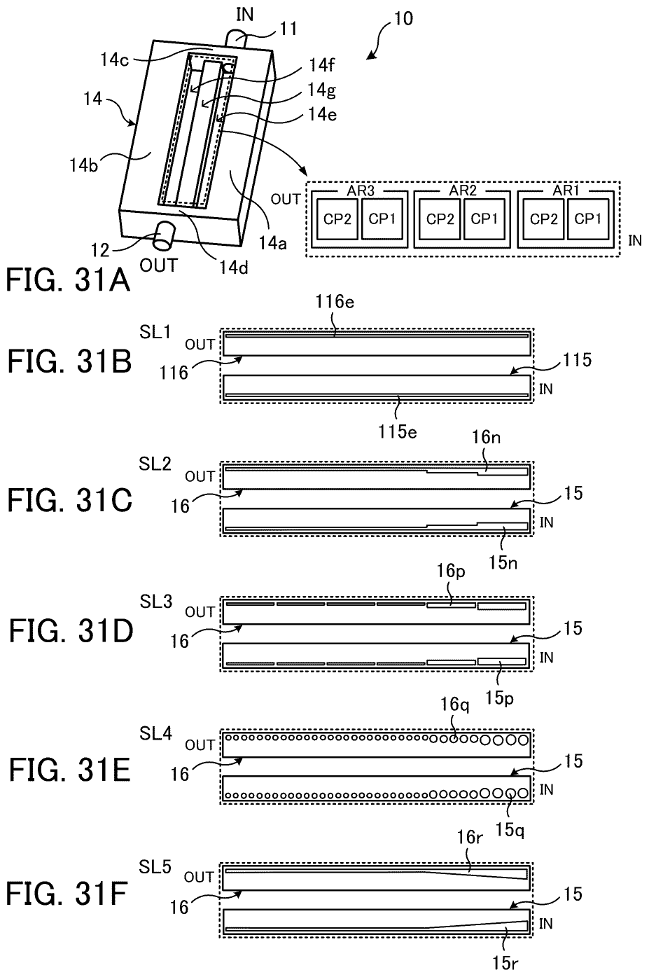

FIGS. 31A to 31F depict a third example of a cooler according to the fourth embodiment. FIG. 31A is a perspective view of a principal part of a third example of a cooler and schematically depicts the layout of semiconductor element mounting areas. FIGS. 31B to 31F are plan views schematically depicting principal parts of flow rate adjusting members used in this third example of a cooler.

In the third example, a container 14 like that depicted in FIG. 31A is used as the cooler 10. The container 14 depicted in FIG. 31A corresponds to a container 14 like that depicted in FIG. 19 described above. In the container 14 depicted in FIG. 31A, the inlet 11 (IN) that communicates with the first flow path 14e is disposed in the third side wall 14c and the outlet 12 (OUT) that communicates with the second flow path 14f is disposed in the fourth side wall 14d. The cooling fins 13a of the heat dissipating plate 13 described above that covers the container 14 are housed in the third flow path 14g, which is an internal space above the first flow path 14e and the second flow path 14f. In the thermal fluid simulations, the cooling fins 13a that are prismatic like those depicted in FIGS. 3A and 3B described above, or are cylindrical like those depicted in FIGS. 15A and 15B are used. In a region corresponding to the third flow path 14g on the heat dissipating plate 13 (that is, the region indicated by the dotted frame in FIG. 31A), in keeping with the example in FIG. 1 and the like described above, a semiconductor element CP1 and a semiconductor element CP2 are disposed in each of the three mounting areas AR1, AR2, and AR3 as depicted in FIG. 31A.

Note that in FIG. 31A (and FIG. 31B to FIG. 31F described later), the inlet 11 side of the container 14 is indicated as “IN” and the outlet 12 side is indicated as “OUT”. The three mounting areas AR1 to AR3 and the semiconductor elements CP1 and CP2 provided in each of these areas have a positional relationship with respect to the IN and OUT of the container 14 like that depicted in FIG. 31A.

In the thermal fluid simulations, in a cooler 10 like that depicted in FIG. 31A, a first flow rate adjusting member 115 and a second flow rate adjusting member 116 like those depicted in FIG. 31B, and first flow rate adjusting members 15 and second flow rate adjusting members 16 like those depicted in FIGS. 31C to 31F are used.

Here, the first flow rate adjusting member 115 and the second flow rate adjusting member 116 depicted in FIG. 31B are indicated as “SL1”. This configuration SL1 corresponds to the first flow rate adjusting member 115 and the second flow rate adjusting member 116 depicted in FIG. 10 described above. The first flow rate adjusting member 115 and the second flow rate adjusting member 116 depicted in FIG. 31B respectively have a slit 115e (or “seventh slit”) and a slit 116e (or “eighth slit”) with a constant width extending in the length direction. The width of the slits 115e and 116e is set at 1 mm.

The first flow rate adjusting member 15 and the second flow rate adjusting member 16 depicted in FIG. 31C are indicated as “SL2”. This configuration SL2 corresponds to the first flow rate adjusting member 15 and the second flow rate adjusting member 16 depicted in FIG. 5 described above but with openings in a changed layout. In the first flow rate adjusting member 15 depicted in FIG. 31C, the width of the slit 15n is adjusted so that out of a group of regions produced by dividing the first flow rate adjusting member 15 into three in the length direction, the aperture ratio of a region (or “first region”) at an end closest to the inlet 11 (IN) is larger than the aperture ratio of the remaining two regions (or “second regions”). The width of the slit 15n (or “first slit”) in the region at the end closest to the inlet 11 has parts with different widths. The width at the wider part is set at 3 mm and the width at the narrower part is set at 2 mm. The width of the slit 15n (or “second slit”) in the other regions is set at 1 mm. In the second flow rate adjusting member 16 depicted in FIG. 31C, the width of the slit 16n is adjusted so that out of a group of regions produced by dividing the second flow rate adjusting member 16 into three in the length direction, the aperture ratio of the region (or “fourth region”) furthest from the outlet 12 (OUT) is larger than the aperture ratio of the remaining two regions (or “third regions”). The width of the slit 16n (or “fourth slit”) in the region at the end furthest from the outlet 12 has parts with different widths. The width at the wider part is set at 3 mm and the width at the narrower part is set at 2 mm. The width of the slit 16n (or “third slit”) in the other regions is set at 1 mm.

The first flow rate adjusting member 15 and the second flow rate adjusting member 16 depicted in FIG. 31D are indicated as “SL3”. This configuration SL3 corresponds to the first flow rate adjusting member 15 and the second flow rate adjusting member 16 depicted in FIG. 22 described above but with openings in a changed layout. As slits 15p, the first flow rate adjusting member 15 depicted in FIG. 31D has slits produced by dividing the slit 15n depicted in FIG. 31C described above in two in each region obtained by dividing the first flow rate adjusting member 15 into three in the length direction (for the region at the end closest to the inlet 11, the two parts are the wider part and the narrower part). The second flow rate adjusting member 16 depicted in FIG. 31D has slits 16p produced by dividing the slit 16n depicted in FIG. 31C described above in two in each region obtained by dividing the second flow rate adjusting member 16 into three in the length direction (in the region at the end furthest from the outlet 12, the two parts are the wider part and the narrower part).

The first flow rate adjusting member 15 and the second flow rate adjusting member 16 depicted in FIG. 31E are indicated as “SL4”. This configuration SL4 corresponds to the first flow rate adjusting member 15 and the second flow rate adjusting member 16 depicted in FIG. 23 described above but with openings in a changed layout. In the first flow rate adjusting member 15 depicted in FIG. 31E, out of a group of regions produced by dividing the first flow rate adjusting member 15 into three in the length direction, the diameters of holes 15q are adjusted so that the aperture ratio of the region (or “first region”) at the end closest to the inlet 11 (IN) is larger than the aperture ratio in the remaining two regions (or “second regions”). The holes 15q (or “first holes”) in the region at the end closest to the inlet 11 have different diameters, with the diameter set at 3 mm for the larger holes and at 2 mm for the smaller holes. The diameter of the holes 15q (or “second holes”) in the remaining regions is set at 1 mm. Likewise, in the second flow rate adjusting member 16 depicted in FIG. 31E, the diameters of holes 16q are adjusted so that out of a group of regions produced by dividing the second flow rate adjusting member 16 into three in the length direction, the aperture ratio of the region (or “fourth region”) at the end furthest from the outlet 12 (OUT) is larger than the aperture ratio in the remaining two regions (or “third regions”). The holes 16q (or “fourth holes”) in the region at the end furthest from the outlet 12 have different diameters, with the diameter set at 3 mm for the larger holes and at 2 mm for the smaller holes. The diameter of the holes 16q (or “third holes”) in the remaining regions is set at 1 mm.

The first flow rate adjusting member 15 and the second flow rate adjusting member 16 depicted in FIG. 31F are indicated as “SL5”. This configuration SL5 corresponds to the first flow rate adjusting member 15 and the second flow rate adjusting member 16 depicted in FIG. 24 described above but with openings in a changed layout. In the first flow rate adjusting member 15 depicted in FIG. 31F, the width of a slit 15r (or “fifth slit”) is adjusted so that out of a group of regions produced by dividing the first flow rate adjusting member 15 into three in the length direction, the aperture ratio of the region (or “first region”) at the end closest to the inlet 11 (IN) is larger than the aperture ratio of the remaining two regions (or “second regions”). The width of the inlet 11 side end of the slit 15r in the region at the end closest to the inlet 11 is set at 3 mm, with the width narrowing toward 1 mm as the distance from the inlet 11 increases. The width of the slit 15r in the remaining regions is set at 1 mm. Likewise, in the second flow rate adjusting member 16 depicted in FIG. 31F, the width of a slit 16r (or “sixth slit”) is adjusted so that out of a group of regions produced by dividing the second flow rate adjusting member 16 into three in the length direction, the aperture ratio of the region (or “fourth region”) at the end furthest from the outlet 12 (OUT) is larger than the aperture ratio of the remaining two regions (or “third regions”). The width of the slit 16r at the opposite end to the end closest to the outlet 12 in the region at the end furthest from the outlet 12 is set at 3 mm, with the width in this region narrowing to 1 mm while approaching the outlet 12 side end. The width of the slit 16r in the remaining regions is set at 1 mm.

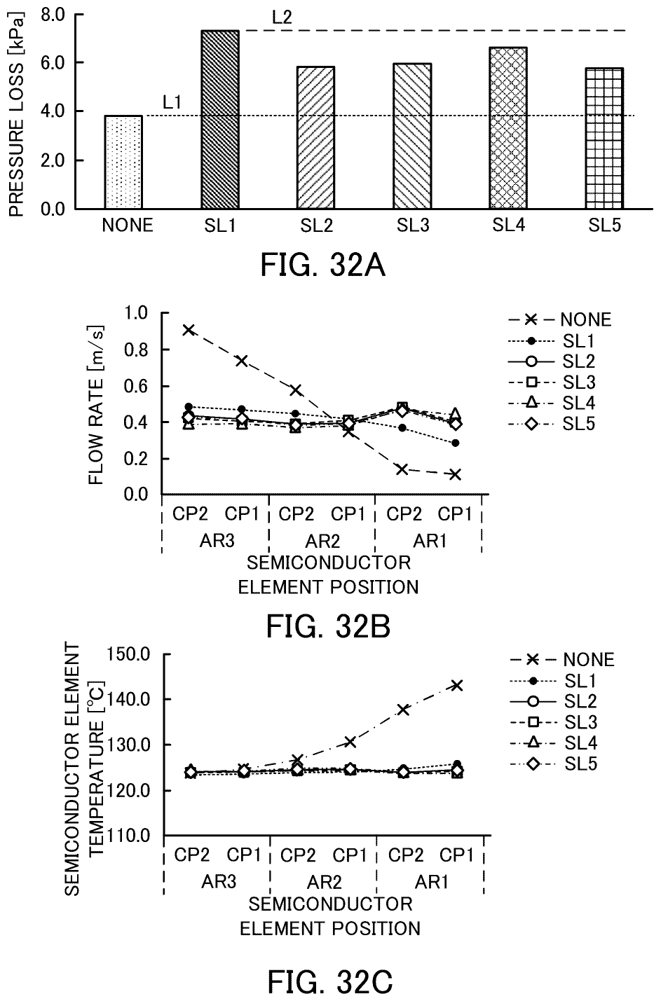

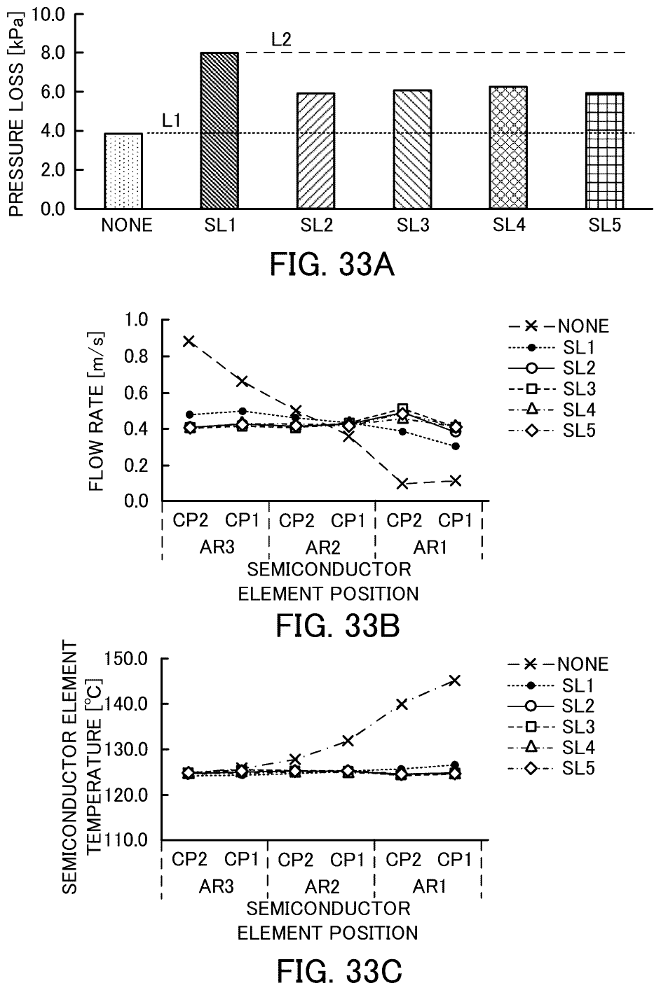

In the thermal fluid simulations, the configurations SL1 to SL5 depicted in FIGS. 31B to 31F are each used in a container 14 of a cooler 10 like that depicted in FIG. 31A. With respect to each of these cases, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the case where prismatic or cylindrical fins are used as the cooling fins 13a of the heat dissipating plate 13 described above. For comparison purposes, with respect to a configuration where the flow rate adjusting members (SL1 to SL5) are not used in the container 14 of the cooler 10 like that depicted in FIG. 31A, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the same way in the case where prismatic or cylindrical cooling fins 13a are used. Note that in the thermal fluid simulations, heat generation is reproduced by assigning a certain amount of loss to the semiconductor elements CP1 and CP2 in the mounting areas AR1 to AR3. The evaluation results produced by these thermal fluid simulations are depicted in FIGS. 32A to 32C and FIGS. 33A to 33C.

FIGS. 32A to 32C depict evaluation results produced by thermal fluid simulations of a third example cooler that uses prismatic cooling fins. FIG. 32A depicts example evaluation results of pressure loss in a cooler. FIG. 32B depicts example evaluation results of coolant flow rates relative to semiconductor element positions. FIG. 32C depicts example evaluation results of semiconductor element temperatures relative to semiconductor element positions. In FIGS. 32A to 32C, the flow rate adjusting members (that is, the first and second flow rate adjusting members) used in the container of a cooler are indicated as “SL1” to “SL5” (see FIG. 31B to FIG. 31F), with “NONE” indicating a configuration where no flow rate adjusting members are used.

From FIG. 32A, it may be understood that compared to the configuration with no flow rate adjusting members (the pressure loss indicated by the dotted line L1 in FIG. 32A), there is an increase of 91.2% in the pressure loss of the cooler 10 when SL1 is used, an increase of 52.1% when SL2 is used, an increase of 56.1% when SL3 is used, an increase of 72.9% when SL4 is used, and an increase of 50.6% when SL5 is used. On the other hand, compared to SL1 where the slit width is constant (the pressure loss indicated by the broken line L2 in FIG. 32A), the pressure loss of the cooler 10 decreases by 20.4% when SL2 is used, decreases by 18.4% when SL3 is used, decreases by 9.6% when SL4 is used, and decreases by 21.2% when SL5 is used. Accordingly, the increase in pressure loss relative to when no flow rate adjusting members are used is smaller when the configurations SL2 to SL5 are used than when the configuration SL1 is used.

From FIG. 32B, it may be understood that when there are no flow rate adjusting members, the coolant flow rates are slower at the positions of the semiconductor elements CP1 and CP2 in the mounting area AR1 and the coolant flow rates are faster at the positions of the semiconductor elements CP1 and CP2 in the mounting area AR3, which means that an unbalanced flow distribution occurs. On the other hand, when SL1 to SL5 are used, the unbalanced flow distribution of the coolant is suppressed at the positions of the semiconductor elements CP1 and CP2 in the mounting areas AR1 to AR3 compared to the configuration with no flow rate adjusting members, which results in a more uniform flow.

From FIG. 32C, it may be understood that if there are no flow rate adjusting members, the temperatures of the semiconductor elements CP1 and CP2 become increasingly high toward the mounting area AR1 where the coolant flow rate is slow. On the other hand, when SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 32A to 32C, it may be said that with the cooler 10 in FIG. 31A that uses prismatic cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 31A that uses prismatic cooling fins, it may be said that when the configurations SL2 to SL5 are used, it is possible to suppress the increase in pressure loss compared to when the configuration SL1 is used but still achieve equal or nearly equal effects of suppressing the unbalanced flow distribution and cooling the semiconductor elements as when the configuration SL1 is used.

FIGS. 33A to 33C depict evaluation results produced by thermal fluid simulations of a third example cooler that uses cylindrical cooling fins. FIG. 33A depicts example evaluation results of pressure loss in a cooler. FIG. 33B depicts example evaluation results of coolant flow rates relative to semiconductor element positions. FIG. 33C depicts example evaluation results of semiconductor element temperature relative to semiconductor element positions. In FIG. 33A to FIG. 33C, the flow rate adjusting members (that is, the first and second flow rate adjusting members) used in the container of a cooler are indicated as “SL1” to “SL5” (see FIG. 31B to FIG. 31F), with “NONE” indicating a configuration where no flow rate adjusting members are used.

From FIG. 33A, it may be understood that compared to the configuration with no flow rate adjusting members (the pressure loss indicated by the dotted line L1 in FIG. 33A), there is an increase of 106.8% in the pressure loss of the cooler 10 when SL1 is used, an increase of 53.0% when SL2 is used, an increase of 56.9% when SL3 is used, an increase of 62.0% when SL4 is used, and an increase of 53.0% when SL5 is used. On the other hand, compared to SL1 where the slit width is constant (the pressure loss indicated by the broken line L2 in FIG. 33A), the pressure loss of the cooler 10 decreases by 26.0% when SL2 is used, decreases by 24.1% when SL3 is used, decreases by 21.6% when SL4 is used, and decreases by 26.0% when SL5 is used. Accordingly, the increase in pressure loss relative to when no flow rate adjusting members are used is smaller when the configurations SL2 to SL5 are used than when the configuration SL1 is used.

From FIG. 33B, it may be understood that when there are no flow rate adjusting members, the coolant flow rates at the positions of the semiconductor elements CP1 and CP2 in the mounting area AR1 are slow and the coolant flow rates at the positions of the semiconductor elements CP1 and CP2 in the mounting area AR3 are high, which means that an unbalanced flow distribution occurs. On the other hand, when SL1 to SL5 are used, an unbalanced flow distribution of coolant at the positions of the semiconductor elements CP1 and CP2 in the mounting areas AR1 to AR3 is suppressed compared to the configuration with no flow rate adjusting members, which results in a more uniform flow.

From FIG. 33C, it may be understood that when there are no flow rate adjusting members, the temperatures of the semiconductor elements CP1 and CP2 increase toward the mounting area AR1 where the coolant flow rate is slow. On the other hand, when SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 33A to 33C, it may be said that with the cooler 10 in FIG. 31A that uses cylindrical cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 31A that uses cylindrical cooling fins, it may be said that when the configurations SL2 to SL5 are used, it is possible to suppress the increase in pressure loss compared to when the configuration SL1 is used but still achieve equal or nearly equal effects of suppressing the unbalanced flow distribution and cooling the semiconductor elements as when the configuration SL1 is used.

### Fourth Example

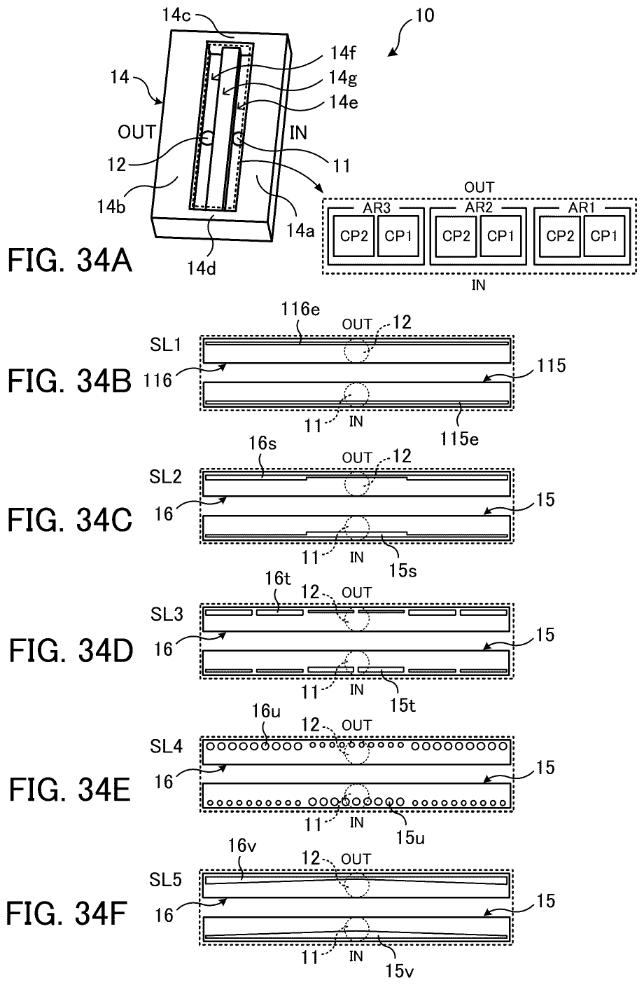

FIGS. 34A to 34F depict a fourth example of a cooler according to the fourth embodiment. FIG. 34A is a perspective view of a principal part of a fourth example of a cooler and schematically depicts the layout of semiconductor element mounting areas. FIGS. 34B to 34F are plan views schematically depicting principal parts of flow rate adjusting members used in this fourth example of a cooler.

In the fourth example, a container 14 like that depicted in FIG. 34A is used as the cooler 10. The container 14 depicted in FIG. 34A corresponds to a container 14 like that depicted in FIG. 20 described above. In the container 14 depicted in FIG. 34A, the inlet 11 (IN) that communicates with the center of the first flow path 14e and the outlet 12 (OUT) that communicates with the center of the second flow path 14f are disposed in the bottom plate 14h. The cooling fins 13a of the heat dissipating plate 13 described above that covers the container 14 are housed in the third flow path 14g, which is an internal space above the first flow path 14e and the second flow path 14f. In the thermal fluid simulations, the cooling fins 13a that are prismatic like those depicted in FIGS. 3A and 3B described above, or are cylindrical like those depicted in FIGS. 15A and 15B are used. In a region corresponding to the third flow path 14g on the heat dissipating plate 13 (that is, the region indicated by the dotted frame in FIG. 34A), in keeping with the example in FIG. 1 and the like described above, a semiconductor element CP1 and a semiconductor element CP2 are disposed in each of the three mounting areas AR1, AR2, and AR3 as depicted in FIG. 34A.

Note that in FIG. 34A (and FIG. 34B to FIG. 34F described later), the inlet 11 side of the container 14 is indicated as “IN” and the outlet 12 side is indicated as “OUT”. The three mounting areas AR1 to AR3 and the semiconductor elements CP1 and CP2 provided in each of these areas have a positional relationship with respect to the IN and OUT of the container 14 like that depicted in FIG. 34A.

In the thermal fluid simulations, in a cooler 10 like that depicted in FIG. 34A, a first flow rate adjusting member 115 and a second flow rate adjusting member 116 like those depicted in FIG. 34B, and first flow rate adjusting members 15 and a second flow rate adjusting members 16 like those depicted in FIGS. 34C to 34F are used. Note that the positions of the inlet 11 (IN) and the outlet 12 (OUT) are indicated in FIG. 34B to FIG. 34F.

Here, the first flow rate adjusting member 115 and the second flow rate adjusting member 116 depicted in FIG. 34B are indicated as “SL1”. The configuration SL1 corresponds to the first flow rate adjusting member 115 and the second flow rate adjusting member 116 depicted in FIG. 10 described above. The first flow rate adjusting member 115 and the second flow rate adjusting member 116 depicted in FIG. 34B respectively have a slit 115e (or “seventh slit”) and a slit 116e (or “eighth slit”) with a constant width extending in the length direction. The width of the slits 115e and 116e is set at 1 mm.

The first flow rate adjusting member 15 and the second flow rate adjusting member 16 depicted in FIG. 34C are indicated as “SL2”. The first flow rate adjusting member 15 depicted in FIG. 34C includes, as a slit 15s, a similar slit to the slit 15e of the first flow rate adjusting member 15 depicted in FIG. 25C described above. The second flow rate adjusting member 16 depicted in FIG. 34C includes, as a slit 16s, a similar slit to the slit 16e of the second flow rate adjusting member 16 depicted in FIG. 25C described above.

The first flow rate adjusting member 15 and the second flow rate adjusting member 16 depicted in FIG. 34D are indicated as “SL3”. The first flow rate adjusting member 15 depicted in FIG. 34D includes, as slits 15t, similar slits to the slits 15f of the first flow rate adjusting member 15 depicted in FIG. 25D described above. The second flow rate adjusting member 16 depicted in FIG. 34D includes, as slits 16t, similar slits to the slits 16f of the second flow rate adjusting member 16 depicted in FIG. 25D described above.

The first flow rate adjusting member 15 and the second flow rate adjusting member 16 depicted in FIG. 34E are indicated as “SL4”. The first flow rate adjusting member 15 depicted in FIG. 34E includes, as holes 15u, similar holes to the holes 15g of the first flow rate adjusting member 15 depicted in FIG. 25E described above. The second flow rate adjusting member 16 depicted in FIG. 34E includes, as holes 16u, similar holes to the holes 16g of the second flow rate adjusting member 16 depicted in FIG. 25E described above.

The first flow rate adjusting member 15 and the second flow rate adjusting member 16 depicted in FIG. 34F are indicated as “SL5”. The first flow rate adjusting member 15 depicted in FIG. 34F includes, as a slit 15v, a similar slit to the slit 15h of the first flow rate adjusting member 15 depicted in FIG. 25F described above. The second flow rate adjusting member 16 depicted in FIG. 34F includes, as a slit 16v, a similar slit to the slit 16h of the second flow rate adjusting member 16 depicted in FIG. 25F described above.

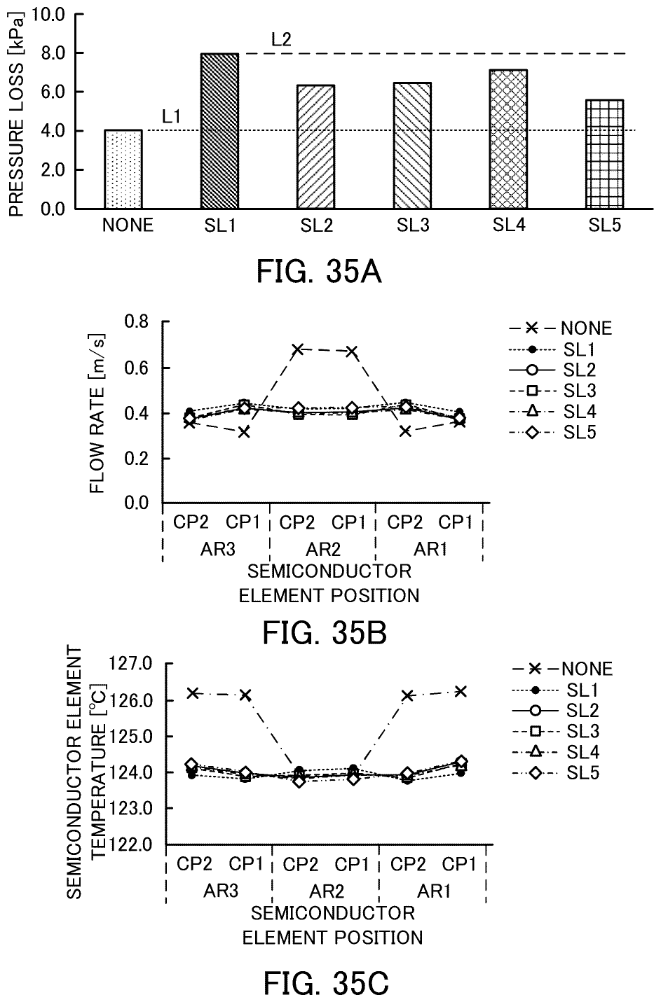

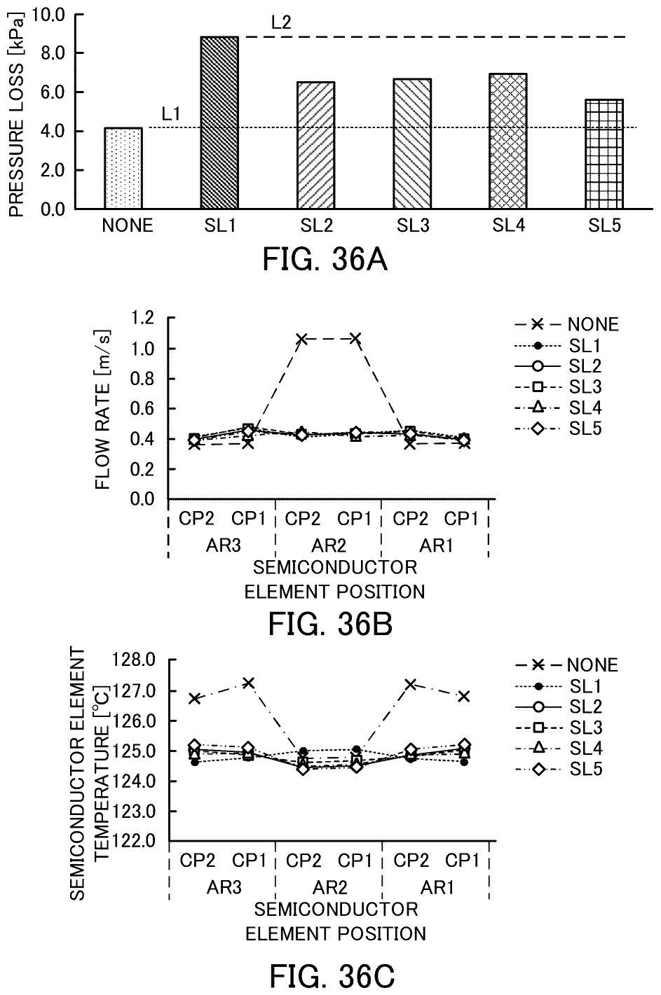

In the thermal fluid simulations, the configurations SL1 to SL5 depicted in FIGS. 34B to 34F are each used in the container 14 of a cooler 10 like that depicted in FIG. 34A. With respect to each of these cases, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the case where prismatic or cylindrical fins are used as the cooling fins 13a of the heat dissipating plate 13 described above. For comparison purposes, with respect to a configuration where the flow rate adjusting members (SL1 to SL5) are not used in the container 14 of the cooler 10 like that depicted in FIG. 34A, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the same way in the case where prismatic or cylindrical cooling fins 13a are used. Note that in the thermal fluid simulations, heat generation is reproduced by assigning a certain amount of loss to the semiconductor elements CP1 and CP2 in the mounting areas AR1 to AR3. The evaluation results produced by thermal fluid simulations are depicted in FIGS. 35A to 35C and FIGS. 36A to 36C.

FIGS. 35A to 35C depict evaluation results produced by thermal fluid simulations of a fourth example cooler that uses prismatic cooling fins. FIG. 35A depicts example evaluation results of pressure loss in a cooler. FIG. 35B depicts example evaluation results of coolant flow rates relative to semiconductor element positions. FIG. 35C depicts example evaluation results of semiconductor element temperatures relative to semiconductor element positions. In FIG. 35A to FIG. 35C, the flow rate adjusting members (that is, the first and second flow rate adjusting members) used in the container of a cooler are indicated as “SL1” to “SL5” (see FIG. 34B to FIG. 34F), with “NONE” indicating a configuration where no flow rate adjusting members are used.

From FIG. 35A, it may be understood that compared to the configuration with no flow rate adjusting members (the pressure loss indicated by the dotted line L1 in FIG. 35A), there is an increase of 98.7% in the pressure loss of the cooler 10 when SL1 is used, an increase of 58.5% when SL2 is used, an increase of 62.2% when SL3 is used, an increase of 78.3% when SL4 is used, and an increase of 38.9% when SL5 is used. On the other hand, compared to SL1 where the slit width is constant (the pressure loss indicated by the broken line L2 in FIG. 35A), the pressure loss of the cooler 10 decreases by 20.2% when SL2 is used, decreases by 18.4% when SL3 is used, decreases by 10.3% when SL4 is used, and decreases by 30.1% when SL5 is used. Accordingly, the increase in pressure loss relative to when no flow rate adjusting members are used is smaller when the configurations SL2 to SL5 are used than when the configuration SL1 is used.

From FIG. 35B, it may be understood that when there are no flow rate adjusting members, the coolant flow rates at the positions of the semiconductor elements CP1 and CP2 in the mounting area AR2 are higher than the coolant flow rates at the positions of the semiconductor elements CP1 and CP2 in the mounting areas AR1 and AR3, which means that an unbalanced flow distribution occurs. On the other hand, when the configurations SL1 to SL5 are used, an unbalanced flow distribution of the coolant at the positions of the semiconductor elements CP1 and CP2 in the mounting areas AR1 to AR3 is suppressed compared to the configuration with no flow rate adjusting members, which means that a more uniform flow is produced.

From FIG. 35C, it may be understood that if there are no flow rate adjusting members, the temperatures of the semiconductor elements CP1 and CP2 in the mounting areas AR1 and AR3 where the coolant flow rate is slow compared to the mounting area AR2 will be high. On the other hand, when SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 35A to 35C, it may be said that with the cooler 10 in FIG. 34A that uses prismatic cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 34A that uses prismatic cooling fins, it may be said that when the configurations SL2 to SL5 are used, it is possible to suppress the increase in pressure loss compared to when the configuration SL1 is used but still achieve equal or nearly equal effects of suppressing the unbalanced flow distribution and cooling the semiconductor elements as when the configuration SL1 is used.

FIGS. 36A to 36C depict evaluation results produced by thermal fluid simulations of a fourth example cooler that uses cylindrical cooling fins. FIG. 36A depicts example evaluation results of pressure loss in a cooler. FIG. 36B depicts example evaluation results of coolant flow rates relative to semiconductor element positions. FIG. 36C depicts example evaluation results of semiconductor element temperatures relative to semiconductor element positions. In FIG. 36A to FIG. 36C, the flow rate adjusting members (that is, the first and second flow rate adjusting members) used in the container of a cooler are indicated as “SL1” to “SL5” (see FIG. 34B to FIG. 34F), with “NONE” indicating a configuration where no flow rate adjusting members are used.

From FIG. 36A, it may be understood that compared to the configuration with no flow rate adjusting member (the pressure loss indicated by the dotted line L1 in FIG. 36A), there is an increase of 113.5% in the pressure loss of the cooler 10 when SL1 is used, an increase of 57.9% when SL2 is used, an increase of 62.1% when SL3 is used, an increase of 68.2% when SL4 is used, and an increase of 36.1% when SL5 is used. On the other hand, compared to SL1 where the slit width is constant (the pressure loss indicated by the broken line L2 in FIG. 36A), the pressure loss of the cooler 10 decreases by 26.0% when SL2 is used, decreases by 24.1% when SL3 is used, decreases by 21.2% when SL4 is used, and decreases by 36.3% when SL5 is used. Accordingly, the increase in pressure loss relative to when no flow rate adjusting members are used is smaller when the configurations SL2 to SL5 are used than when the configuration SL1 is used.

From FIG. 36B, it may be understood that when there are no flow rate adjusting members, the coolant flow rates at the positions of the semiconductor elements CP1 and CP2 in the mounting areas AR2 are faster than the coolant flow rates at the positions of the semiconductor elements CP1 and CP2 in the mounting areas AR1 and AR3, which means that an unbalanced flow distribution occurs. On the other hand, when the configurations SL1 to SL5 are used, an unbalanced flow distribution of the coolant at the positions of the semiconductor elements CP1 and CP2 in the mounting areas AR1 to AR3 is suppressed compared to the configuration with no flow rate adjusting members, which results in a more uniform flow.

From FIG. 36C, it may be understood that when there are no flow rate adjusting members, the temperatures of the semiconductor elements CP1 and CP2 in the mounting areas AR1 and AR3, where the coolant flow rates are slow compared to the mounting area AR2, are high. On the other hand, when the configurations SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 36A to 36C, it may be said that with the cooler 10 in FIG. 34A that uses cylindrical cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 34A that uses cylindrical cooling fins, it may be said that when the configurations SL2 to SL5 are used, it is possible to suppress the increase in pressure loss compared to when the configuration SL1 is used but still achieve equal or nearly equal effects of suppressing the unbalanced flow distribution and cooling the semiconductor elements as when the configuration SL1 is used.

### Fifth Example

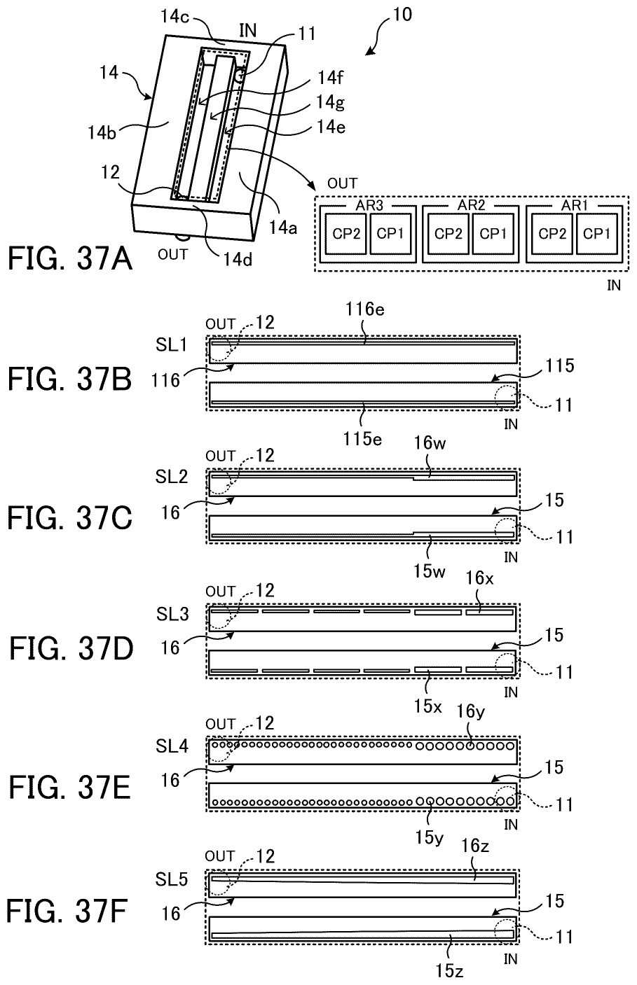

FIGS. 37A to 37F depict a fifth example of a cooler according to the fourth embodiment. FIG. 37A is a perspective view of a principal part of a fifth example of a cooler and schematically depicts the layout of semiconductor element mounting areas. FIGS. 37B to 37F are plan views schematically depicting principal parts of flow rate adjusting members used in this fifth example of a cooler.

In the fifth example, a container 14 like that depicted in FIG. 37A is used as the cooler 10. The container 14 depicted in FIG. 37A is a modification of a container 14 like that depicted in FIG. 21 described above. In the container 14 depicted in FIG. 37A, the inlet 11 (IN) that communicates with a third side wall 14c-side end of the first flow path 14e and the outlet 12 (OUT) that communicates with the fourth side wall 14d-side end of the second flow path 14f are disposed in the bottom plate 14h. The cooling fins 13a of the heat dissipating plate 13 that covers the container 14 are housed in the third flow path 14g, which is an internal space above the first flow path 14e and the second flow path 14f. In the thermal fluid simulations, the cooling fins 13a that are prismatic like those depicted in FIGS. 3A and 3B described above, or are cylindrical like those depicted in FIGS. 15A and 15B are used. In a region corresponding to the third flow path 14g on the heat dissipating plate 13 (that is, the region indicated by the dotted frame in FIG. 37A), in keeping with the example in FIG. 1 and the like described above, a semiconductor element CP1 and a semiconductor element CP2 are disposed in each of the three mounting areas AR1, AR2, and AR3 as depicted in FIG. 37A.

Note that in FIG. 37A (and FIG. 37B to FIG. 37F described later), the inlet 11 side of the container 14 is indicated as “IN” and the outlet 12 side is indicated as “OUT”. The three mounting areas AR1 to AR3 and the semiconductor elements CP1 and CP2 provided in each of these areas have a positional relationship with respect to the IN and OUT of the container 14 like that depicted in FIG. 37A.

In the thermal fluid simulations, in a cooler 10 like that depicted in FIG. 37A, a first flow rate adjusting member 115 and a second flow rate adjusting member 116 like those depicted in FIG. 37B, and first flow rate adjusting members 15 and second flow rate adjusting members 16 like those depicted in FIGS. 37C to 37F are used. Note that the positions of the inlet 11 (IN) and the outlet 12 (OUT) are depicted in FIG. 37B to FIG. 37F.

Here, the first flow rate adjusting member 115 and the second flow rate adjusting member 116 depicted in FIG. 37B are indicated as “SL1”. The configuration SL1 corresponds to the first flow rate adjusting member 115 and the second flow rate adjusting member 116 depicted in FIG. 10 described above. The first flow rate adjusting member 115 and the second flow rate adjusting member 116 depicted in FIG. 37B respectively have a slit 115e (or “seventh slit”) and a slit 116e (or “eighth slit”) with a constant width extending in the length direction. The width of the slits 115e and 116e is set at 1 mm.

The first flow rate adjusting member 15 and the second flow rate adjusting member 16 depicted in FIG. 37C are indicated as “SL2”. The configuration SL2 corresponds to the first flow rate adjusting member 15 and the second flow rate adjusting member 16 depicted in FIG. 5 described above but with openings in a changed layout. In the first flow rate adjusting member 15 depicted in FIG. 37C, the width of a slit 15w is adjusted so that out of a group of regions produced by dividing the first flow rate adjusting member 15 into three in the length direction, the aperture ratio of the region (or “first region”) at the end closest to the inlet 11 (IN) is larger than the aperture ratio of the remaining two regions (or “second regions”). The width of the slit 15w (or “first slit”) in the region at the end closest to the inlet 11 is set at 2 mm, and the width of the slit 15w (or “second slit”) in the remaining regions is set at 1 mm. In the second flow rate adjusting member 16 depicted in FIG. 37C, the width of a slit 16w is adjusted so that out of a group of regions produced by dividing the second flow rate adjusting member 16 into three in the length direction, the aperture ratio of the region (or “fourth region”) at the end furthest from the outlet 12 (OUT) is larger than the aperture ratio of the remaining two regions (or “third regions”). The width of the slit 16w (or “fourth slit”) in the region at the end furthest from the outlet 12 is set at 2 mm, and the width of the slit 16w (or “third slit”) in the remaining regions is set at 1 mm.

The first flow rate adjusting member 15 and the second flow rate adjusting member 16 depicted in FIG. 37D are indicated as “SL3”. The configuration SL3 corresponds to the first flow rate adjusting member 15 and the second flow rate adjusting member 16 depicted in FIG. 22 described above but with openings in a changed layout. As slits 15x, the first flow rate adjusting member 15 depicted in FIG. 37D has slits produced by dividing the slit 15w depicted in FIG. 37C described above in two in each region obtained by dividing the first flow rate adjusting member 15 into three in the length direction. As slits 16x, the second flow rate adjusting member 16 depicted in FIG. 37D has slits produced by dividing the slit 16w depicted in FIG. 37C described above in two in each region obtained by dividing the second flow rate adjusting member 16 into three in the length direction.

The first flow rate adjusting member 15 and the second flow rate adjusting member 16 depicted in FIG. 37E are indicated as “SL4”. This configuration SL4 corresponds to the first flow rate adjusting member 15 and the second flow rate adjusting member 16 depicted in FIG. 23 described above but with openings in a changed layout. In the first flow rate adjusting member 15 depicted in FIG. 37E, the diameters of holes 15y are adjusted so that out of a group of regions produced by dividing the first flow rate adjusting member 15 into three in the length direction, the aperture ratio of the region (or “first region”) that is closest to the inlet 11 (IN) is larger than the aperture ratio in the remaining two regions (or “second regions”). The diameter of the holes 15y (or “first holes”) in the region that is closest to the inlet 11 is set at 2 mm and the diameter of the holes 15y (or “second holes”) in the remaining regions is set at 1 mm. In addition, in the second flow rate adjusting member 16 depicted in FIG. 37E, the diameters of holes 16y are adjusted so that out of a group of regions produced by dividing the second flow rate adjusting member 16 into three in the length direction, the aperture ratio of the region (or “fourth region”) at the end furthest from the outlet 12 (OUT) is larger than the aperture ratio of the remaining two regions (or “third regions”). The diameter of the holes 16y (or “fourth holes”) in the region that is furthest from the outlet 12 is set at 2 mm and the diameter of the holes 16y (or “third holes”) in the remaining regions is set at 1 mm.

The first flow rate adjusting member 15 and the second flow rate adjusting member 16 depicted in FIG. 37F are indicated as “SL5”. This configuration SL5 corresponds to the first flow rate adjusting member 15 and the second flow rate adjusting member 16 depicted in FIG. 24 described above but with openings in a changed layout. In the first flow rate adjusting member 15 depicted in FIG. 37F, the width of a slit 15z (or “fifth slit”) is adjusted so that the aperture ratio of a region that is close to the inlet 11 (IN) (or “first region”) is (increasingly) larger than the aperture ratios of regions (or “second regions”) that are further from the inlet 11, or in other words, so that the slit 15z narrows as the distance from the inlet 11 increases. The width of the inlet 11-side end of the slit 15z is set at 2 mm and the width at the other end is set at 1 mm. In the second flow rate adjusting member 16 depicted in FIG. 37F, the width of a slit 16z (or “sixth slit”) is adjusted so that the aperture ratio of a region close to the outlet 12 (OUT) (or “third region”) is (increasingly) smaller than the aperture ratio of regions (or “fourth regions”) that are further from the outlet 12, or in other words, so that the slit 16z widens as the distance from the outlet 12 increases. The width of the outlet 12-side end of the slit 16z is set at 1 mm and the width at the other end is set at 2 mm.

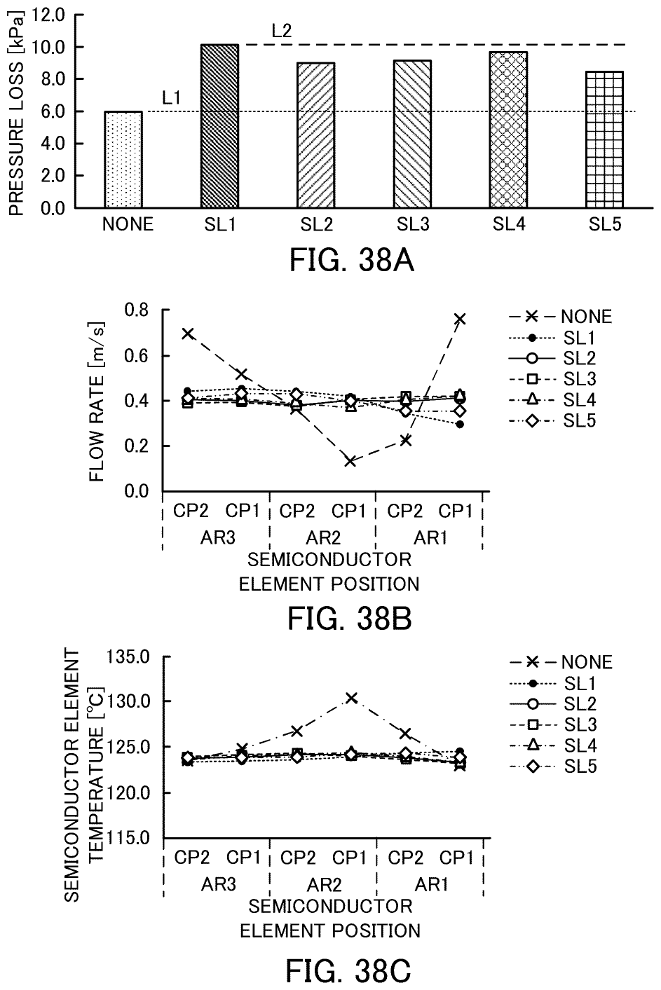

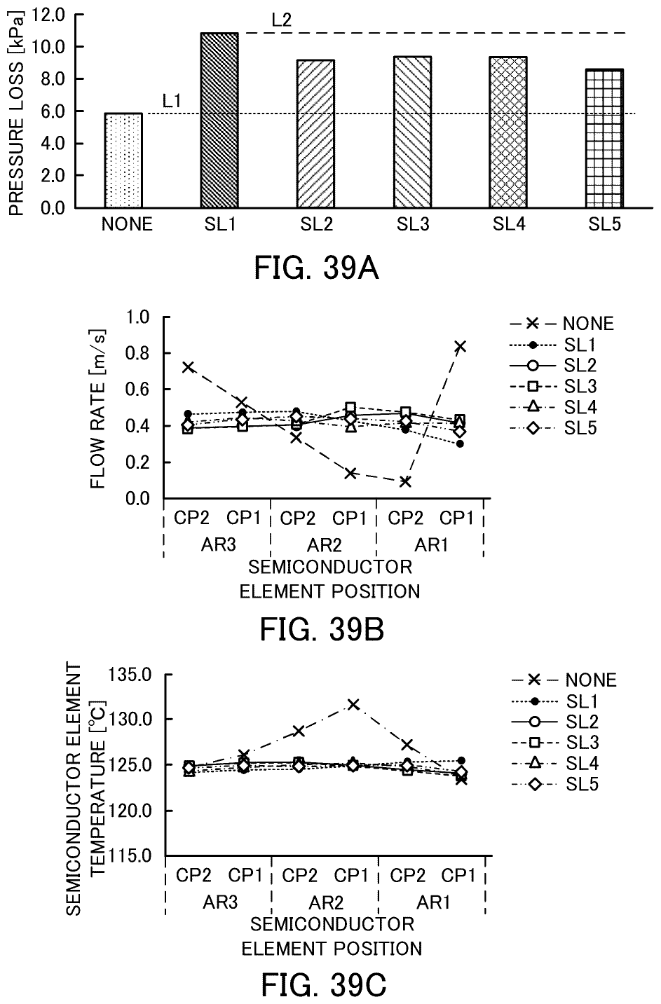

In the thermal fluid simulations, the configurations SL1 to SL5 depicted in FIGS. 37B to 37F are each used in the container 14 of a cooler 10 like that depicted in FIG. 37A. With respect to each of these cases, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the case where prismatic or cylindrical fins are used as the cooling fins 13a of the heat dissipating plate 13 described above. For comparison purposes, with respect to a configuration where the flow rate adjusting members (SL1 to SL5) are not used in the container 14 of a cooler 10 like that depicted in FIG. 37A, the pressure loss between the inlet 11 and the outlet 12, the coolant flow rates at the positions of the semiconductor elements CP1 and CP2 in the mounting areas AR1 to AR3, and the temperatures of the semiconductor elements CP1 and CP2 are obtained in the same way in the case where prismatic or cylindrical cooling fins 13a are used. Note that in the thermal fluid simulations, heat generation is reproduced by assigning a certain amount of loss to the semiconductor elements CP1 and CP2 in the mounting areas AR1 to AR3. The evaluation results produced by thermal fluid simulations are depicted in FIGS. 38A to 38C and FIGS. 39A to 39C.

FIGS. 38A to 38C depict evaluation results produced by thermal fluid simulations of a fifth example cooler that uses prismatic cooling fins. FIG. 38A depicts example evaluation results of pressure loss in a cooler. FIG. 38B depicts example evaluation results of coolant flow rates relative to semiconductor element positions. FIG. 38C depicts example evaluation results of semiconductor element temperatures relative to semiconductor element positions. In FIG. 38A to FIG. 38C, the flow rate adjusting members (that is, the first and second flow rate adjusting members) used in the container of a cooler are indicated as “SL1” to “SL5” (see FIG. 38B to FIG. 38F), with “NONE” indicating a “no flow rate adjusting member” configuration where no flow rate adjusting members are used.

From FIG. 38A, it may be understood that compared to the case with no flow rate adjusting members (the pressure loss indicated by the dotted line L1 in FIG. 38A), there is an increase of 69.8% in the pressure loss of the cooler 10 when SL1 is used, an increase of 50.7% when SL2 is used, an increase of 53.1% when 25 SL3 is used, an increase of 61.7% when SL4 is used, and an increase of 41.7% when SL5 is used. On the other hand, compared to SL1 where the slit width is constant (the pressure loss indicated by the broken line L2 in FIG. 32A), the pressure loss of the cooler 10 decreases by 11.2% when SL2 is used, decreases by 9.9% when SL3 is used, decreases by 4.8% when SL4 is used, and decreases by 16.5% when SL5 is used. Accordingly, the increase in pressure loss relative to when no flow rate adjusting members are used is smaller when the configurations SL2 to SL5 are used than when the configuration SL1 is used.

From FIG. 38B, it may be understood that when there are no flow rate adjusting members, the coolant flow rates at the positions of the semiconductor elements CP1 and CP2 in the mounting areas AR1 to AR3 are uneven, which means that an unbalanced flow distribution occurs. On the other hand, when the configurations SL1 to SL5 are used, an unbalanced flow distribution of the coolant at the positions of the semiconductor elements CP1 and CP2 in the mounting areas AR1 to AR3 is suppressed compared to the configuration with no flow rate adjusting members, which means that a more uniform flow is produced.

From FIG. 38C, it may be understood that if there are no flow rate adjusting members, the temperatures of the semiconductor elements CP1 and CP2 in the mounting areas AR1 to AR3 are uneven. On the other hand, when the configurations SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 38A to 38C, it may be said that with the cooler 10 in FIG. 37A that uses prismatic cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 37A that uses prismatic cooling fins, it may be said that when the configurations SL2 to SL5 are used, it is possible to suppress the increase in pressure loss compared to when the configuration SL1 is used but still achieve equal or nearly equal effects of suppressing an unbalanced flow distribution and cooling the semiconductor elements as when the configuration SL1 is used.

FIGS. 39A to 39C depict evaluation results produced by thermal fluid simulations of a fifth example cooler that uses cylindrical cooling fins. FIG. 39A depicts example evaluation results of pressure loss in a cooler. FIG. 39B depicts example evaluation results of coolant flow rates relative to semiconductor element positions. FIG. 39C depicts example evaluation results of semiconductor element temperature relative to semiconductor element positions. In FIG. 39A to FIG. 39C, the flow rate adjusting members (that is, the first and second flow rate adjusting members) used in the container of a cooler are indicated as “SL1” to “SL5” (see FIG. 37B to FIG. 37F), with “NONE” indicating a configuration where no flow rate adjusting members are used.

From FIG. 39A, it may be understood that compared to the configuration with no flow rate adjusting members (the pressure loss indicated by the dotted line L1 in FIG. 39A), there is an increase of 85.8% in the pressure loss of the cooler 10 when SL1 is used, an increase of 56.8% when SL2 is used, an increase of 60.3% when SL3 is used, an increase of 60.2% when SL4 is used, and an increase of 47.3% when SL5 is used. On the other hand, compared to SL1 where the slit width is constant (the pressure loss indicated by the broken line L2 in FIG. 39A), the pressure loss of the cooler 10 decreases by 15.6% when SL2 is used, decreases by 13.7% when SL3 is used, decreases by 13.8% when SL4 is used, and decreases by 20.7% when SL5 is used. Accordingly, the increase in pressure loss relative to when no flow rate adjusting members are used is smaller when the configurations SL2 to SL5 are used than when the configuration SL1 is used.

From FIG. 39B, it may be understood that when there are no flow rate adjusting members, the coolant flow rates at the positions of the semiconductor elements CP1 and CP2 in the mounting areas AR1 to AR3 are uneven, which means that an unbalanced flow distribution occurs. On the other hand, when the configurations SL1 to SL5 are used, an unbalanced flow distribution of the coolant at the positions of the semiconductor elements CP1 and CP2 in the mounting areas AR1 to AR3 is suppressed compared to the configuration with no flow rate adjusting members, which results in a more uniform flow.

From FIG. 39C, it may be understood that if there are no flow rate adjusting members, the temperatures of the semiconductor elements CP1 and CP2 in the mounting areas AR1 to AR3 are uneven. On the other hand, when the configurations SL1 to SL5 are used, compared to the configuration with no flow rate adjusting members, the temperatures of the semiconductor elements CP1 and CP2 in the mounting areas AR1 to AR3 are kept comparatively constant and are cooled more uniformly.

From the results depicted in FIGS. 39A to 39C, it may be said that with the cooler 10 in FIG. 37A that uses cylindrical cooling fins, when the configurations SL1 to SL5 are used, compared to the configuration with no flow rate adjusting members, a superior effect of suppressing an uneven flow distribution and a superior effect of cooling the semiconductor elements may be obtained. In the cooler 10 in FIG. 37A that uses cylindrical cooling fins, it may be said that when the configurations SL2 to SL5 are used, it is possible to suppress the increase in pressure loss compared to when the configuration SL1 is used but still achieve equal or nearly equal effects of suppressing the unbalanced flow distribution and cooling the semiconductor elements as when the configuration SL1 is used.

According to an aspect of the present disclosure, it is possible to realize a cooler capable of suppressing the occurrence of an unbalanced flow distribution and an increase in pressure loss.

According to another aspect of the present disclosure, it is possible to realize a semiconductor device equipped with a cooler capable of suppressing the occurrence of an unbalanced flow distribution and an increase in pressure loss.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A cooler, comprising:
a container that includes a first side wall having an inlet for a coolant and a second side wall having an outlet for the coolant;
a first flow path that is disposed parallel to the first side wall inside the container, and communicates with the inlet;
a second flow path that is disposed parallel to the second side wall inside the container, and communicates with the outlet;
a third flow path disposed inside the container and communicating with both the first flow path and the second flow path;
a first flow rate adjusting member disposed inside the container between the first flow path and the third flow path; and
a second flow rate adjusting member disposed inside the container between the second flow path and the third flow path, wherein
the first flow rate adjusting member includes a first region and a second region, and has one or more openings through which the coolant flows from the first flow path to the third flow path, the first region having a first open area ratio that is a ratio of a total size of the one or more openings in the first region to a size of the first region, the second region having a second open area ratio that is a ratio of a total size of the one or more openings in the second region to a size of the second region that is smaller than the first open area ratio at the second region, and
the second flow rate adjusting member includes a third region and a fourth region, and has one or more openings through which the coolant flows from the third flow path to the second flow path, the third region having a third open area ratio that is a ratio of a total size of the one or more openings in the third region to a size of the third region, the fourth region having a fourth open area ratio that is a ratio of a total size of the one or more openings in the fourth region to a size of the fourth region that is larger than the third open area ratio.

2. The cooler according to claim 1, wherein the first region and the third region are aligned in a direction orthogonal to a direction in which the first and second flow paths extend.

3. The cooler according to claim 1, wherein
in the first flow rate adjusting member, the first region is positioned closer to the inlet than is the second region, and
in the second flow rate adjusting member, the third region is positioned closer to the outlet than is the fourth region.

4. The cooler according to claim 1, wherein
the one or more openings in the first region include a first slit with a first width,
the one or more openings in the second region include a second slit with a second width narrower than the first width,
the one or more openings in the third region include a third slit with a third width, and
the one or more openings in the fourth region include a fourth slit with a fourth width wider than the third width.

5. The cooler according to claim 1, wherein
the one or more openings in the first region include a first hole with a first diameter,
the one or more openings in the second region include a second hole with a second diameter smaller than the first diameter,
the one or more openings in the third region include a third hole with a third diameter, and
the one or more openings in the fourth region include a fourth hole with a fourth diameter larger than the third diameter.

6. The cooler according to claim 1, wherein
the one or more openings of the first flow rate adjusting member include one slit extending from the first region to the second region and having a width that narrows from the first region toward the second region, and
the one or more openings of the second flow rate adjusting member include another slit extending from the third region to the fourth region and having a width that widens from the third region toward the fourth region.

7. The cooler according to claim 1, wherein
the first flow path is a first channel that extends along the first side wall in a bottom portion of the container between the first side wall and the second side wall,
the second flow path is a second channel that extends along the second side wall in the bottom portion between the first side wall and the second side wall, and
the third flow path is an internal space in the container located above the first channel and the second between the first side wall and the second side wall.

8. The cooler according to claim 7, wherein
out of a group of regions defined by dividing the first flow path into three so as to be aligned in a direction where the first channel extends along the first side wall, one region defined by the dividing corresponds to the first region and the remaining two regions defined by the dividing correspond to the second region, and
out of a group of regions defined by dividing the second flow path into three so as to be aligned in a direction where the second channel extends along the second side wall, one region defined by the dividing corresponds to the third region and the remaining two regions defined by the dividing correspond to the fourth region.

9. The cooler according to claim 7, wherein
the one or more openings of the first flow rate adjusting member are provided adjacent to the first side wall, and
the one or more openings of the second flow rate adjusting member are provided adjacent to the second side wall.

10. The cooler according to claim 7, wherein the container includes a heat dissipating plate that covers the third flow path and is equipped with fins disposed in the third flow path.

11. A semiconductor device, comprising:
a cooler; and
a semiconductor module mounted on the cooler, wherein the cooler includes:
a container that includes a first side wall having an inlet for a coolant and a second side wall having an outlet for the coolant;
a first flow path that is disposed parallel to the first side wall inside the container, and communicates with the inlet;
a second flow path that is disposed parallel to the second side wall inside the container, and communicates with the outlet;
a third flow path disposed inside the container and communicating with both the first flow path and the second flow path;
a first flow rate adjusting member disposed inside the container between the first flow path and the third flow path; and
a second flow rate adjusting member disposed inside the container between the second flow path and the third flow path, wherein
the first flow rate adjusting member includes a first region and a second region, and has one or more openings through which the coolant flows from the first flow path to the third flow path, the first region having a first open area ratio that is a ratio of a total size of the one or more openings in the first region to a size of the first region, the second region having a second open area ratio that is a ratio of a total size of the one or more openings in the second region to a size of the second region that is smaller than the first open area ratio at the second region, and
the second flow rate adjusting member includes a third region and a fourth region, and has one or more openings through which the coolant flows from the third flow path to the second flow path, the third region having a third open area ratio that is a ratio of a total size of the one or more openings in the third region to a size of the third region, the fourth region having a fourth open area ratio that is a ratio of a total size of the one or more openings in the fourth region to a size of the fourth region that is larger than the third open area ratio.

12. The semiconductor device according to claim 11, wherein the first region and the third region are aligned in a direction orthogonal to a direction in which the first and second flow paths extend.

13. The semiconductor device according to claim 11, wherein
in the first flow rate adjusting member, the first region is positioned closer to the inlet than is the second region, and
in the second flow rate adjusting member, the third region is positioned closer to the outlet than is the fourth region.

14. The semiconductor device according to claim 11, wherein
the one or more openings in the first region include a first slit with a first width,
the one or more openings in the second region include a second slit with a second width narrower than the first width,
the one or more openings in the third region include a third slit with a third width, and
the one or more openings in the fourth region include a fourth slit with a fourth width wider than the third width.

15. The semiconductor device according to claim 11, wherein
the one or more openings in the first region include a first hole with a first diameter,
the one or more openings in the second region include a second hole with a second diameter smaller than the first diameter,
the one or more openings in the third region include a third hole with a third diameter, and
the one or more openings in the fourth region include a fourth hole with a fourth diameter larger than the third diameter.

16. The semiconductor device according to claim 11, wherein
the one or more openings of the first flow rate adjusting member include one slit extending from the first region to the second region and having a width that narrows from the first region toward the second region, and
the one or more openings of the second flow rate adjusting member include another slit extending from the third region to the fourth region and having a width that widens from the third region toward the fourth region.

17. The semiconductor device according to claim 11, wherein
the first flow path is a first groove that extends along the first side wall in a bottom portion of the container between the first side wall and the second side wall,
the second flow path is a second channel that extends along the second side wall in the bottom portion between the first side wall and the second side wall, and
the third flow path is an internal space in the container located above the first channel and the second channel between the first side wall and the second side wall.

18. The semiconductor device according to claim 17, wherein
out of a group of regions defined by dividing the first flow path into three so as to be aligned in a direction where the first flow path extends along the first side wall, one region defined by the dividing corresponds to the first region and the remaining two regions defined by the dividing correspond to the second region, and
out of a group of regions defined by dividing the second flow path into three so as to be aligned in a direction where the second flow path extends along the second side wall, one region defined by the dividing corresponds to the third region and the remaining two regions defined by the dividing correspond to the fourth region.

19. The semiconductor device according to claim 17, wherein
the one or more openings of the first flow rate adjusting member are provided adjacent to the first side wall, and
the one or more openings of the second flow rate adjusting member are provided adjacent to the second side wall.

20. The semiconductor device according to claim 17, wherein
the container includes a heat dissipating plate that covers the third flow path and is equipped with fins disposed in the third flow path, and
the heat dissipating plate is disposed between the semiconductor module and the third flow path that face each other.
